(19) United States
(12) Patent Application Publication
(10) Pub. No.: US 2026/0149469 A1
(43) Pub. Date: May 28, 2026

(54) DECODING SCHEMES FOR UNEQUAL MESSAGE PROTECTION USING NESTED SUBCODES IN REED-MULLER CODES

(71) Applicant: QUALCOMM Incorporated, San Diego, CA (US)

(72) Inventors: Gabriele CESA, Diemen (NL); Ashish KHISTI, Vaughan (CA); Kumar PRATIK, Amsterdam (NL); Arash BEHBOODI, Amsterdam (NL)

(21) Appl. No.: 18/957,538

(22) Filed: Nov. 22, 2024

(51) Int. Cl. H03M 13/00; H03M 13/13

(52) U.S. Cl. CPC H03M 13/6527; H03M 13/136; H03M 13/616

(57) ABSTRACT

The apparatus may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first and second subset of codewords are associated with first and second RM codes, wherein the first RM code is a subcode of the second RM code, decode the plurality of codewords using a decoding method that is associated with a first error tolerance for the first subset of the plurality of codewords that is higher than a second error tolerance for the second subset of the plurality of codewords, and output a plurality of decoded codewords associated with the plurality of messages.

### TECHNICAL FIELD

The present disclosure relates generally to communication systems, and more particularly, to encoding and decoding methods for transmitting signals.

### INTRODUCTION

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (e.g., with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard. There exists a need for further improvements in 5G NR technology. These improvements may also be applicable to other multi-access technologies and the telecommunication standards that employ these technologies.

### BRIEF SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In an aspect of the disclosure, a method, a computer-readable medium, and an apparatus are provided. The apparatus may be an encoder, or encoding, device (e.g., at a network device or a user equipment (UE)) that may be configured to obtain a plurality of messages comprising a first subset of the plurality of messages and a second subset of the plurality of messages, encode the first subset of the plurality of messages into a first set of codewords associated with a first Reed-Muller (RM) code, encode the second subset of the plurality of messages into a second set of codewords associated with a second RM code, where the first RM code is a subcode of the second RM code, and transmit, to a decoder device, the plurality of codewords.

In an aspect of the disclosure, a method, a computer-readable medium, and an apparatus are provided. The apparatus may be a decoder, or decoding, device (e.g., at a network device or a UE) that may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages.

In an aspect of the disclosure, a method, a computer-readable medium, and an apparatus are provided. The apparatus may be configured to train a machine-learning (ML) aided algorithm to determine whether particular codewords in a plurality of input codewords were encoded with a first RM code or a second RM code that is a subcode of the first RM code and to decode input codewords encoded by the first RM code with a first threshold accuracy and to decode input codewords encoded by the second RM code with a second threshold accuracy that is higher than the first threshold accuracy, by providing a training data set including multiple data sets, each data set including at least (1) multiple projections generated by an RPA decoding method applied to a test codeword encoded with one of the first RM code or the second RM code and (2) an indication of whether the first RM code or the second RM code was used to encode the test codeword, and outputting the set of weights associated with the MT algorithm.

To the accomplishment of the foregoing and related ends, the one or more aspects may include the features hereinafter fully described and particularly pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a diagram illustrating an example of a wireless communications system and

an access network.

FIG. 2A is a diagram illustrating an example of a first frame, in accordance with various aspects of the present disclosure.

FIG. 2B is a diagram illustrating an example of downlink (DL) channels within a subframe, in accordance with various aspects of the present disclosure.

FIG. 2C is a diagram illustrating an example of a second frame, in accordance with various aspects of the present disclosure.

FIG. 2D is a diagram illustrating an example of uplink (UL) channels within a subframe, in accordance with various aspects of the present disclosure.

FIG. 3 is a diagram illustrating an example of a base station and user equipment (UE) in an access network.

FIG. 4 is a diagram illustrating aspects of UMP in accordance with some aspects of the disclosure.

FIG. 5 is an example of the AI/ML algorithm associated with a RM decoder for UMP and illustrates various aspects model training, model inference, model feedback, and model update.

FIG. 6 is a diagram illustrating pseudocode for a Reed decoding algorithm for decoding Reed-Muller codes in accordance with some aspects of the disclosure.

FIG. 7 is a diagram illustrating majority voting in the context of a Reed decoder in accordance with some aspects of the disclosure.

FIG. 8 is a diagram illustrating pseudocode for the RPA decoding algorithm for decoding Reed-Muller codes in accordance with some aspects of the disclosure.

FIG. 9A is a diagram illustrating a 4-dimensional hypercube representing the codewords of a RM code and a RM code in accordance with some aspects of the disclosure.

FIG. 9B is a diagram illustrating a distance associated with error correction/detection for codewords for an RM code and for an RM code in accordance with some aspects of the disclosure.

FIG. 10 is a diagram illustrating pseudocode for the modified Reed decoder in accordance with some aspects of the disclosure.

FIG. 11 is a diagram illustrating a first modified RPA decoder in accordance with some aspects of the disclosure.

FIG. 12 is a diagram illustrating a second modified RPA decoder in accordance with some aspects of the disclosure.

FIG. 13 is a call flow diagram illustrating a method of wireless communication in accordance with some aspects of the disclosure.

FIG. 14 is a flowchart of a method of wireless communication.

FIG. 15 is a flowchart of a method of wireless communication.

FIG. 16 is a flowchart of a method of wireless communication.

FIG. 17 is a flowchart of a method of wireless communication.

FIG. 18 is a diagram illustrating an example of a hardware implementation for an example apparatus and/or network entity.

FIG. 19 is a diagram illustrating an example of a hardware implementation for an example network entity.

FIG. 20 is a flowchart of a method of training an AI/ML algorithm.

FIG. 21 is an illustrative block diagram of an example machine learning (ML) model represented by an artificial neural network (ANN), in accordance with various aspects of the present disclosure.

### DETAILED DESCRIPTION

In some aspects of electronic communication different methods of encoding and decoding may be applied to provide protection against errors. Binary RM codes may be used to provide the error protection and/or a fault tolerance with different Binary RM codes providing different levels of error protection and/or fault tolerance.

Various aspects relate generally to the use of RM codes for unequal error correction (UEC) and/or unequal message protection (UMP) for different messages. Some aspects more specifically relate to an encoder that encodes different classes of messages (e.g., two or more classed including a first class of messages (e.g., which may be considered to be important messages) and a second class of messages (e.g., which may be considered to be less important or regular messages) using different RM codes based on an associated threshold error tolerance and corresponding decoders. In some examples, an encoding device, may be configured to obtain a plurality of messages comprising a first subset of the plurality of messages and a second subset of the plurality of messages, encode the first subset of the plurality of messages into a first set of codewords associated with a first RM code, encode the second subset of the plurality of messages into a second set of codewords associated with a second RM code, where the first RM code is a subcode of the second RM code, and transmit, to a decoder device, the plurality of codewords. In some examples, a decoder, or decoding, device may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages.

Particular aspects of the subject matter described in this disclosure can be implemented to realize one or more of the following potential advantages. In some examples, by applying different RM codes for encoding different classes of messages and providing at least one decoder that can decode messages using the different error thresholds and/or fault tolerances without prior knowledge of the RM code associated with a particular received codeword, the described techniques can be used to provide unequal message protection to different classes of messages in an electronic and/or wireless communication environment.

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Several aspects of telecommunication systems are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer.

While aspects, implementations, and/or use cases are described in this application by illustration to some examples, additional or different aspects, implementations and/or use cases may come about in many different arrangements and scenarios. Aspects, implementations, and/or use cases described herein may be implemented across many differing platform types, devices, systems, shapes, sizes, and packaging arrangements. For example, aspects, implementations, and/or use cases may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described examples may occur. Aspects, implementations, and/or use cases may range a spectrum from chip-level or modular components to non-modular, non-chip-level implementations and further to aggregate, distributed, or original equipment manufacturer (OEM) devices or systems incorporating one or more techniques herein. In some practical settings, devices incorporating described aspects and features may also include additional components and features for implementation and practice of claimed and described aspect. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). Techniques described herein may be practiced in a wide variety of devices, chip-level components, systems, distributed arrangements, aggregated or disaggregated components, end-user devices, etc. of varying sizes, shapes, and constitution.

Deployment of communication systems, such as 5G NR systems, may be arranged in multiple manners with various components or constituent parts. In a 5G NR system, or network, a network node, a network entity, a mobility element of a network, a radio access network (RAN) node, a core network node, a network element, or a network equipment, such as a base station (BS), or one or more units (or one or more components) performing base station functionality, may be implemented in an aggregated or disaggregated architecture. For example, a BS (such as a Node B (NB), evolved NB (CNB), NR BS, 5G NB, access point (AP), a transmission reception point (TRP), or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU can be implemented as virtual units, i.e., a virtual central unit (VCU), a virtual distributed unit (VDU), or a virtual radio unit (VRU).

Base station operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

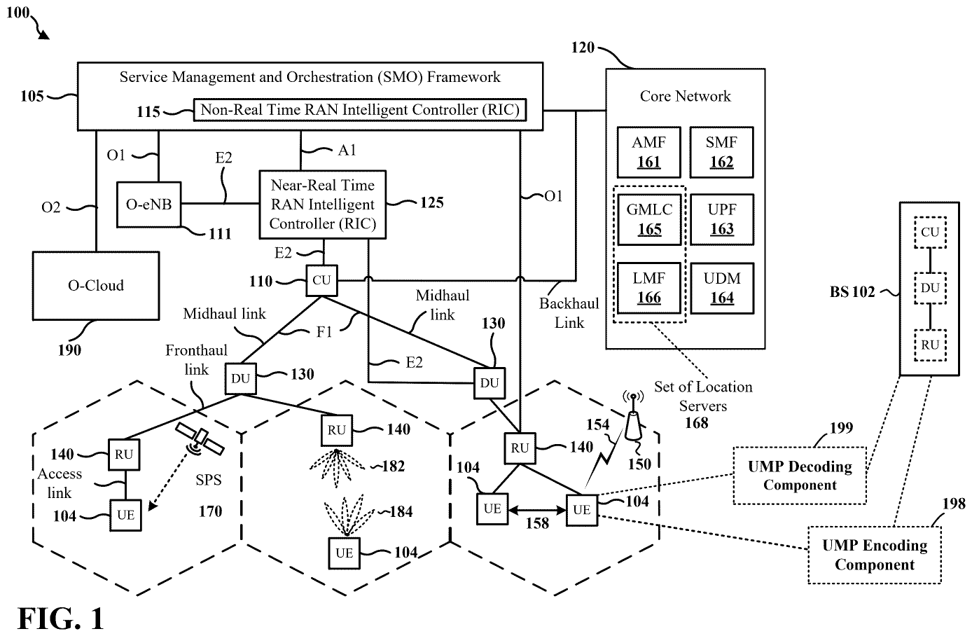

FIG. 1 is a diagram 100 illustrating an example of a wireless communications system and an access network. The illustrated wireless communications system includes a disaggregated base station architecture. The disaggregated base station architecture may include one or more CUs 110 that can communicate directly with a core network 120 via a backhaul link, or indirectly with the core network 120 through one or more disaggregated base station units (such as a Near-Real Time (Near-RT) RAN Intelligent Controller (RIC) 125 via an E2 link, or a Non-Real Time (Non-RT) RIC 115 associated with a Service Management and Orchestration (SMO) Framework 105, or both). A CU 110 may communicate with one or more DUs 130 via respective midhaul links, such as an F1 interface. The DUs 130 may communicate with one or more RUs 140 via respective fronthaul links. The RUs 140 may communicate with respective UEs 104 via one or more radio frequency (RF) access links. In some implementations, the UE 104 may be simultaneously served by multiple RUs 140.

Each of the units, i.e., the CUs 110, the DUs 130, the RUs 140, as well as the Near-RT RICs 125, the Non-RT RICs 115, and the SMO Framework 105, may include one or more interfaces or be coupled to one or more interfaces configured to receive or to transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or to transmit signals over a wired transmission medium to one or more of the other units. Additionally, the units can include a wireless interface, which may include a receiver, a transmitter, or a transceiver (such as an RF transceiver), configured to receive or to transmit signals, or both, over a wireless transmission medium to one or more of the other units.

In some aspects, the CU 110 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 110. The CU 110 may be configured to handle user plane functionality (i.e., Central Unit-User Plane (CU-UP)), control plane functionality (i.e., Central Unit-Control Plane (CU-CP)), or a combination thereof. In some implementations, the CU 110 can be logically split into one or more CU-UP units and one or more CU-CP units. The CU-UP unit can communicate bidirectionally with the CU-CP unit via an interface, such as an E1 interface when implemented in an O-RAN configuration. The CU 110 can be implemented to communicate with the DU 130, as necessary, for network control and signaling.

The DU 130 may correspond to a logical unit that includes one or more base station functions to control the operation of one or more RUs 140. In some aspects, the DU 130 may host one or more of a radio link control (RLC) layer, a medium access control (MAC) layer, and one or more high physical (PHY) layers (such as modules for forward error correction (FEC) encoding and decoding, scrambling, modulation, demodulation, or the like) depending, at least in part, on a functional split, such as those defined by 3GPP. In some aspects, the DU 130 may further host one or more low PHY layers. Each layer (or module) can be implemented with an interface configured to communicate signals with other layers (and modules) hosted by the DU 130, or with the control functions hosted by the CU 110.

Lower-layer functionality can be implemented by one or more RUs 140. In some deployments, an RU 140, controlled by a DU 130, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 140 can be implemented to handle over the air (OTA) communication with one or more UEs 104. In some implementations, real-time and non-real-time aspects of control and user plane communication with the RU(s) 140 can be controlled by the corresponding DU 130. In some scenarios, this configuration can enable the DU(s) 130 and the CU 110 to be implemented in a cloud-based RAN architecture, such as a vRAN architecture.

The SMO Framework 105 may be configured to support RAN deployment and provisioning of non-virtualized and virtualized network elements. For non-virtualized network elements, the SMO Framework 105 may be configured to support the deployment of dedicated physical resources for RAN coverage requirements that may be managed via an operations and maintenance interface (such as an O1 interface). For virtualized network elements, the SMO Framework 105 may be configured to interact with a cloud computing platform (such as an open cloud (O-Cloud) 190) to perform network element life cycle management (such as to instantiate virtualized network elements) via a cloud computing platform interface (such as an O2 interface). Such virtualized network elements can include, but are not limited to, CUs 110, DUs 130, RUs 140 and Near-RT RICs 125. In some implementations, the SMO Framework 105 can communicate with a hardware aspect of a 4G RAN, such as an open eNB (O-eNB) 111, via an O1 interface. Additionally, in some implementations, the SMO Framework 105 can communicate directly with one or more RUs 140 via an O1 interface. The SMO Framework 105 also may include a Non-RT RIC 115 configured to support functionality of the SMO Framework 105.

The Non-RT RIC 115 may be configured to include a logical function that enables non-real-time control and optimization of RAN elements and resources, artificial intelligence (AI)/machine learning (ML) (AI/ML) workflows including model training and updates, or policy-based guidance of applications/features in the Near-RT RIC 125. The Non-RT RIC 115 may be coupled to or communicate with (such as via an A1 interface) the Near-RT RIC 125. The Near-RT RIC 125 may be configured to include a logical function that enables near-real-time control and optimization of RAN elements and resources via data collection and actions over an interface (such as via an E2 interface) connecting one or more CUs 110, one or more DUs 130, or both, as well as an O-eNB, with the Near-RT RIC 125.

In some implementations, to generate AI/ML models to be deployed in the Near-RT RIC 125, the Non-RT RIC 115 may receive parameters or external enrichment information from external servers. Such information may be utilized by the Near-RT RIC 125 and may be received at the SMO Framework 105 or the Non-RT RIC 115 from non-network data sources or from network functions. In some examples, the Non-RT RIC 115 or the Near-RT RIC 125 may be configured to tune RAN behavior or performance. For example, the Non-RT RIC 115 may monitor long-term trends and patterns for performance and employ AI/ML models to perform corrective actions through the SMO Framework 105 (such as reconfiguration via 01) or via creation of RAN management policies (such as A1 policies).

At least one of the CU 110, the DU 130, and the RU 140 may be referred to as a base station 102. Accordingly, a base station 102 may include one or more of the CU 110, the DU 130, and the RU 140 (each component indicated with dotted lines to signify that each component may or may not be included in the base station 102). The base station 102 provides an access point to the core network 120 for a UE 104. The base station 102 may include macrocells (high power cellular base station) and/or small cells (low power cellular base station). The small cells include femtocells, picocells, and microcells. A network that includes both small cell and macrocells may be known as a heterogeneous network. A heterogeneous network may also include Home Evolved Node Bs (eNBs) (HeNBs), which may provide service to a restricted group known as a closed subscriber group (CSG). The communication links between the RUs 140 and the UEs 104 may include uplink (UL) (also referred to as reverse link) transmissions from a UE 104 to an RU 140 and/or downlink (DL) (also referred to as forward link) transmissions from an RU 140 to a UE 104. The communication links may use multiple-input and multiple-output (MIMO) antenna technology, including spatial multiplexing, beamforming, and/or transmit diversity. The communication links may be through one or more carriers. The base station 102/UEs 104 may use spectrum up to Y MHz (e.g., 5, 10, 15, 20, 100, 500, etc. MHz) bandwidth per carrier allocated in a carrier aggregation of up to a total of Yx MHz (x component carriers) used for transmission in each direction. The carriers may or may not be adjacent to each other. Allocation of carriers may be asymmetric with respect to DL and UL (e.g., more or fewer carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

Certain UEs 104 may communicate with each other using device-to-device (D2D) communication link 158. The D2D communication link 158 may use the DL/UL wireless wide area network (WWAN) spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, Bluetooth™ (Bluetooth is a trademark of the Bluetooth Special Interest Group (SIG)), Wi-Fi™ (Wi-Fi is a trademark of the Wi-Fi Alliance) based on the Institute of Electrical and Electronics Engineers (IEEE) 902.11 standard, LTE, or NR.

The wireless communications system may further include a Wi-Fi AP 150 in communication with UEs 104 (also referred to as Wi-Fi stations (STAs)) via communication link 154, e.g., in a 5 GHz unlicensed frequency spectrum or the like. When communicating in an unlicensed frequency spectrum, the UEs 104/AP 150 may perform a clear channel assessment (CCA) prior to communicating in order to determine whether the channel is available.

The electromagnetic spectrum is often subdivided, based on frequency/wavelength, into various classes, bands, channels, etc. In 5G NR, two initial operating bands have been identified as frequency range designations FR1 (510 MHz-8.125 GHZ) and FR2 (24.25 GHz-52.6 GHZ). Although a portion of FR1 is greater than 6 GHZ, FR1 is often referred to (interchangeably) as a “sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHZ). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR2-2 (52.6 GHz-81 GHZ), FR4 (71 GHz-114.25 GHZ), and FR5 (114.25 GHZ-300 GHz). Each of these higher frequency bands falls within the EHF band.

With the above aspects in mind, unless specifically stated otherwise, the term “sub-6 GHz” or the like if used herein may broadly represent frequencies that may be less than 6 GHz, may be within FR1, or may include mid-band frequencies. Further, unless specifically stated otherwise, the term “millimeter wave” or the like if used herein may broadly represent frequencies that may include mid-band frequencies, may be within FR2, FR4, FR2-2, and/or FR5, or may be within the EHF band.

The base station 102 and the UE 104 may each include a plurality of antennas, such as antenna elements, antenna panels, and/or antenna arrays to facilitate beamforming. The base station 102 may transmit a beamformed signal 182 to the UE 104 in one or more transmit directions. The UE 104 may receive the beamformed signal from the base station 102 in one or more receive directions. The UE 104 may also transmit a beamformed signal 184 to the base station 102 in one or more transmit directions. The base station 102 may receive the beamformed signal from the UE 104 in one or more receive directions. The base station 102/UE 104 may perform beam training to determine the best receive and transmit directions for each of the base station 102/UE 104. The transmit and receive directions for the base station 102 may or may not be the same. The transmit and receive directions for the UE 104 may or may not be the same.

The base station 102 may include and/or be referred to as a gNB, Node B, eNB, an access point, a base transceiver station, a radio base station, a radio transceiver, a transceiver function, a basic service set (BSS), an extended service set (ESS), a TRP, network node, network entity, network equipment, or some other suitable terminology. The base station 102 can be implemented as an integrated access and backhaul (IAB) node, a relay node, a sidelink node, an aggregated (monolithic) base station with a baseband unit (BBU) (including a CU and a DU) and an RU, or as a disaggregated base station including one or more of a CU, a DU, and/or an RU. The set of base stations, which may include disaggregated base stations and/or aggregated base stations, may be referred to as next generation (NG) RAN (NG-RAN).

The core network 120 may include an Access and Mobility Management Function (AMF) 161, a Session Management Function (SMF) 162, a User Plane Function (UPF) 163, a Unified Data Management (UDM) 164, one or more location servers 168, and other functional entities. The AMF 161 is the control node that processes the signaling between the UEs 104 and the core network 120. The AMF 161 supports registration management, connection management, mobility management, and other functions. The SMF 162 supports session management and other functions. The UPF 163 supports packet routing, packet forwarding, and other functions. The UDM 164 supports the generation of authentication and key agreement (AKA) credentials, user identification handling, access authorization, and subscription management. The one or more location servers 168 are illustrated as including a Gateway Mobile Location Center (GMLC) 165 and a Location Management Function (LMF) 166. However, generally, the one or more location servers 168 may include one or more location/positioning servers, which may include one or more of the GMLC 165, the LMF 166, a position determination entity (PDE), a serving mobile location center (SMLC), a mobile positioning center (MPC), or the like. The GMLC 165 and the LMF 166 support UE location services. The GMLC 165 provides an interface for clients/applications (e.g., emergency services) for accessing UE positioning information. The LMF 166 receives measurements and assistance information from the NG-RAN and the UE 104 via the AMF 161 to compute the position of the UE 104. The NG-RAN may utilize one or more positioning methods in order to determine the position of the UE 104. Positioning the UE 104 may involve signal measurements, a position estimate, and an optional velocity computation based on the measurements. The signal measurements may be made by the UE 104 and/or the base station 102 serving the UE 104. The signals measured may be based on one or more of a satellite positioning system (SPS) 170 (e.g., one or more of a Global Navigation Satellite System (GNSS), global position system (GPS), non-terrestrial network (NTN), or other satellite position/location system), LTE signals, wireless local area network (WLAN) signals, Bluetooth signals, a terrestrial beacon system (TBS), sensor-based information (e.g., barometric pressure sensor, motion sensor), NR enhanced cell ID (NR E-CID) methods, NR signals (e.g., multi-round trip time (Multi-RTT), DL angle-of-departure (DL-AoD), DL time difference of arrival (DL-TDOA), UL time difference of arrival (UL-TDOA), and UL angle-of-arrival (UL-AoA) positioning), and/or other systems/signals/sensors.

Examples of UEs 104 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (e.g., parking meter, gas pump, toaster, vehicles, heart monitor, etc.). The UE 104 may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

Referring again to FIG. 1, in certain aspects, the UE 104 and/or the base station 102 may have a UMP encoding component 198 that may be configured to obtain a plurality of messages comprising a first subset of the plurality of messages and a second subset of the plurality of messages, encode the first subset of the plurality of messages into a first set of codewords associated with a first RM code, encode the second subset of the plurality of messages into a second set of codewords associated with a second RM code, where the first RM code is a subcode of the second RM code, and transmit, to a decoder device, the plurality of codewords. In certain aspects, the base station 102 and/or the UE 104 may have a UMP decoding component 199 that may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages. In some aspects a single UMP encoding/decoding component including the function of both the UMP encoding component 198 and the UMP decoding component 199 may be included at the base station 102 and/or the UE 104. Although the following description may be focused on 5G NR, the concepts described herein may be applicable to other similar areas, such as LTE, LTE-A, CDMA, GSM, and other wireless technologies.

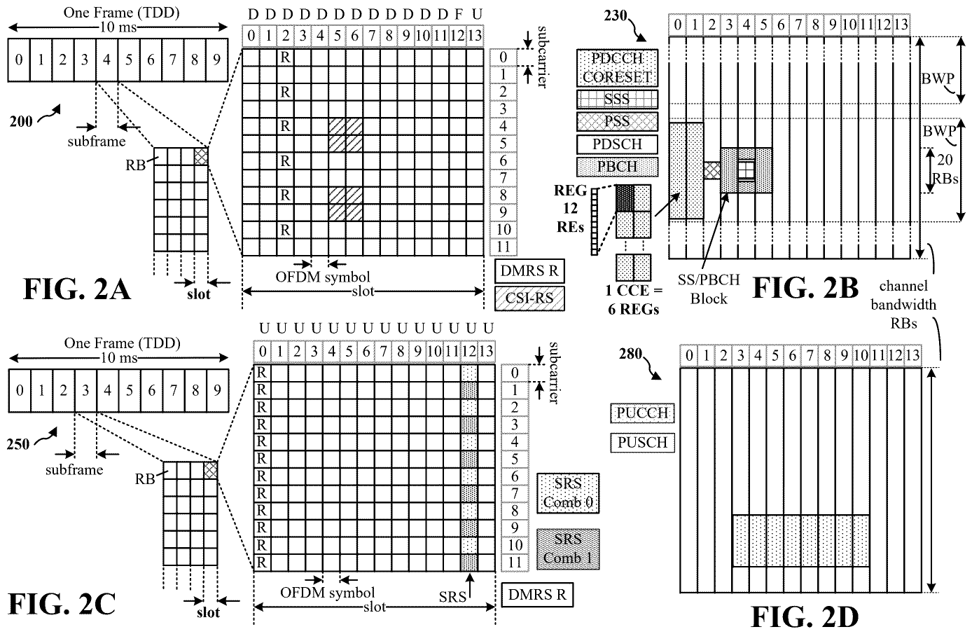

FIG. 2A is a diagram 200 illustrating an example of a first subframe within a 5G NR frame structure. FIG. 2B is a diagram 230 illustrating an example of DL channels within a 5G NR subframe. FIG. 2C is a diagram 250 illustrating an example of a second subframe within a 5G NR frame structure. FIG. 2D is a diagram 280 illustrating an example of UL channels within a 5G NR subframe. The 5G NR frame structure may be frequency division duplexed (FDD) in which for a particular set of subcarriers (carrier system bandwidth), subframes within the set of subcarriers are dedicated for either DL or UL, or may be time division duplexed (TDD) in which for a particular set of subcarriers (carrier system bandwidth), subframes within the set of subcarriers are dedicated for both DL and UL. In the examples provided by FIGS. 2A, 2C, the 5G NR frame structure is assumed to be TDD, with subframe 4 being configured with slot format 28 (with mostly DL), where D is DL, U is UL, and F is flexible for use between DL/UL, and subframe 3 being configured with slot format 1 (with all UL). While subframes 3, 4 are shown with slot formats 1, 28, respectively, any particular subframe may be configured with any of the various available slot formats 0-61. Slot formats 0, 1 are all DL, UL, respectively. Other slot formats 2-61 include a mix of DL, UL, and flexible symbols. UEs are configured with the slot format (dynamically through DL control information (DCI), or semi-statically/statically through radio resource control (RRC) signaling) through a received slot format indicator (SFI). Note that the description infra applies also to a 5G NR frame structure that is TDD.

FIGS. 2A-2D illustrate a frame structure, and the aspects of the present disclosure may be applicable to other wireless communication technologies, which may have a different frame structure and/or different channels. A frame (10 ms) may be divided into 10 equally sized subframes (1 ms). Each subframe may include one or more time slots. Subframes may also include mini-slots, which may include 8, 4, or 2 symbols. Each slot may include 14 or 12 symbols, depending on whether the cyclic prefix (CP) is normal or extended. For normal CP, each slot may include 14 symbols, and for extended CP, each slot may include 12 symbols. The symbols on DL may be CP orthogonal frequency division multiplexing (OFDM) (CP-OFDM) symbols. The symbols on UL may be CP-OFDM symbols (for high throughput scenarios) or discrete Fourier transform (DFT) spread OFDM (DFT-s-OFDM) symbols (for power limited scenarios; limited to a single stream transmission). The number of slots within a subframe is based on the CP and the numerology. The numerology defines the subcarrier spacing (SCS) (see Table 1). The symbol length/duration may scale with 1/SCS.

TABLE 1
Numerology, SCS, and CP

| | SCS | |
|---|---|---|
| μ | Δf = 2^{μ} · 15[kHz] | Cyclic prefix |
| 0 | 15 | Normal |
| 1 | 30 | Normal |
| 2 | 60 | Normal, Extended |
| 3 | 120 | Normal |
| 4 | 240 | Normal |
| 5 | 480 | Normal |
| 6 | 960 | Normal |

For normal CP (14 symbols/slot), different numerologies μ 0 to 4 allow for 1, 2, 4, 8, and 16 slots, respectively, per subframe. For extended CP, the numerology 2 allows for 4 slots per subframe. Accordingly, for normal CP and numerology μ, there are 14 symbols/slot and 2^{μ} slots/subframe. The subcarrier spacing may be equal to 2^{μ}*15 kHz, where μ is the numerology 0 to 4. As such, the numerology μ=0 has a subcarrier spacing of 15 kHz and the numerology μ=4 has a subcarrier spacing of 240 kHz. The symbol length/duration is inversely related to the subcarrier spacing. FIGS. 2A-2D provide an example of normal CP with 14 symbols per slot and numerology μ=2 with 4 slots per subframe. The slot duration is 0.25 ms, the subcarrier spacing is 60 kHz, and the symbol duration is approximately 16.67 μs. Within a set of frames, there may be one or more different bandwidth parts (BWPs) (see FIG. 2B) that are frequency division multiplexed. Each BWP may have a particular numerology and CP (normal or extended).

A resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 2A, some of the REs carry reference (pilot) signals (RS) for the UE. The RS may include demodulation RS (DM-RS) (indicated as R for one particular configuration, but other DM-RS configurations are possible) and channel state information reference signals (CSI-RS) for channel estimation at the UE. The RS may also include beam measurement RS (BRS), beam refinement RS (BRRS), and phase tracking RS (PT-RS).

FIG. 2B illustrates an example of various DL channels within a subframe of a frame. The physical downlink control channel (PDCCH) carries DCI within one or more control channel elements (CCEs) (e.g., 1, 2, 4, 8, or 16 CCEs), each CCE including six RE groups (REGs), each REG including 12 consecutive REs in an OFDM symbol of an RB. A PDCCH within one BWP may be referred to as a control resource set (CORESET). A UE is configured to monitor PDCCH candidates in a PDCCH search space (e.g., common search space, UE-specific search space) during PDCCH monitoring occasions on the CORESET, where the PDCCH candidates have different DCI formats and different aggregation levels. Additional BWPs may be located at greater and/or lower frequencies across the channel bandwidth. A primary synchronization signal (PSS) may be within symbol 2 of particular subframes of a frame. The PSS is used by a UE 104 to determine subframe/symbol timing and a physical layer identity. A secondary synchronization signal (SSS) may be within symbol 4 of particular subframes of a frame. The SSS is used by a UE to determine a physical layer cell identity group number and radio frame timing. Based on the physical layer identity and the physical layer cell identity group number, the UE can determine a physical cell identifier (PCI). Based on the PCI, the UE can determine the locations of the DM-RS. The physical broadcast channel (PBCH), which carries a master information block (MIB), may be logically grouped with the PSS and SSS to form a synchronization signal (SS)/PBCH block (also referred to as SS block (SSB)). The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry DM-RS (indicated as R for one particular configuration, but other DM-RS configurations are possible) for channel estimation at the base station. The UE may transmit DM-RS for the physical uplink control channel (PUCCH) and DM-RS for the physical uplink shared channel (PUSCH). The PUSCH DM-RS may be transmitted in the first one or two symbols of the PUSCH. The PUCCH DM-RS may be transmitted in different configurations depending on whether short or long PUCCHs are transmitted and depending on the particular PUCCH format used. The UE may transmit sounding reference signals (SRS). The SRS may be transmitted in the last symbol of a subframe. The SRS may have a comb structure, and a UE may transmit SRS on one of the combs. The SRS may be used by a base station for channel quality estimation to enable frequency-dependent scheduling on the UL.

FIG. 2D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and hybrid automatic repeat request (HARQ) acknowledgment (ACK) (HARQ-ACK) feedback (i.e., one or more HARQ ACK bits indicating one or more ACK and/or negative ACK (NACK)). The PUSCH carries data, and may additionally be used to carry a buffer status report (BSR), a power headroom report (PHR), and/or UCI.

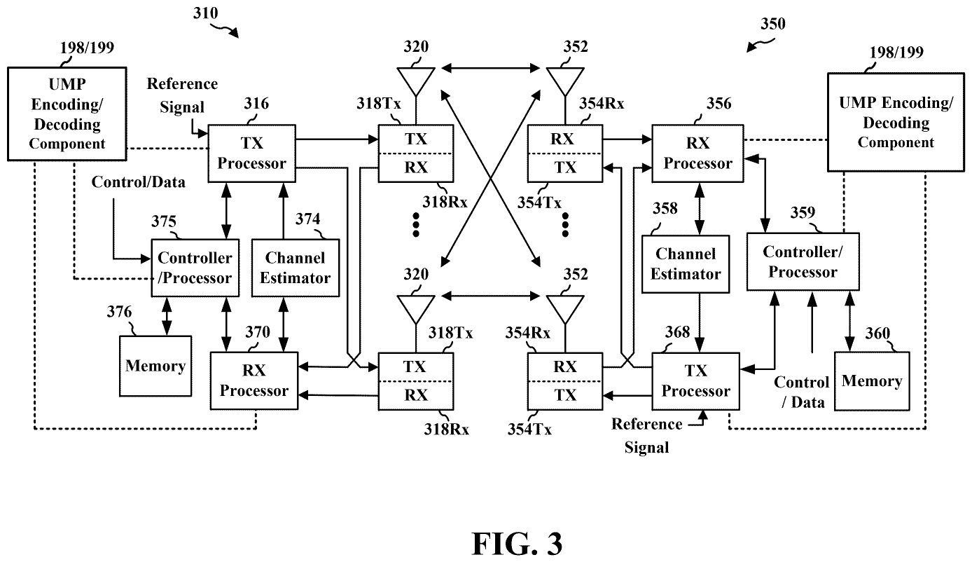

FIG. 3 is a block diagram of a base station 310 in communication with a UE 350 in an access network. In the DL, Internet protocol (IP) packets may be provided to a controller/processor 375. The controller/processor 375 implements layer 3 and layer 2 functionality. Layer 3 includes a radio resource control (RRC) layer, and layer 2 includes a service data adaptation protocol (SDAP) layer, a packet data convergence protocol (PDCP) layer, a radio link control (RLC) layer, and a medium access control (MAC) layer. The controller/processor 375 provides RRC layer functionality associated with broadcasting of system information (e.g., MIB, SIBs), RRC connection control (e.g., RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols may then be split into parallel streams. Each stream may then be mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal and/or channel condition feedback transmitted by the UE 350. Each spatial stream may then be provided to a different antenna 320 via a separate transmitter 318Tx. Each transmitter 318Tx may modulate a radio frequency (RF) carrier with a respective spatial stream for transmission.

At the UE 350, each receiver 354Rx receives a signal through its respective antenna 352. Each receiver 354Rx recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 then converts the OFDM symbol stream from the time-domain to the frequency domain using a Fast Fourier Transform (FFT). The frequency domain signal includes a separate OFDM symbol stream for each subcarrier of the OFDM signal. The symbols on each subcarrier, and the reference signal, are recovered and demodulated by determining the most likely signal constellation points transmitted by the base station 310. These soft decisions may be based on channel estimates computed by the channel estimator 358. The soft decisions are then decoded and deinterleaved to recover the data and control signals that were originally transmitted by the base station 310 on the physical channel. The data and control signals are then provided to the controller/processor 359, which implements layer 3 and layer 2 functionality.

The controller/processor 359 can be associated with at least one memory 360 that stores program codes and data. The at least one memory 360 may be referred to as a computer-readable medium. In the UL, the controller/processor 359 provides demultiplexing between transport and logical channels, packet reassembly, deciphering, header decompression, and control signal processing to recover IP packets. The controller/processor 359 is also responsible for error detection using an ACK and/or NACK protocol to support HARQ operations.

Similar to the functionality described in connection with the DL transmission by the base station 310, the controller/processor 359 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the base station 310 may be used by the TX processor 368 to select the appropriate coding and modulation schemes, and to facilitate spatial processing. The spatial streams generated by the TX processor 368 may be provided to different antennas 352 via separate transmitters 354Tx. Each transmitter 354Tx may modulate an RF carrier with a respective spatial stream for transmission.

The UL transmission is processed at the base station 310 in a manner similar to that described in connection with the receiver function at the UE 350. Each receiver 318Rx receives a signal through its respective antenna 320. Each receiver 318Rx recovers information modulated onto an RF carrier and provides the information to a RX processor 370.

The controller/processor 375 can be associated with at least one memory 376 that stores program codes and data. The at least one memory 376 may be referred to as a computer-readable medium. In the UL, the controller/processor 375 provides demultiplexing between transport and logical channels, packet reassembly, deciphering, header decompression, control signal processing to recover IP packets. The controller/processor 375 is also responsible for error detection using an ACK and/or NACK protocol to support HARQ operations.

At least one of the TX processor 368, the RX processor 356, and the controller/processor 359 may be configured to perform aspects in connection with the UMP encoding component 198 and/or the UMP decoding component 199 of FIG. 1 (e.g., in connection with a combined UMP encoding/decoding component 198/199).

At least one of the TX processor 316, the RX processor 370, and the controller/processor 375 may be configured to perform aspects in connection with the UMP encoding component 198 and/or the UMP decoding component 199 of FIG. 1 (e.g., in connection with a combined UMP encoding/decoding component 198/199).

In some aspects of electronic and/or communication different methods of encoding and decoding may be applied to provide protection against errors. Binary RM codes may be used to provide the error protection and/or a fault tolerance with different Binary RM codes providing different levels of error protection and/or fault tolerance.

Binary RM codes are a family of binary linear block codes that are defined by two parameters, m and r. In particular, a RM(m, r) code has a blocklength n=2^{m} (e.g., a RM(m, r) code may be referred to as being of length 2^{m}), may be of order r, and may have a dimension

$$k = {\sum }_{t = 0}^{r} ( \begin{matrix}m \\ t\end{matrix} ) , where ( \begin{matrix}m \\ t\end{matrix} )$$

is the number of unique combinations of t members selected from a group of m candidates. An RM(m, r) code is further associated with a minimum distance (a minimum Hamming distance) d=2^{m-r}. The encoding process is described through evaluations of a multivariate polynomial over [symbol] ₂. For example, Let {X₁, . . . , Xₘ} be a collection of variables over [symbol] ₂ and for each subset (S) of members of the set {1, 2, . . . , m} (e.g., for SE {1, 2, . . . , m}), let X_{S}=Π_{i∈S}Xᵢ be a monomial term where each variable has a degree of at-most 1 (as any higher power of a variable in [symbol] ₂ is equal to the variable). For example, for m=3, X_{S} may be equal to {X₁, X₁X₂, X₁X₃, X₂X₃, X₁X₂X₃} for S={(1), (1, 2), (1, 3), (2, 3), (1, 2, 3)}. Let |S| denote the size of S and define:

$$f ( {X}_{1} , ... , {X}_{m} ) = {\sum }_{S ⊆ \{ 1 , 2 , ... , m \} : \vert S \vert \leq r} {C}_{S} {X}_{S} \qquad ( eq . 1 )$$

where M is the number of subsets S of the set {1, 2, . . . , m} indexed from 1 to M that are at most size r (e.g., for which |S|≤r) and each C_{S}∈ [symbol] ₂. Given a sequence of information symbols {C_{S}}, the codeword in the RM(m, r) code may be obtained by evaluating ƒ(X₁, . . . , Xₘ) for each choice of (X₁, . . . , Xₘ)∈ [symbol] ₂^{m}. The order r coefficients of a RM(m, r) code are those C_{S} where |S|=r.

The RM(m, r) code can also be described in terms of a generator matrix of the form:

$$G = [ \begin{matrix}{G}_{m} \\ {G}_{m - 1} \\ ⋮ \\ {G}_{1} \\ {G}_{0}\end{matrix} ] \qquad ( eq . 2 )$$

where for an RM code of order r, Gᵢ=0 for i>r and where G₀ is a vector of length 2^{m} consisting of all 1's. G₁ is a matrix of size m×2^{m} where each column is a distinct binary vector of length m. Furthermore, the rows of Gⱼ for j>1 are obtained by taking all possible sets of j rows of G₁ and taking their element-wise product, accordingly, Gⱼ has

$$( \begin{matrix}m \\ j\end{matrix} )$$

rows. The RM code, in some aspects, may be characterized as an [n, k, d] code with length (or block length n, dimension k, and minimum distance d, where the dimension may correspond to the number of information bits carried by the n bits of a codeword.

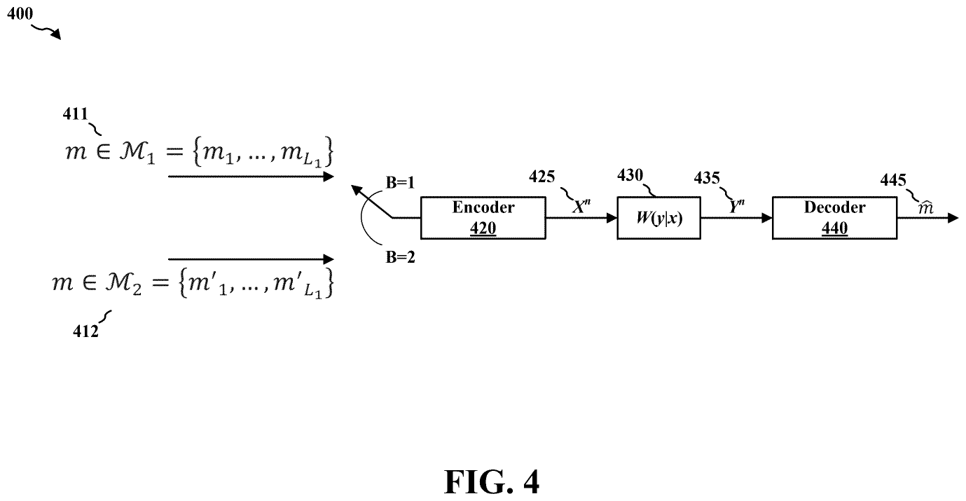

FIG. 4 is a diagram 400 illustrating aspects of UMP in accordance with some aspects of the disclosure. UMP, in some aspects, may be used whenever a set of messages or data to be transmitted can be broken into a first subset and a second subset. For example, a set of messages, [symbol] , may be broken up into a first subset of the messages 411, [symbol] ₁={m₁, . . . , m_{M}_{₁}}, and a second set of the messages 412, [symbol] ₂={m_{M}_{₁}₊₁, . . . , m_{M}}, where [symbol] = [symbol] ₁∪ [symbol] ₂. The first subset of the messages, [symbol] ₁, and the second subset of the messages, [symbol] ₂, may correspond to different classes of messages. In some aspects, the first subset of the messages, [symbol] ₁, may be referred to as important messages, and the second subset of the messages, [symbol] ₂, may be referred to as ordinary messages. An encoder 420, encoding device, or encoding method may be associated with a mapping [symbol] : [symbol] → [symbol] ⁿ where [symbol] is the channel input alphabet and n is the block-length. We let xⁿ= [symbol] (m) 425 be the channel input sequence associated with the message m. In some aspects, the encoding at the encoder 420 may include receiving a particular message, identifying whether it is in the first subset of the messages ( [symbol] ₁) or the second subset of the messages ( [symbol] ₂) and mapping (e.g., based on a one-to-one, or unique, mapping) the particular message to one of a set of bits or a set of codewords associated with the identified subset of messages.

The channel may be a memoryless channel 430 with the transition probability W(y|x). Given an input sequence 425 (e.g., xⁿ in Xⁿ), the memoryless channel generates and outputs a sequence 435

$$( e . g . , {x}^{n} ∼ {\prod }_{i = 1}^{n} W ( {y}_{i} \vert {x}_{i} ) or {Y}^{n} ) .$$

A corresponding decoder 440, decoding device, or decoding method may be associated with a mapping [symbol] : [symbol] ⁿ→ [symbol] . A decoded message 445 may be defined as \hat{m}= [symbol] (yⁿ). For UMP, a first error threshold term, ϵ₁, and a second error threshold term, ϵ₂, may be defined for an (ϵ₁, ϵ₂) UMP. The (ϵ₁, ϵ₂) UMP may be associated with an encoder and decoder pair ( [symbol] , [symbol] ) such that P (m≠\hat{m}/m∈ [symbol] ᵢ)≤ϵᵢ for each i∈{1,2}. In some aspects, the decoder may not be aware of the subset of the messages associated with a particular received codeword.

UMP may be practiced in various contexts and/or setting. For a first example, UMP may be practiced in relation to the transmission of control signals in wireless communications (e.g., for 4G NR or 6G). For a communication setting including communication between a base station and a UE, where the base station transmits a sequence of data packets to the UE and the UE responds with a (binary) sequence of ACKs and/or NACKs corresponding to the sequence of data packets to indicate successful and/or unsuccessful decoding of the data packets. Typically, the length of such a feedback sequence is rather small (10-30 bits). Since the feedback happens over a wireless channel, it is to be protected from errors. The UMP setting naturally applies here as it is often more expensive to interpret a NACK as an ACK than vice versa. Thus, one could define [symbol] ₁ (e.g., which may be the more important message set) as those sequences where the number of NACKs is above a certain threshold and [symbol] ₂ (e.g., which may be a less important message set) as those sequences where the number of NACKs is below that threshold. The choice of the threshold may be application dependent.

As a second example, UMP may be practiced in relation to the transmission of artificial intelligence (AI) and/or machine learning (ML) (AI/ML) generated traffic. For a setting and/or context where a UE acquires live video streams that are partially processed on device (e.g., at the UE) using a deep learning model (e.g., as an example of an AI/ML method) and then transmitted over a communication channel to a remote node for further downstream task processing. In the application of multi-task learning, different tasks may have different target error rates. This leads to a UMP setting for the communication systems where the messages generated at the UE belonging to different tasks may benefit from having different levels of error protection.

Accordingly, for a practical application of UMP, messages defined to be in the first subset of messages [symbol] ₁ (e.g., messages with a threshold number of NACK's when used in association with ACK/NACK messages or associated with a first task having a lower target error rate), in some aspects, may be mapped to one of a set of bits for encoding with a first RM code of a first order or a codeword of the first RM code of the first order. Similarly, in some aspects, messages defined to be in the second subset of messages [symbol] ₂ may be mapped to one of another set of bits for encoding with a second RM code of a second order or a codeword of the second RM code, where the first RM code is a subcode of the second RM code. In some aspects, there may be a one-to-one mapping between messages in the first subset of messages and codewords of the first RM and a one-to-one mapping between messages in the second subset of messages and a subset of the codewords of the second RM, where the subset of the codewords of the second RM does not include the codewords of the first RM code.

In some aspects, the framework presented below may be extended to include more message classes with different levels of importance if called for by the setting and/or application. The different message classes may be associated with different subcodes of a highest-order RM code (where each subcode is a lower-order RM code of a same length as the highest-order RM code). In the examples above, a decoder may be used that can achieve target error rates for the different subsets of messages without explicit indication of the subset of the messages associated with any particular codeword received by (or to be decoded by) the decoder. In some aspects, the decoder and/or decoding algorithm (or method) associated with the UMP may reduce a number of operations (on average) to decode a set of received codewords when compared to a standard decoding of codewords associated with the highest-order RM code (e.g., the second RM code in the ACK/NACK example above). Additionally, the decoder and/or decoding algorithm (or method) associated with the UMP may reduce a number of operations (on average) to decode a set of received codewords while achieving the target error rates of the first subset of messages when compared to a standard decoding of codewords associated with achieving the target error rates of the first subset of the messages.

Various aspects relate generally to the use of RM codes for UEC and/or UMP for different messages. Some aspects more specifically relate to an encoder that encodes different classes of messages (e.g., two or more classes that may include a first class of message that may be more important messages and a second class of messages that may be less important messages, among other examples) using different RM codes based on an associated threshold error tolerance and corresponding decoders. In some examples, an encoding device, may be configured to obtain a plurality of messages comprising a first subset of the plurality of messages and a second subset of the plurality of messages, encode the first subset of the plurality of messages into a first set of codewords associated with a first RM code, encode the second subset of the plurality of messages into a second set of codewords associated with a second RM code, where the first RM code is a subcode of the second RM code, and transmit, to a decoder device, the plurality of codewords. In some examples, a decoder, or decoding, device may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages.

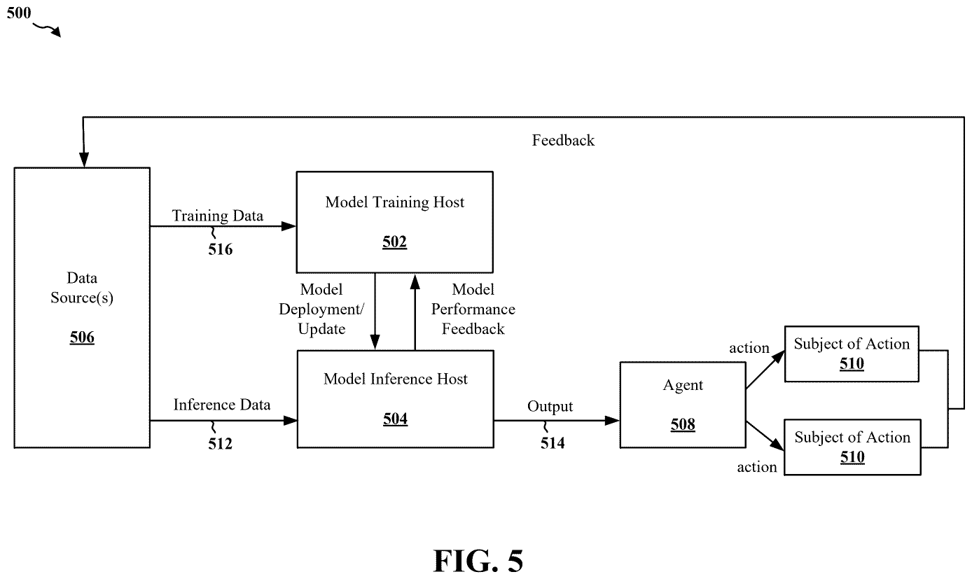

FIG. 5 is an illustrative block diagram of an example ML architecture 500 that may be used for wireless communications in any of the various implementations, processes, environments, networks, or use cases listed above. As illustrated, architecture 500 includes multiple logical entities, such as model training host 502, model inference host 504, data source(s) 506, and agent 508. Model inference host 504 is configured to run an ML model based on inference data 512 provided by data source(s) 506. Model inference host 504 may produce output 514, which may include a prediction or inference, such as a discrete or continuous value based on inference data 512, which may then be provided as input to the agent 508.

Agent 508 may represent an element or an entity of a wireless communication system including, for example, a radio access network (RAN), a wireless local area network, a device-to-device (D2D) communications system, etc. As an example, agent 508 may be a user equipment (such as UE 104, referring to FIG. 1, for example), a base station (such as base station 102, referring to FIG. 1, for example), or a disaggregated network entity (such as a CU 110, DU 130, or RU 140 in FIG. 1), an access point, a wireless station, a RAN intelligent controller (RIC) in a cloud-based RAN, among some examples. Additionally, agent 508 may also be a type of agent that depends on the type of tasks performed by model inference host 504, the type of inference data 512 provided to model inference host 504, or the type of output 514 produced by model inference host 504.

The AI/ML architecture may be associated with a RM decoder for UMP and illustrates various aspects model training, model inference, model feedback, and model update.

Agent 508 may perform one or more actions associated with receiving output 514 from model inference host 504, e.g., decoding of a transmission. Agent 508 may indicate the one or more actions performed to at least one subject of action 510. In some cases, agent 508 and the subject of action 510 are the same entity.

Data can be collected from data sources 506, and may be used as training data 516 for training an ML model, or as inference data 512 for feeding an ML model inference operation. Data sources 506 may collect data from various subject of action 510 entities (such as the UE or the network entity) and provide the collected data to a model training host 502 for ML model training. In some examples, if output 514 provided to agent 508 is inaccurate (or the accuracy is below an accuracy threshold), model training host 502 may provide feedback to model inference host 504 to modify or retrain the ML model used by model inference host 504, such as via an ML model deployment update.

The data collection may be a function that provides input data for the model training and the model inference. The data collection function may include any form of data preparation, and it may not be specific to the implementation of the AI/ML algorithm (e.g., data pre-processing and cleaning, formatting, and transformation).

The examples of input data may include, but are not limited to, multiple projections generated by a recursive projection-aggregation (RPA) decoding method for RM codes applied to a test codeword encoded with one of any number of RM codes (e.g., the first RM code or the second RM code) and (2) an indication of which RM code (e.g., whether the first RM code or the second RM code) was used to encode the test codeword, feedback from the actor (e.g., which may be a UE or network node), output from another AI/ML model. The data collection may include training data, which refers to the data to be sent as the input for the AI/ML model training, and inference data, which refers to data input for the AI/ML model inference. While discussed using an example of RPA decoding, other decoding methods may use, or be associated with, different types of input data for model training or for model inference.

The model training may be a function that performs the ML model training, validation, and testing, which may generate model performance metrics as part of the model testing procedure. The model training may also include data preparation (e.g., data pre-processing and cleaning, formatting, and transformation) based on the training data delivered or received from the data collection function. The model training component may deploy or update a trained, validated, and tested AI/ML model to the model inference component, and receive a model performance feedback from the model inference component. As described above, there may be various functionalities to be performed by an AI/ML model for wireless communication

The model inference may be a function that provides the AI/ML model inference output (e.g., predictions or decisions). The model inference may also perform data preparation (e.g., data pre-processing and cleaning, formatting, and transformation) based on the inference data delivered from the data collection function. The output of the model inference may include the inference output of the AI/ML model produced by the model inference. The details of the inference output may be use case specific. As an example, the output may include decoded codewords. The decoding may be for the transmitter or the receiver and may be for the network or the UE. In some aspects, the actor may be a component of the base station or of a core network. In other aspects, the actor may be a UE in communication with a wireless network.

The model performance feedback may refer to information derived from the model inference function that may be suitable for the improvement of the AI/ML model trained in the model training. The feedback from the actor or other network entities (via the data collection function) may be implemented for the model inference to create the model performance feedback.

Model training host 502 may be deployed at the same or a different entity than that in which model inference host 504 is deployed. For example, in order to offload model training processing, which can impact the performance of model inference host 504, model training host 502 may be deployed at a model server.

The actor may be a function that receives the output from the model inference and triggers or performs corresponding actions. The actor may trigger actions directed to network entities including the other network entities or itself. The actor may also provide a feedback information that the model training or the model inference to derive training or inference data or performance feedback. The feedback may be transmitted back to the data source 506.

A network or UE may use machine-learning algorithms, deep-learning algorithms, neural networks, reinforcement learning, regression, boosting, or advanced signal processing methods for aspects of wireless communication including the various functionalities of decoding and/or identifying codewords as being associated with a particular subset of messages in a plurality of subsets of messages defined for the UMP encoding/decoding.

In some aspects described herein, the network may train one or more neural networks to learn the dependence of measured qualities on individual parameters. Among others, examples of machine learning models or neural networks that may be included in the network entity include artificial neural networks (ANN); decision tree learning; convolutional neural networks (CNNs); deep learning architectures in which an output of a first layer of neurons becomes an input to a second layer of neurons, and so forth; support vector machines (SVM), e.g., including a separating hyperplane (e.g., decision boundary) that categorizes data; regression analysis; Bayesian networks; genetic algorithms; deep convolutional networks (DCNs) configured with additional pooling and normalization layers; and deep belief networks (DBNs).

A machine learning model, such as an ANN, may include an interconnected group of artificial neurons (e.g., neuron models), and may be a computational device or may represent a method to be performed by a computational device. The connections of the neuron models may be modeled as weights. Machine learning models may provide predictive modeling, adaptive control, and other applications through training via a dataset. The model may be adaptive based on external or internal information that is processed by the machine learning model. Machine learning may provide non-linear statistical data model or decision making and may model complex relationships between input data and output information.

A machine learning model may include multiple layers and/or operations that may be formed by the concatenation of one or more of the referenced operations. Examples of operations that may be involved include extraction of various features of data, convolution operations, fully connected operations that may be activated or deactivated, compression, decompression, quantization, flattening, etc. As used herein, a “layer” of a machine learning model may be used to denote an operation on input data. For example, a convolution layer, a fully connected layer, and/or the like may be used to refer to associated operations on data that is input into a layer. A convolution A×B operation refers to an operation that converts a number of input features A into a number of output features B. “Kernel size” may refer to a number of adjacent coefficients that are combined in a dimension. As used herein, “weight” may be used to denote one or more coefficients used in the operations in the layers for combining various rows and/or columns of input data. For example, a fully connected layer operation may have an output y that is determined based at least in part on a sum of a product of input matrix x and weights A (which may be a matrix) and bias values B (which may be a matrix). The term “weights” may be used herein to generically refer to both weights and bias values. Weights and biases are examples of parameters of a trained machine learning model. Different layers of a machine learning model may be trained separately.

Machine learning models may include a variety of connectivity patterns, e.g., any feed-forward networks, hierarchical layers, recurrent architectures, feedback connections, etc. The connections between layers of a neural network may be fully connected or locally connected. In a fully connected network, a neuron in a first layer may communicate its output to each neuron in a second layer, and each neuron in the second layer may receive input from every neuron in the first layer. In a locally connected network, a neuron in a first layer may be connected to a limited number of neurons in the second layer. In some aspects, a convolutional network may be locally connected and configured with shared connection strengths associated with the inputs for each neuron in the second layer. A locally connected layer of a network may be configured such that each neuron in a layer has the same, or similar, connectivity pattern, but with different connection strengths.

A machine learning model or neural network may be trained. For example, a machine learning model may be trained based on supervised learning. During training, the machine learning model may be presented with input that the model uses to compute to produce an output. The actual output may be compared to a target output, and the difference may be used to adjust parameters (such as weights and biases) of the machine learning model in order to provide an output closer to the target output. Before training, the output may be incorrect or less accurate, and an error, or difference, may be calculated between the actual output and the target output. The weights of the machine learning model may then be adjusted so that the output is more closely aligned with the target. To adjust the weights, a learning algorithm may compute a gradient vector for the weights. The gradient may indicate an amount that an error would increase or decrease if the weight were adjusted slightly. At the top layer, the gradient may correspond directly to the value of a weight connecting an activated neuron in the penultimate layer and a neuron in the output layer. In lower layers, the gradient may depend on the value of the weights and on the computed error gradients of the higher layers. The weights may then be adjusted so as to reduce the error or to move the output closer to the target. This manner of adjusting the weights may be referred to as back propagation through the neural network. The process may continue until an achievable error rate stops decreasing or until the error rate has reached a target level.

The machine learning models may include computational complexity and substantial processor for training the machine learning model. An output of one node is connected as the input to another node. Connections between nodes may be referred to as edges, and weights may be applied to the connections/edges to adjust the output from one node that is applied as input to another node. Nodes may apply thresholds in order to determine whether, or when, to provide output to a connected node. The output of each node may be calculated as a non-linear function of a sum of the inputs to the node. The neural network may include any number of nodes and any type of connections between nodes. The neural network may include one or more hidden nodes. Nodes may be aggregated into layers, and different layers of the neural network may perform different kinds of transformations on the input. A signal may travel from input at a first layer through the multiple layers of the neural network to output at the last layer of the neural network and may traverse layers multiple times.

The structure of RM codes, in some aspects, admits a natural encoding strategy. For a first message set [symbol] ₁ (which may be a more important message set) with size m₁=2^{k}^{₁} where

$${k}_{1} = {\sum }_{t = 0}^{r} ( \begin{matrix}m \\ t\end{matrix} )$$

and the second message set [symbol] ₂ (which may be a less important message set) with size m₂=2^{k}−2^{k}^{₁} where

$$k = {\sum }_{t = 0}^{s + r} ( \begin{matrix}m \\ t\end{matrix} ) .$$

In other words, for the message set [symbol] ₁, there are m₁=2^{k}^{₁} different messages that may be sent encoded into m₁=2^{k}^{₁} codewords, and, for the message set [symbol] ₂, there are m₂=2^{k}−2^{k}^{₁} different messages that may be sent encoded into m₂=2^{k}−2^{k}^{₁} codewords. In some aspects, this situation may correspond to a set of k-bit messages with a first subset of the messages (e.g., 2^{k}^{₁} of the 2^{k} possible messages that may be encoded by k bits) identified as being more important for encoding into a set of codewords (which may be a particular set of codewords or may be considered special codewords) with a higher error tolerance (e.g., a lower target error rate, a greater capacity to correct errors, or a larger number of errors that may be corrected). The particular set of codewords (e.g., special codewords) may be a subset of the codewords associated with the RM(m, r+s) code that are also associated with the RM(m, r) subcode of the RM(m,r+s) code and may correspond to a codeword generated by setting information symbols (or bits) associated with the rows in Gᵣ₊₁, . . . , Gᵣ₊ₛ to zero. For example, a set of 2^{k}^{₁} messages (e.g., which may be identified as being more important to correctly decode) may be mapped to a set of input bit strings including all zeros in positions associated with rows Gᵣ₊₁, . . . , Gᵣ₊ₛ of the generator matrix G associated with the RM(m,r+s) code and then encoded using the generator matrix G associated with the RM(m, r+s) code. Alternatively, the first subset of messages may be directly mapped to the particular set of codewords based on a known, or configured, mapping (e.g., a mapping known to the encoder and a decoder or recipient of decoded codewords). On the other hand, the second subset of messages can be mapped to all other codewords of the RM(m, r+s) code. The differential encoding, by itself, may not provide additional (or unequal) protection to some messages. The unequal protection, in some aspects, may be provided by a corresponding decoding. The corresponding decoding, in some aspects, may be more efficient based on the differential encoding described above.

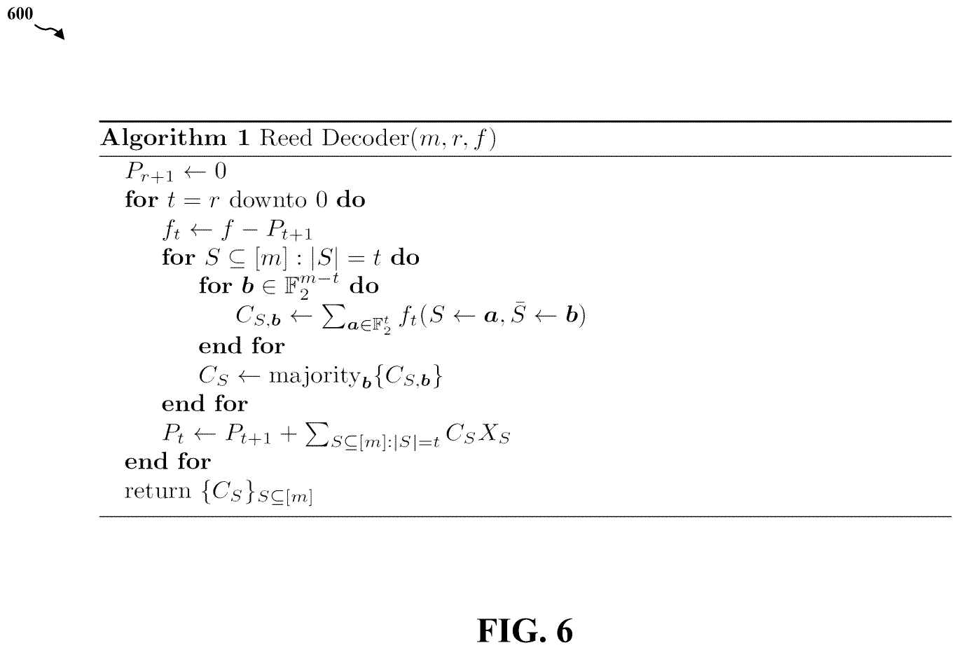

FIG. 6 is a diagram 600 illustrating pseudocode for a (standard) Reed decoding algorithm for decoding Reed-Muller codes in accordance with some aspects of the disclosure. It exploits the multi-variate polynomial representation and is guaranteed to produce the correct output if the number of errors in the received codeword is (strictly) less than half the minimum distance. It proceeds by first decoding all order r coefficients and, once these are fixed, it proceeds by decoding all order r−1 coefficients, and so on. The Reed decoder illustrated in diagram 600 has complexity O(nr) and works whenever the message contains less than 2^{m-r-1} errors. For example, the decoding may be based on a first codeword length based on m, an order r, and a received codeword ƒ associated with an RM(m, r) code. A generator matrix associated with the RM(m, r) code may have a first number of rows corresponding to a first number of bits in each decoded codeword. Each row of the generator matrix, in some aspects, uniquely corresponds to an order of the RM code, where a particular order of the RM code may correspond to one of a single row or multiple rows of the generator matrix.

In some aspects, the decoding for a received codeword corresponding to an encoded message (e.g., a message provided to an encoder) may include setting a current order of the decoder to be r and a current codeword to be the received codeword ƒ. The Reed decoding algorithm may determine, for each row of the generator matrix corresponding to the current order of the decoder and until the current order is decremented below zero, a corresponding bit value based on a majority-based thresholding operation (e.g., majority_{b}) performed on a set of binary values (e.g., {C_{S,b}}) associated with a set of linear combinations of bits in the current codeword (e.g., C_{S}←majority_{b}{C_{S,b}}). Based on the determined corresponding bit values the Reed decoding algorithm may calculate an updated codeword (e.g., may calculate Pₜ←Pₜ₊₁+Σ_{S⊆[m]:|S|=t}C_{S} X_{S} and ƒₜ←ƒ−Pₜ₊₁, where Pᵣ₊₁ is initialized to 0 and a current order value, t, begins at r). The current order is then decremented and the updated codeword is then used for decoding the corresponding bit value for each row of the generator matrix corresponding to the current order of the decoder. The Reed decoding algorithm may, after decoding the order zero bit (e.g., there is one row corresponding to r=0) return the determined corresponding bit values as the message encoded into the received codeword.

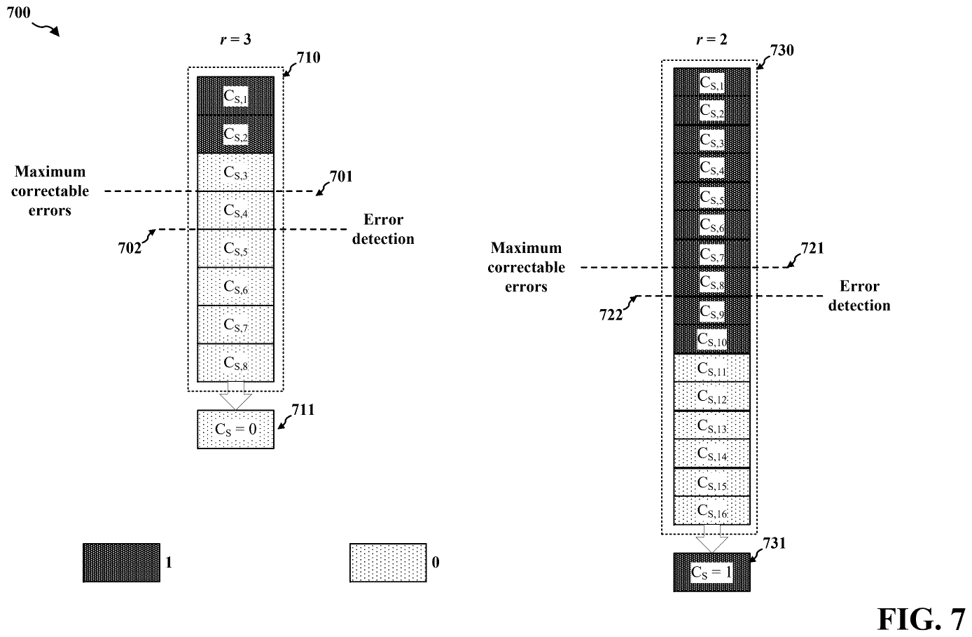

FIG. 7 is a diagram 700 illustrating majority voting in the context of a Reed decoder in accordance with some aspects of the disclosure. For example, for an RM(6,3) code with a block length 64 (e.g., 2⁶), a decoding for t=3 may result in a set of 2^{m-t}=2³, or 8, cosets and corresponding set of values 710 (e.g., C_{S,b} for b∈[1, . . . , 2^{m-t}]) for a related coefficient C_{S} 711, where C_{S} 711 is determined based on the majority of the values of the related C_{S,b}. The majority voting for t=3, in some aspects, may be associated with a maximum correctable error 701 that is strictly less than half the number of cosets and/or corresponding values and an error detection value 702 that is half the number of cosets and/or corresponding values. Similarly, a decoding for t=2 may result in a set of 2^{m-t}=2⁴, or 16, cosets and corresponding set of values 730 (e.g., C_{S,b} for b∈[1, . . . , 2^{m-t}]) for a related coefficient C_{S} 731, where C_{S} 731 is determined based on the majority of the values of the related C_{S,b}. The majority voting for t=2, in some aspects, may be associated with a maximum correctable error 721 that is strictly less than half the number of cosets and/or corresponding values and an error detection value 722 that is half the number of cosets and/or corresponding values.

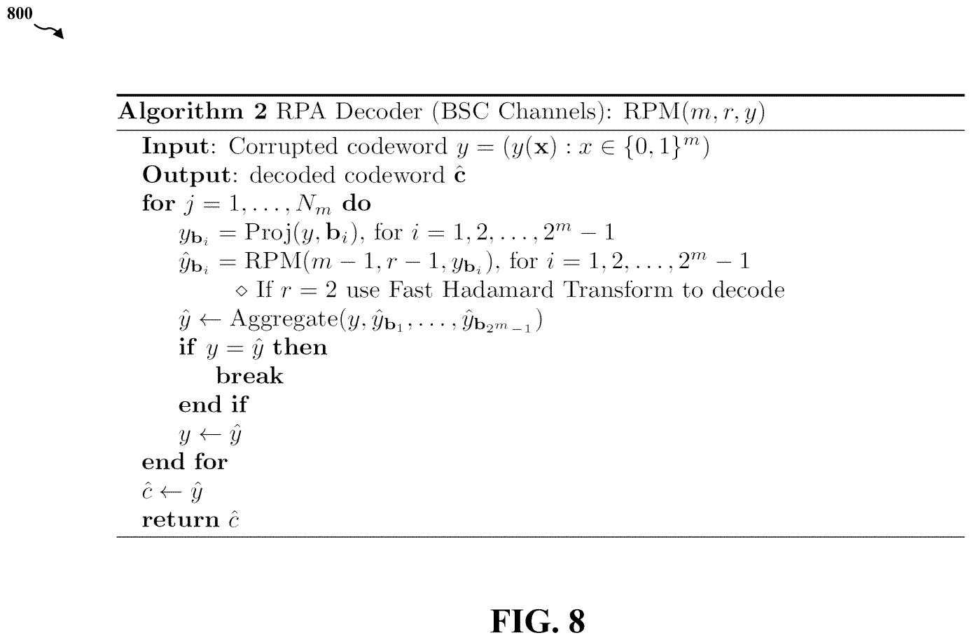

FIG. 8 is a diagram 800 illustrating pseudocode for the RPA decoding algorithm for decoding Reed-Muller codes in accordance with some aspects of the disclosure. The RPA decoding algorithm is based on the observation that order one Reed-Muller codes, i.e., RM(m, 1) codes, have a fast decoding algorithm, namely the Fast Hadamard Transform (FHT). The RPA algorithm recursively projects higher order RM codes to construct lower order RM codes and then uses the FHT to decode order one RM codes. The recursion may include multiple rounds of each recursive step. For example, a particular recursive step may be repeated a maximum number (Nₘ) times, or until a decoded codeword at the current level of the recursion converges such that the input codeword to the current level of the recursion is the same as the decoded codeword at the current level of the recursion. In some aspects, the condition that “If r=2 use Fast Hadamard Transform to decode” may be restated as the behavior for a call to RPM (m, 1, y), e.g., a definition of a lowest level of recursion for any m and y that can serve as the basis of resolving previous calls to the RPM (m, r, y) function for r>1.

Based on the definition of the RM(m, r) code, the decoding of the RM(m, r) code, in some aspects, involves evaluating a multivariate polynomial, see eq. 1, over n=2^{m} evaluation points. Any codeword can be expressed as {c(x)}_{x∈{0,1}}_{^{m}} where c(⋅) is the multivariate polynomial defined by the information symbols C_{S}. To define a projection of this code over a one-dimensional space, let b∈{0,1}^{m} be an arbitrary non-zero vector. We consider all possible 2^{m-1} cosets generated by b of the form Tₓ={x, x⊕b}, x∈{0,1}^{m} and define c(Tₓ)=c(x)⊕c(x⊕b). The one-dimensional projection of a codeword {c(x)} with respect to a nonzero vector b is the collection of c(Tₓ) over all the cosets Tₓ generated by b (that mat be denoted by c_{b}(⋅). It is known that for any non-zero b the projected codewords constitute a RM(m−1,r−1) code.

Consider a RM(3,1) which is defined by the following polynomial: ƒ(x₁, x₂, x₃)=v₀+v₁x₁+v₂x₂+v₃x₃. The RM(3,1) codewords are obtained by evaluating ƒ(⋅) over all possible vectors x∈{0,1}³. The codewords are of the form: (v₀, v₀+v₁, v₀+v₂, v₀+v₃, v₀+v₁+v₂, v₀+v₁+v₃, v₀+v₂+v₃, v₀+v₁+v₂+v₃) where all addition is over the binary field. The projection of the codewords with respect to a vector b=(1,1,1) is constructed as follows: for the coset T={(0,0,0), (1,1,1)} we obtain c(T)=v₀+v₀+v₁+v₂+v₃=v₁+v₂+v₃. For T={(0,0,1), (1,1,0)} we obtain c(T)=v₀++v₃+v₀+v₁+v₂=v₃+v₁+v₂ and so on. In fact, it can be seen that in this case the projected codeword is a length 4 sequence of the form (v₁+v₂+v₃, v₁+v₂+v₃, v₁+v₂+v₃, v₁+v₂+v₃), which constitutes a RM(2,0) code (a repetition code). It can also be easily verified that the projection of RM(m, 0) code on any non-zero sequence will always lead to all zero codewords.

The decoder illustrated in FIG. 8 accepts a noisy version of the transmitted codeword (e.g., y) as input. It generates successive projections and recursively decodes these projections. When the codewords are order-1 codes, the FHT decoder is used. Once the projected codewords are decoded, a method is used to use the decoded codewords to produce a decoded version of y, e.g., ĉ. This is the role of the Aggregate (⋅) function. The proposal for this function is the following: Let [z+bᵢ] denote the coset which contains the sequence z upon projection with respect to bᵢ. Then we define the following function:

$$changevote ( z ) = \frac{1}{n - 1} {\sum }_{i = 1}^{n - 1} [ {y}_{{b}_{i}} [ z + {b}_{i} ] \neq {\hat{y}}_{{b}_{i}} [ z + {b}_{i} ] ] .$$

Note that the above function computes the number of times the projection of y(z) agrees with the decoded sequences. If there are too many disagreements then the received symbol is flipped. The aggregate function is defined by the following relation: y(z)←y(z) ⊕[changevote(z)>0.5]. The algorithm may be extended to binary input AWGN channels. For example, instead of propagating projections, we may propagate the likelihood values. In the aggregation function, the likelihood values may be updated as follows. If we let L(z) denote the likelihood value for a position associated with z. We may define the following:

$$cumLLR ( z ) ← \frac{1}{n - 1} {\sum }_{i = 1}^{n - 1} {a}_{i} \cdot L ( z + {b}_{i} ) where {a}_{i} = \{ \begin{matrix}1 : {\hat{y}}_{{b}_{i}} [ z + {b}_{i} ] = 0 \\ - 1 : {\hat{y}}_{{b}_{i}} [ z + {b}_{i} ] = 1\end{matrix} \} .$$

In some aspects, a soft aggregation function that uses likelihoods of the decoded codewords may be applied as follows:

$$cumLLR ( z ) ← \frac{1}{n - 1} {\sum }_{i = 1}^{n - 1} {w}_{i} \cdot tanh ( {\hat{l}}_{q} ( \frac{[ z + {b}_{i} ]}{2} ) L ( z + {b}_{i} ) ) ,$$

where \hat{l}_{q} denotes the likelihoods of the projected codewords and wᵢ are coefficients that are learned using a deep-learning framework.

The Reed Muller code may be adapted to support the UMP scheme for two or more message classes. For simplicity, we start with the assumption we have two message classes [symbol] ₁ and [symbol] ₂, respectively with 2^{k}^{₁} and 2^{k}^{₁}^{+k}^{₂}−2^{k}^{₁} (or 2^{k}−2^{k}^{₁}) elements, where

$${k}_{1} = {\sum }_{t = 0}^{r} ( \begin{matrix}m \\ t\end{matrix} ) , {k}_{2} = {\sum }_{t = r + 1}^{s + r} ( \begin{matrix}m \\ t\end{matrix} ) , and k = {\sum }_{t = 0}^{s + r} ( \begin{matrix}m \\ t\end{matrix} ) ,$$

for certain integers m 0, and r, s≥0. The combined message classes contain in total k₁+k₂=k messages and could be encoded by using a Reed Muller code (e.g., a RM(m,r+s) code) and decoded by using Algorithm 1 with an error tolerance of 2^{m-r-s-1} errors (an ability to correct up to, but not including 2^{m-r-s-1} errors) for any message. Under the UMP scheme, a larger and/or higher tolerance (t₁, θ₁, or ρ₁>2^{m-r-s-1}) is selected for messages from [symbol] ₁, while allowing a (resulting) smaller and/or lower tolerance (t₂, θ₂, or ρ₂<2^{m-r-s-1}) for messages in [symbol] ₂, where the variable tᵢ, θᵢ, or ρᵢ may be used interchangeably depending on the context. Thus, we support the UMP property by providing a higher error tolerance threshold for messages in [symbol] ₁ and a lower error tolerance threshold for message in [symbol] ₂.

We can achieve this via a smart combination of two codes an RM(m, r) code and a RM(m,r+s) code. First, it may be noted that because both codes produce codewords of length n=2^{m} bits, a received corrupted codeword can be decoded under both codes. Then, at a high level some aspects may generally be associated with, for a received codeword at a distance, e.g., a Hamming distance, smaller than t₁ (or ρ₁) from a nearest codeword of the RM(m, r) code, decoding the received codeword as the nearest codeword of the RM(m, r) code. Otherwise, for a received codeword at a distance, e.g., a Hamming distance, larger than t₁ (or ρ₁) from a nearest codeword of the RM(m, r) code, the received codeword may be decoded to be a nearest codeword of the RM(m, r+s) code. In some aspects, this may be associated with applying a decoding based on the RM(m, r) code for a received codeword at a distance smaller than t₁ (or ρ₁) from a codeword in the set of codewords associated with RM(m, r) and, otherwise, applying a decoding based on the RM(m, r+s) code, e.g. using majority voting. Before providing additional details of UMP methods, a simple example for r=0, s=1, and m=2, such that we have a first class and/or subset of messages, [symbol] ₁, with 2 messages and a second class and/or subset of messages, [symbol] ₂, with 6 messages.

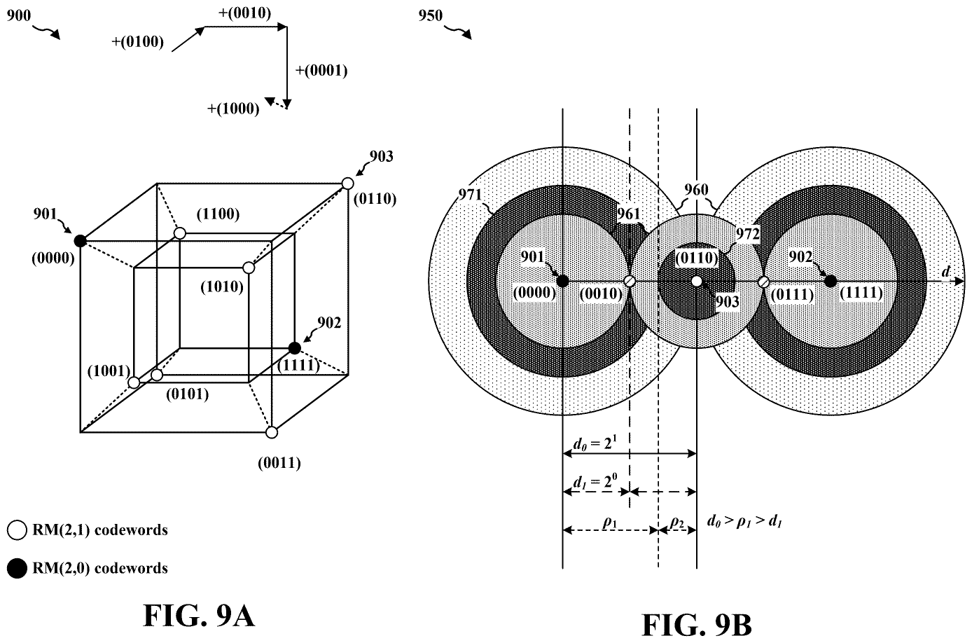

FIG. 9A is a diagram 900 illustrating a 4-dimensional hypercube representing the codewords of a RM(2,1) code and a RM(2,0) code in accordance with some aspects of the disclosure. The RM(2,1) code and the RM(2,0) code, in some aspects may be associated with the generator matrix

$${G}_{( 2 , 1 )} = [ \begin{matrix}1 & 1 & 0 & 0 \\ 1 & 0 & 1 & 0 \\ 1 & 1 & 1 & 1\end{matrix} ]$$

and G_{(2,0)}=[1 1 1 1], respectively. The RM(2,0) code as illustrated is associated with a single input bit that is repeated 2^{m} times in the codeword generated by G_{(2,0)} such that it can produce the a first codeword 901 (e.g., codeword {0000}) or a second codeword 902 (e.g., codeword {1111}) (e.g., a corner of the outer cube and an “opposite” corner of the inner cube). The RM(2,1) code as illustrated is associated with a set of three input bits that upon application of G_{(2,1)} can produce any of the (eight) codewords illustrated as being either in the set of codewords for the RM(2,0) code or the RM(2,1) code (e.g., the third codeword 903, {0110}). A distance, or Hamming distance, between codewords in this simplified case may be identified by the number of edges traversed to go from one codeword to another codeword on the fourth dimensional hypercube. As can be seen from the illustration the distance between “adjacent” codewords is 2 (e.g., d=2^{m-r}=2²⁻¹) for the RM(2,1) code and is 4 (e.g., d=2^{m-r}=2²⁻⁰) for the RM(2,0) code. As will be explained in more detail below, the distance (or minimum distance) between adjacent/closest (or any) codewords may be associated with a limit of error correction and/or error detection. For example, error correction may be performed for a number of errors that is strictly less than half the minimum distance, while error detection may be performed for a number of errors that is equal to half the minimum distance.

FIG. 9B is a diagram 950 illustrating a distance associated with error correction/detection for codewords for an RM(2,0) code and for an RM(2,1) code in accordance with some aspects of the disclosure. While diagram 950 may not capture the nuances of a 4-dimensional (or n=2^{m}-dimensional for RM codes of block length n=2^{m}) space, it may be helpful to understand aspects of the disclosure conceptually. For example, the diagram 950 may be considered to be a 1-dimensional projection of a distance from {0000} (e.g., with origin at {0000} and distance along the axis being equal to the distance from {0000}) For illustrative purposes, diagram 950 includes the two codewords (i.e., the first codeword 901 {0000} and the second codeword 902 {1111}) common to the RM(2,0) code and the RM(2,1) code and an arbitrary codeword (e.g., the third codeword 903 {0110}) from the set of additional codewords associated with the RM(2,1) code (where each codeword in the set of additional codewords associated with the RM(2,1) code are located at the same distance from {0000}). As discussed above, the minimum distance between codewords is given by d=2^{m-r} and for the case illustrated in diagram 950 using a same value for m, a minimum distance (dᵣ=2^{m-r-1}) may be associated with error correction (dᵣ<2^{m-r-1}) and/or detection (dᵣ=2^{m-r-1}) for an RM code of order r.

Diagram 950 illustrates that for the RM(2,0) code (an RM code of order 0 and block length n=2^{m}), the minimum distance associated with error correction/detection is 2 (e.g., d₀=2²⁻⁰⁻¹=2¹=2) represented by the area 960, and for the RM(2,1) code (an RM code of order 1 and block length n=2^{m}), the minimum distance associated with error correction/detection is 1 (e.g., d₁=2²⁻¹⁻¹=2⁰=1) represented by the area 961. As can be seen from this simplified case, for the RM(2,0) code, a single-bit error may be corrected (e.g., {0010}→{0000} or {1111}→{1111}) as it is in the area 960 and two-bit errors may be detected and/or identified as an error (without a clear correction suggesting itself) as the two-bit error is on the border of the area 960 around both the first codeword 901 and the second codeword 902 (it is equally distant from both {0000} and {1111}). Similarly, for the RM(2,1) code, a single-bit error (e.g., {0010}) may be detected and/or identified as an error (without a clear correction suggesting itself) as the single-bit error is on the border of the area 961 around both the first codeword 901 and the third codeword 903 (it is equally distant from both {0110} and {0000}).

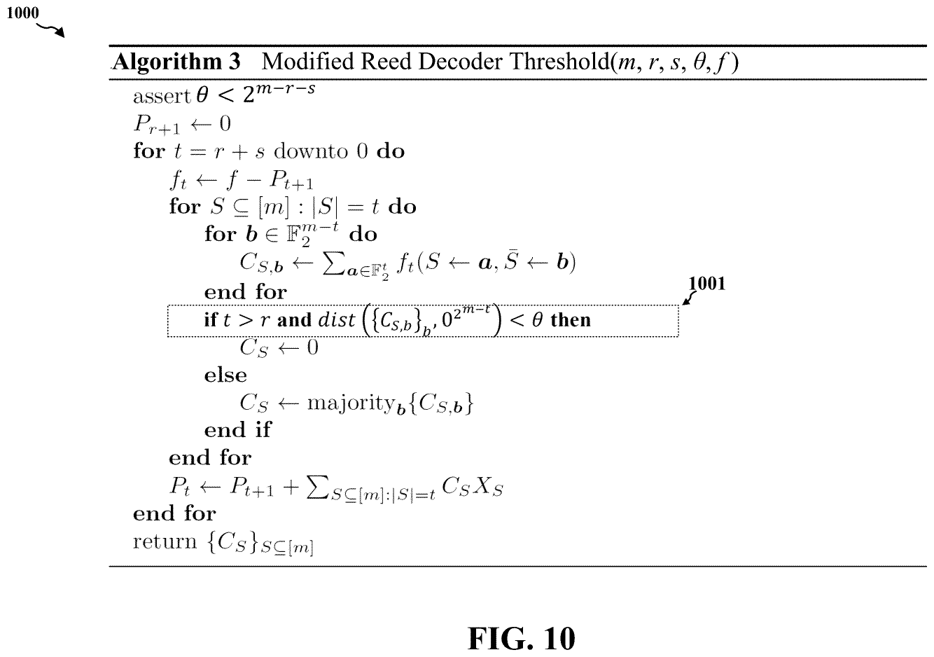

In some aspects of UMP, the encoding/decoding (e.g., ( [symbol] , [symbol] )) may be associated with an adjustment to the area 961 around codewords associated with the first subset of messages (e.g., [symbol] ₁) and a corresponding adjustment to the area 961 around codewords associated with the second subset of messages (e.g., [symbol] ₂). For example, in the simplified illustration in diagram 950, the area 961 around the first codeword 901 may be expanded to area 971 (corresponding to an increased “radius” ρᵢ, where i is an index associated with an associated subset of the messages (e.g., ρ₁ for messages in the first subset of messages [symbol] ₁, or ρ₂ for messages in the first subset of messages [symbol] ₂) within which codewords are interpreted as the first codeword 901. At the same time, the area 961 around the third codeword 903 may be contracted to area 972 (corresponding to a decreased “radius” ρ₂) within which codewords are interpreted as the third codeword 903. Accordingly, in the simplified example of diagram 950, a single bit error from {0000} may be corrected to {0000} (with a single bit error from {1111} such as {0111} similarly being interpreted as {1111}) instead of being identified as an error without a clear correction suggesting itself. In some aspects, the decreased “radius” ρ₂ is not a specified value but may be the by-product and/or result of setting the ρ₁ and/or the θ₁ used in a modified Reed decoder as will be described below in relation to FIG. 10 below.

While in the simplified diagram 950 the behavior is changed for a single-bit error (e.g., 50% of the minimum distance), for a RM code of longer block lengths (32, 64, 128, 256, etc.) and with a larger minimum distance between codewords, a threshold may be set with finer granularity and may effect a large number of errors. For example, for a set of messages, [symbol] , including up to 2¹⁶² messages, consider an implementation of UMP using an RM(8,2) code, a [256, 36, 64] code, for the first subset of up to 2³⁶ messages, [symbol] ₁, and an RM(8,4) code, a [256, 162, 16] code, for the second subset of up to 2¹⁶²⁻³⁶ messages, [symbol] ₂. For the RM(8,4) code the minimum distance is 16 (d=2⁸⁻⁴=2⁴) such that the maximum correctable error is 8 bits (e.g., strictly less than half the minimum distance, d₄=2⁸⁻⁴⁻¹, or 8) while for the RM(8,2) code, the minimum distance is 64 (d=2⁸⁻²=2⁶) such that the maximum correctable error is 31 bits (e.g., strictly less than half the minimum distance, d₂=2⁸⁻²⁻¹, or 32). When adjusting the “radius” (e.g., ρ₁ in the context of a decoder for the RM(8,4) code) associated with the first subset of codewords produced by the lower order subcode (e.g., the RM(8,2) code) and/or associated with the first subset of messages, [symbol] ₁, the new value, ρ₁, may be set to a value less than the distance between codewords of the RM(8,4) code (e.g., 2d₄) and greater than or equal to half the distance between codewords of the RM(8,4) code (e.g., d₄), or d₄≤ρ₁<2d₄) such that the decoding of received signals (e.g., corrupted codewords) that are different from a codeword in the first subset of codewords by strictly less than ρ₁ bits may be interpreted as the nearest codeword in the first subset of codewords.

While in some aspects, we may allow ρ₁ to take any value between the values d₄ and d₂, taking the values at the ends of the range would result in an interpretation of received signals that are the same as would be produced by the unmodified RM(8,4) code or the unmodified RM(8,2) code, respectively and any values above 2d₄ would result in failure to decode at least the codewords associated with the second subset of messages nearest to codewords associated with the first subset of messages (e.g., any such messages would be interpreted as the nearest codeword associated with the first subset of messages). Accordingly, when using a first RM(m, r) code and a second RM(m, r+s) code, the value for ρ₁ would most likely be selected to be some fraction of the minimum distance between codewords associated with the higher-order (e.g., the RM(m, r+s)) code while being above the minimum distance for error detection (e.g., ρ₁=γ2^{m-r-s}, where γ∈(0.5, 1) or, in some aspects, more likely γ∈[0.6, 0.9]) such that the error protection is increased for the first subset of messages associated with codewords of, or encoded by, the first RM(m, r) code, while maintaining an acceptable error rate for the second subset of messages associated with codewords of, or encoded by, the second RM(m, r+s) code. For example, when using the RM(8,4) code and the RM(8,2) code, ρ₁ would most likely be selected from the range between 9 and 15 (or from a range between 11 and 13) with the particular value selected based on the error tolerances associated with the different classes of messages and/or the application/context.

While illustrated for two sets of messages, the adjustment of multiple thresholds would follow the same principles. For example, we may consider three sets and/or classes of message (e.g., [symbol] ₁, [symbol] ₂, and [symbol] ₃) encoded by the RM(8,2) code, an RM(8,3) code (a [256, 92, 32] code with a maximum correctable error of 15 bits), and the RM(8,4) code, respectively. For a first subset of messages (e.g., which may be higher priority/more important/different class) encoded by the RM(8,2) code, the “radius” ρ₁ may be adjusted as above (e.g., d₄≤ρ₁≤2d₄). For a second subset of messages (e.g., which may be intermediate priority/less important/different class) encoded by the RM(8,3) code, the “radius” ρ₂ may be adjusted as above with one additional restraint, that it be less than ρ₁ (e.g., d₄≤ρ₂≤ρ₁≤2d₄). This may result, for a third d subset of messages (e.g., which may be lower priority/ordinary/different class) encoded by the RM(8,4) code, in an uneven “radius” ρ₄ associated with the codewords of the RM(8,4) code as codewords having a same number of errors may be interpreted as the nearest codeword of the RM(8,4) code if the errors are “away from” a nearest codeword of the RM(8,2) code (and “towards” a nearest codeword of the RM(8,3) code) while they may be interpreted as the nearest codeword of the RM(8,2) code if the errors are “towards” a nearest codeword of the RM(8,2) code. As used above, errors “toward” and “away from” a codeword may refer to decreasing and increasing a distance (a Hamming distance), respectively, from that codeword.

In practice, if we encoded the [symbol] ₁ messages using the RM(2,0) code, it would provide a protection of d₀=2²⁻⁰⁻¹=2¹=2 errors as described above. However, RM(2,0) is not large enough to also encode the messages in [symbol] ₂; one would typically have to use the RM(2,1) code to encode the union of [symbol] ₁ and [symbol] ₂, but this offers a protection up to d₁=2²⁻¹⁻¹=2⁰=1 errors as described above. The UMP scheme, in some aspects allows providing a protection up to d₁<t₁<d₀ errors to messages in [symbol] ₁ by (1) encoding them using the RM(2,0) code (i.e., not using the coefficients corresponding to polynomials of order greater than r=0 or mapping them to codewords of the the RM(2,0) code), and (2) decoding under RM(2,0), but with a tolerance t₁ lower than the 50% used in majority voting, i.e., with a tolerance t₁<d₀, yet larger than the tolerance d₁ allowed by the RM(2,1) code. Whenever this decoding fails, the received corrupted codeword has distance greater than to from My and, therefore, we can proceed with standard decoding under RM(2,1) using majority voting. Here, the (lower) threshold t₂=d₀−t₁<d₁ may not be considered, as the threshold matters whenever the codeword is close to a codeword of the RM(2,0) code, which has already been excluded in the previous step. Instead, the majority coding (or majority voting) may be used to estimate the additional coefficients.

Based on the above concepts, the Reed decoder presented in FIG. 6 may be modified to support UMP. FIG. 10 is a diagram 1000 illustrating pseudocode for the modified Reed decoder in accordance with some aspects of the disclosure. In some aspects, both the standard and modified Reed decoder decode coefficients, C_{S}, for a RM(m, r+s) code starting from coefficients

$$( e . g . , the ( \begin{matrix}m \\ r + s\end{matrix} ) coefficients )$$

associated with a highest order generator submatrix Gᵣ₊ₛ. All such coefficients (e.g., coefficients associated with Gᵣ₊ₛ down to Gᵣ₊₁) are, by construction, 0 for messages in [symbol] ₁ but are non-zero (e.g., are not all zero) for messages in [symbol] ₂. Accordingly, a threshold θ (e.g., the t₁ and/or “radius” ρ₁ discussed above at least in relation to FIG. 9B) may be adjusted (e.g., to be greater than 50% of the minimum distance associated with the higher-order RM code used to encode the second subset of messages) when decoding the sequence of coefficients associated with Gᵣ₊ₛ down to Gᵣ₊₁ that correspond to an all-zero sequence for messages in [symbol] ₁ as illustrated in line 1001 of the pseudocode of diagram 1000.

Given a noisy codeword {y(z)}, in some aspects, the RPA decoder may be modified to determine if the noisy codeword, {y(z)}, corresponds to a first type of codeword (e.g., which may be considered a special codeword) (associated with a message in [symbol] ₁) or a second type of codeword (e.g., which may be considered an ordinary codeword) (associated with a message in [symbol] ₂). As before, we assume that the first type of codewords are codewords of the RM(m, r) subcode while the second type of codewords are the remaining codewords of the RM(m, r+s) code. Given the received sequence y(z), the projection steps in the RPA decoding algorithm illustrated in diagram 800 are identical whether we decode using the RM(m, r) code or RM(m, r+s) code. This is because the coset partitioning depends on the value of m and not the order of the code. The difference is that after r+1 projections of a first type codeword all the codewords will be the zero sequence. On the other hand, for a second type of codeword there will be at-least one non-zero sequence. Based on this, two approaches to modifying the RPA decoder/decoding may be implemented to detect and decode a message in the first subset and/or class of messages (e.g., which may be considered to be more important and/or higher priority messages) (e.g., messages in [symbol] ₁).

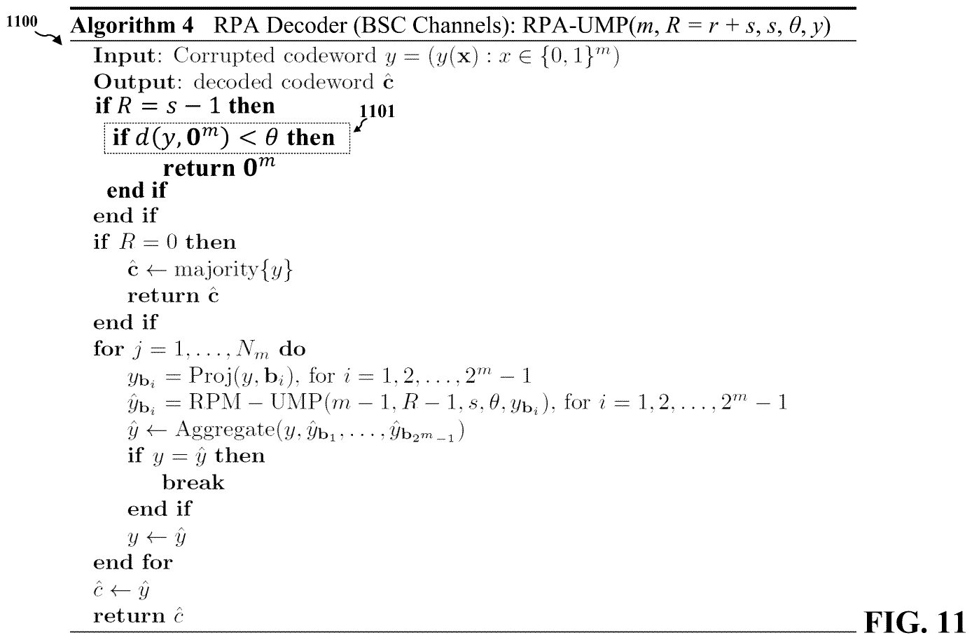

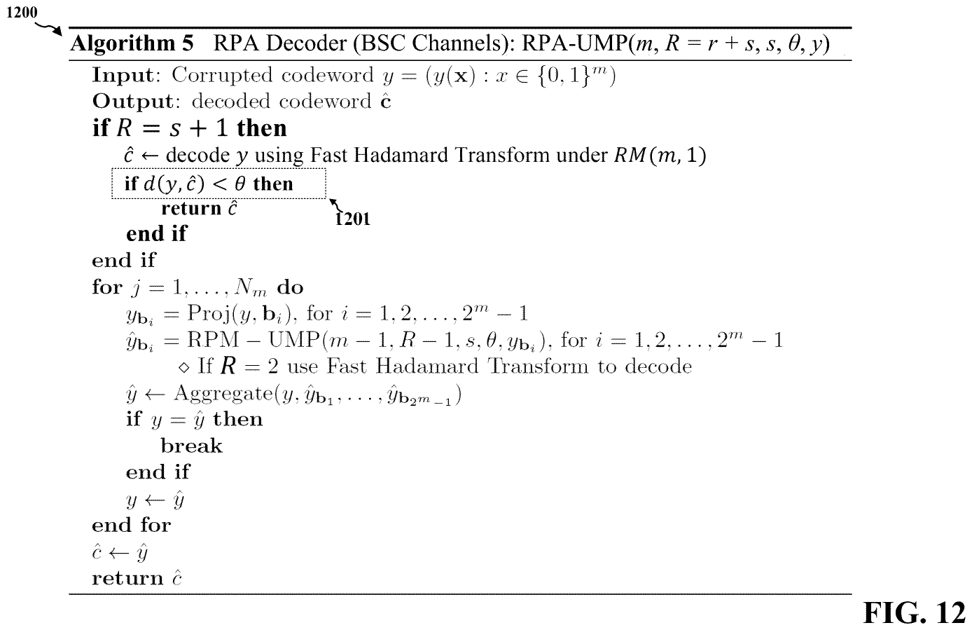

FIG. 11 is a diagram 1100 illustrating a first modified RPA decoder in accordance with some aspects of the disclosure. FIG. 12 is a diagram 1200 illustrating a second modified RPA decoder in accordance with some aspects of the disclosure. In both modified RPA decoders (e.g., Algorithm 4 of diagram 1100 and Algorithm 5 of diagram 1200), a number of projections, pᵣ, based on r is applied, where pᵣ is r+1 for Algorithm 4 and r−1 for Algorithm 5). After applying the p, projections, the algorithms may determine if the codeword is associated with a message in the first subset and/or class of messages (e.g., which may be considered to be more important and/or higher priority messages) (e.g., messages in [symbol] ₁). For example, Algorithm 4 may, after r+1 projections, determine (e.g., at 1101) if a current projection is within a threshold (Hamming) distance of an all-zero codeword (e.g., 0^{m}, where m is the current length value, where m, in some aspects may be interpreted as the length of a current input codeword which is equal to 2^{m}) of a same length (e.g., if the distance is less than a threshold value (θ)), where if the (Hamming) distance is less than the threshold distance, the algorithm determines that the message is a message in the first subset and/or class of messages (e.g., which may be more important and/or higher priority messages) (e.g., messages in [symbol] ₁). Similarly, for Algorithm 5, the algorithm may, after r−1 projections, attempt to decode the resulting codewords using the FHT (e.g., assuming that a first type codeword was transmitted). If the Hamming distance between the decoded codeword (using the FHT) and the input sequence is determined (e.g., at 1201) to be less than a threshold value (θ), the codeword is determined to be a message in the first subset and/or class of messages (e.g., which may be more important and/or higher priority messages) (e.g., messages in [symbol] ₁). Otherwise, if the (Hamming) distance between the current projection and the all-zero codeword is greater than, or equal to, the threshold distance or if the attempt to decode using the FHT fails (e.g., either of the above conditions for Algorithm 4 or Algorithm 5 does not hold), the algorithms may proceed with the rest of the decoding assuming that the input sequence is a codeword from the RM(m, r+s) code.

Specifically, for Algorithm 4 a determination is made after r+1 levels of projection of the RPA algorithm. If a first type codeword from the RM(m, r) code (or subcode) is transmitted then all the projected codewords are the all-zero codewords as described above. As a result, Algorithm 4 uses a threshold test (e.g., 1101) that, if passed (e.g., if the distance from the all-zero codeword is below the threshold value), declares and/or sets the projection to be the all-zero sequence. In Algorithm 5 a determination is made after r−1 levels of projection in the RPA algorithm. After the r−1 levels of projection, the algorithm attempts to decode each projection using the FHT. In some aspects, Algorithm 5 may be more efficient than Algorithm 4 as it involves fewer levels of projection by replacing the last two recursion steps with the FHT. Algorithm 5 is based on the fact that, if the input sequence (e.g., the codeword y(z)) is a first type codeword associated with, or encoded by, the RM(m, r) code (or subcode), the decoder is expected to succeed. As a result, the algorithm applies a thresholding test (e.g., 1201) as illustrated in Algorithm 5.

The thresholding tests in the previous subsection are heuristic. The projections in the RPA algorithm lead to correlated errors across the projected sequences. As a result, it is not straightforward to characterize an optimal rule for detecting whether a first type codeword is transmitted. For example, when r=1, the threshold θ has interpretable meaning since the check for d(y, ĉ)<θ is performed before a recursive call, i.e., θ is equal to the number of errors tolerated for first type codewords. When r>1, the comparison with projected codewords may be complicated by the different projections being correlated and each projection may have more errors than the initial corrupted codeword.

RPA, in some aspects, may be associated with a higher computational cost of using higher order RM codes for messages of the message set [symbol] ₂. For example, if we assume that the message set [symbol] ₁ has size m₁=2^{k}^{₁} and the message set [symbol] ₂ has size m₂=2^{k}−2^{k}^{₁} as described above, the RPA decoder has complexity O(2^{m(r+s)} m). If m₁<2^{k}^{₁} we have exponential overhead as [symbol] ₂ is encoded using a higher order (e.g., an even-higher order) RM code (e.g., if the size of m₁ increases such that it exceeds, even by one, a number of messages associated with a lower value for k₁ but is less than 2^{k}^{₁} a higher order RM code will be used to encode the messages in [symbol] ₂ which increases the complexity exponentially).

In some aspects an AI/ML based approach may be used to improve the efficiency and/or accuracy of the RPA algorithm. Suppose y is the original received sequence and we apply r+1 levels of RPA projection to generate projected sequences, say ŷ₁, . . . , ŷ_{T}. If a first type of codeword from the RM(m,r) code (or subcode) was transmitted (e.g., if y is based on a message in [symbol] ₁), then all the projections are noisy versions of the all zero codeword. Thus, we would like to define and/or implement a function ƒ(ŷ₁, . . . , ŷ_{T}) that evaluates to either 0 or 1 depending on whether a first type codeword (e.g., which may be considered a special codeword or important codeword) or a second type of codeword (e.g., which may be considered ordinary codeword or regular codeword) is associated with y, or the set of (ŷ₁, . . . , ŷ_{T}). Due to the correlation in noise between the projections, in some aspects an AI/ML algorithm may be suited to providing such a function. Specifically, in some aspects, deep learning, or more specifically, a transformer based architecture in deep learning, may be an effective approach and/or provide an efficient algorithm for implementing this function. Furthermore, in some aspects, the AI/ML algorithm may be trained such that the resulting decoder mimics the UMP properties previously described, i.e., P(m≠\hat{m}/m∈ [symbol] ᵢ)≤ϵᵢ for each i∈{1,2}. Different strategies to reach this goal are possible. Some simple approaches may include relaxing the hard constraint (e.g., that P(m≠\hat{m}|m∈ [symbol] ᵢ)≤ϵᵢ for each i∈{1,2}) and, instead, minimizing a hinge loss function [symbol] [σP(\hat{m}≠m)−ϵ₁)]+ [symbol] [σP(\hat{m}≠m)−ϵ₂)], where σ is one of the rectified linear unit (ReLU) function or a weighted loss function

$$\frac{1}{{ϵ}_{1}} {𝔼}_{m ∈ {ℳ}_{1} , y ∼ W ( y \vert x = ℱ ( m ) )} [ P ( \hat{m} \neq m ) ] + \frac{1}{{ϵ}_{2}} {𝔼}_{m ∈ {ℳ}_{2} , y ∼ W ( y \vert x = ℱ ( m ) )} [ P ( \hat{m} \neq m ) ] .$$

Referring back to FIG. 5, a model training host 502 may be provided with training data such as a set of projections after a set of recursive steps of the RPA and an indication of whether the original message was in [symbol] ₁ or in [symbol] ₂. In some aspects, the number of recursive steps in the set of recursive steps may be equal to r+1 and the set of projections may include

$${\{ {y}_{{b}_{i}} ∈ {𝔽}_{2}^{m - r - 1} \}}_{i ∈ [ 1 , ... , {2}^{m} - 1 ] \times [ 1 , ... , {2}^{m - 1} - 1 ] \times ... \times [ 1 , ... , {2}^{m - r - 1} - 1 ]}$$

and a first goal of the training may be to identify if the received message, y, was associated with [symbol] ₁ or [symbol] ₂ (e.g., whether y∈ [symbol] ₁). As discussed above, in some aspects, the model training host 502 may further be provided with values for ϵ₁ and ϵ₂ and/or be configured to minimize the hinge function described above so that it not only identifies whether a message is associated with [symbol] ₁ or [symbol] ₂, but also approximates the UMP condition P(m≠\hat{m}|m∈ [symbol] ᵢ)≤ϵᵢ for each i∈{1,2}.

Generally, given a received sequence y, let RMDecode(y, m, r) denote any decoder for the RM(m, r) code, a two-step approach may be used as follows. First invoke RMDecode(y, m, r) to find a candidate first type codeword (e.g., which may be referred to as a candidate special codeword) c₁, then invoke RMDecode(y, m,r+s) to find a candidate second type codeword (e.g., which may be referred to as a candidate ordinary codeword) c₂. If c₁=c₂, then output c=c₂ (or c=c₁). Otherwise, consider a likelihood ratio test such as

$$log \frac{W ( {c}_{1} \vert y )}{W ( {c}_{2} \vert y )} \geq t ,$$

where t<0 is a threshold selected based on the UMP conditions for the first messages ( [symbol] ₁) and the second messages ( [symbol] ₂) (e.g., P(m≠\hat{m}|m∈ [symbol] ᵢ)≤ϵᵢ for each i∈{1,2}). If the above condition is true, the algorithm may output c=c₁, otherwise the algorithm may output c=c₂.

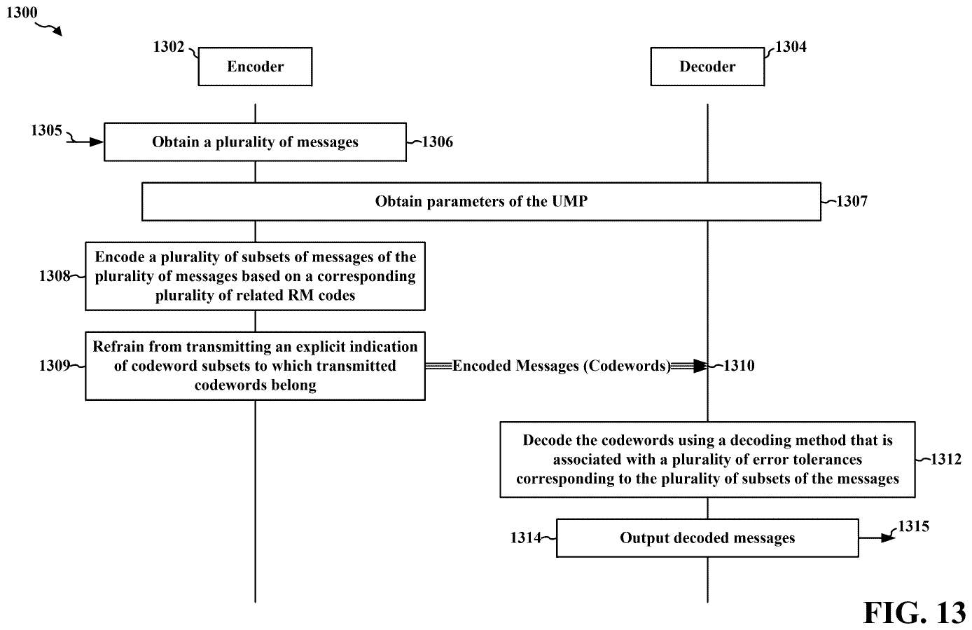

FIG. 13 is a call flow diagram 1300 illustrating a method of wireless communication in accordance with some aspects of the disclosure. The method is illustrated in relation to an encoder 1302 and a decoder 1304 (e.g., a device including the encoder/decoder, one or more processors of a device that perform the encoding/decoding) in communication, where the encoder 1302 and the decoder 1304 may be included in a wired or wireless device (e.g., a UE, base station, satellite, drone, etc.) or component thereof and where any examples are non-limiting and are for illustrative purposes. The functions ascribed to the encoder 1302, in some aspects, may be performed by one or more components of a device including the encoder 1302. Similarly, the functions ascribed to the decoder 1304, in some aspects, may be performed by one or more components of a device including the decoder 1304. Accordingly, references to “transmitting” in the description below may be understood to refer to a first component of the encoder 1302 (or the decoder 1304) outputting (or providing) an indication of the content of the transmission to be transmitted by a different component of the encoder 1302 (or the decoder 1304). Similarly, references to “receiving” in the description below may be understood to refer to a first component of the encoder 1302 (or the decoder 1304) receiving a transmitted signal and outputting (or providing) the received signal (or information based on the received signal) to a different component of the encoder 1302 (or the decoder 1304). Although not shown, the encoder 1302 and the decoder 1304 may have known, configured, or exchanged, information regarding different applications and/or traffic that may be subject to UMP and/or parameters associated with the UMP (e.g., m, r, s, θ, etc.).

The encoder 1302, in some aspects, may, at 1306, obtain a plurality of messages 1305. The plurality of messages 1305, in some aspects, may include a plurality of subsets of messages including, e.g., a first subset of the plurality of messages and a second subset of the plurality of messages. The encoder 1302 and the decoder 1304, at 1307 (e.g., at some time before an encoding and/or decoding operation) may obtain a set of parameters for the UMP encoding/decoding. For example, the set of parameters, in some aspects, may include a codeword length associated with each codeword in the plurality of codewords (e.g., m), a first order associated with the first RM code (e.g., r), a second order associated with the second RM code that is greater than the first order (e.g., r+s or s), and a threshold value associated with at least the first error tolerance for the first subset of the plurality of codewords (e.g., θ). In some aspects, other algorithm-dependent parameters may additionally be determined or obtained, such as, for a modified RPA decoding algorithm and/or method, a maximum number (Nₘ) of rounds of projections and aggregations to perform before exiting a (current) recursion.

Based on obtaining the plurality of messages 1305, the encoder 1302 may, at 1308, encode the plurality of subsets of the plurality of messages based on a corresponding plurality of RM codes (e.g., a first RM code of a common blocklength and a lowest order for encoding a first subset of the plurality of messages through an nth RM code of the common blocklength with a highest order in the plurality of RM codes). For example, the encoder 1302 may encode the first subset of the plurality of messages into a first set of codewords associated with a first RM code (e.g., an RM(m, r) code), and encode the second subset of the plurality of messages into a second set of codewords associated with a second RM code (e.g., an RM(m, r+s) code), where the first RM code is a subcode of the second RM code. In some aspects, the plurality of messages further includes a third subset of the plurality of messages and the first RM code is a first subcode of the second RM code, where a third subset of the plurality of codewords associated with the third subset of the plurality of messages is associated with a third RM code that is a second subcode of the second RM code, and where the third order is associated with a third error tolerance that is greater than the second error tolerance and less than the first error tolerance.

In some aspects, the encoding of the first and second subsets of the plurality of messages may be based on a known (one-to-one) mapping between messages in the plurality of the messages and codewords of the second RM code, where the first subset of messages are mapped to codewords that are also codewords of the first RM code and the second subset of messages are mapped to codewords of the second RM code that are not also codewords of the first RM code. In other words, in some aspects, the first subset of codewords is not included in the second subset of codewords despite being associated with the second RM code. In some aspects, encoding a particular message in the first (or second) subset of the plurality of messages into a particular codeword in the first (or second) set of codewords may include identifying that the particular messages belongs to the first (or second) subset of messages and mapping the particular message to one of the particular codeword or a string of bits to be encoded into the particular codeword using a generator matrix associated with the first (or second) RM code.

As described above, the first RM code and the second RM code may be of a first length (or blocklength). In some aspects, the first RM code of the first length is of a first order (e.g., r) and the second RM code of the first length is of a second order (e.g., r+s) that is greater than the first order (e.g., s≥1). The first order, in some aspects, is associated with a first error tolerance (e.g., even before modifying a related decoder) that is greater than a second error tolerance associated with the second order (e.g., dᵣ₊ₛ=2^{m-r-s-1}<dᵣ=2^{m-r-1}, based on the condition that s≥1). In some aspects, the first subset of codewords may be smaller than the second subset of codewords by a factor based on a difference between the first order and the second order (e.g., the first subset of codewords may include 2^{k}^{₁} while the second subset of codewords may include 2^{k}−2^{k}^{₁} or a factor of (2^{k-k}^{₁}−1) more codewords, where k₁ and k are based on m, r, and s as described above.

The encoder 1302 (or a device including the encoder 1302 along with at least one transceiver or other wired and/or wireless transmission mechanism) may transmit, and the decoder 1304 may receive, the encoded (plurality of) messages as (a plurality of) codewords 1310. The plurality of codewords, in some aspects, may include a first subset of the plurality of codewords associated with a first subset of the plurality of messages and a second subset of the plurality of codewords associated with a second subset of the plurality of messages, where, as described above, the first subset of codewords may be associated with a first RM code and the second subset of codewords may be associated with a second RM code, where the first RM code is a subcode of the second RM code. In some aspects, the encoder 1302 may refrain from transmitting an explicit indication of a subset of messages associated with each of the (plurality of) codewords 1310. For example, the encoder 1302 may, at 1309, refrain from transmitting, for each codeword in the plurality of codewords, an explicit indication of whether the codeword belongs to the first subset of codewords or the second subset of codewords. During the transmission (either wired or wireless) there may be some corruption and/or degradation such that some errors are introduced.

The decoder, at 1312, may decode the codewords 1310 (to produce a de-noised codeword and/or the original plurality of messages) using a decoding method that is associated with a first error tolerance (e.g., related to a thresholding parameter θ) for the first subset of the plurality of codewords associated with the first RM code and a second error tolerance for the second subset of the plurality of codewords associated with the second RM code. In some aspects, the first error tolerance (e.g., a first ability to correct up to a first number of errors introduced to a codeword in the first subset of codewords) may be higher than the second error tolerance (e.g., a second ability to correct up to a second number of errors introduced to a codeword in the second subset of codewords, where the second number is less than the first number). In some aspects, a first target error rate (e.g., ϵ₁) associated with the first subset of the codewords may be lower than a second target error rate (e.g., ϵ₂, where ϵ₁<ϵ₂) associated with the second subset of the codewords. Accordingly, in some aspects, instead of discussing different error tolerances associated with different subsets of the codewords, we may discuss different target error rates (e.g., P(m≠\hat{m}|m∈ [symbol] ᵢ) for each i∈{1, . . . , n} for n subsets of codewords and/or messages) associated with the different subsets of the codewords and/or messages.

For example, the decoder 1304, at 1312, may decode the plurality of codewords 1310 using a decoding method (e.g., one of the decoding methods illustrated in FIGS. 10-12) that is associated with a first error tolerance for first codewords (or a first subset of codewords) associated with the first RM code (e.g., the RM(m, r) code) and a second error tolerance for second codewords (or a second set of codewords) associated with the second RM code (e.g., the RM(m, r+s) code), where the first error tolerance is higher than the second error tolerance (e.g., dᵣ=2^{m-r-1}>dᵣ₊ₛ=2^{m-r-s-1}, based on the condition that s≥1). In some aspects, a one-to-one mapping exists from decoded codewords in the plurality of decoded codewords to corresponding messages in the plurality of messages (e.g., a first one-to-one mapping may exist between codewords and sets of bits used to generate the codewords using a generator matrix while a second one-to-one mapping may exist between the sets of bits used to generate the codewords and messages in the plurality of messages, such that each valid codeword can uniquely identify a valid message in the plurality of messages).

In some aspects, each codeword includes a first number of bits (e.g., is of a first length or has a first blocklength). The first number of bits, in some aspects, may include at least a first set of bits associated with a corresponding set of rows of an encoder (e.g., rows of a generator matrix corresponding to Gᵢ for i>r) associated with the first RM code that are not associated with an encoder associated with the subcode of the first RM code. In some aspects, the decoding method is an adapted reed decoder, and the decoding for a particular codeword of the plurality of codewords includes calculating, for each bit in the first set of bits, a first set of binary values (e.g., {C_{S}}_{b}) including a first number (2^{m-t} for t>r) of binary values and comparing, for each bit in the first set of bits, a second number (n_{S}) of the binary values in the first set of binary values that have a first binary value (e.g., a value of “1”) to a threshold number (e.g., θ), where, if the second number is (strictly) less than the threshold number, the bit is set to the second binary value (e.g., a value of “0”), and if the second number is at least the threshold number, the bit is set to the first binary value. In some aspects, the threshold may be applied such that if the second number is less than, or equal to, the threshold number, the bit is set to the second binary value (e.g., a value of “0”), and if the second number is greater than the threshold number, the bit is set to the first binary value (e.g., the inequality for the test may be one of n_{S}<θ or n_{S}≤θ). In some aspects, the threshold number (θ) is a threshold fraction of the first number (e.g., γ2^{m-t}), wherein the threshold fraction is greater than 50 percent (e.g., 0.5<γ<1).

In some aspects, the second RM code is associated with a generator matrix having a first number of rows corresponding to a first number of bits in each decoded codeword, wherein each row uniquely corresponds to an order of the RM code (e.g., is a row of a Gᵢ for one i∈[0, r+s]), where a particular order of the RM code may correspond to one of a single row or multiple rows of the generator matrix (e.g., each Gᵢ may include one or multiple rows). In some aspects, the decoding method may be an adapted (or modified) Reed decoder (As illustrated in FIG. 10), and the decoding for a particular codeword (ƒ) of the plurality of codewords corresponding to a particular message of the plurality of messages, in some aspects may include: (1) setting a current order of the decoder to be the second order (e.g., t=r+s) and a current codeword (ƒₜ) to be the particular codeword (ƒ), and, until the current order is decremented below zero, (2) determining, for each row of the generator matrix corresponding to the current order of the decoder, a corresponding bit value (C_{S}) based on a thresholding operation (e.g., dist({C_{S,b}}_{b}, 0²^{^{m-t}})<θ or C_{S}←majority_{b}{C_{S,b}}) performed on a set of binary values (C_{S,b}) associated with a set of linear combinations of bits in the current codeword, where the thresholding operation is based on the threshold value when a current order (t) of the decoder is greater than the first order (r) and is based on a majority when a current order of the decoder is not greater than the first order (e.g., if t>r and dist({C_{S,b}}_{b}, 0²^{^{m-t}})<θ, then C_{S}←0, else C_{S}←majority_{b}{C_{S,b}}), (3) calculating, based on the determined corresponding bit values, an updated codeword (e.g., Pₜ←Pₜ₊₁+Σ_{S⊆[m]:|S|=t}C_{S}X_{S} and ƒₜ←ƒ−Pₜ₊₁, where Pᵣ₊₁ is initialized to 0 and a current order value, t, begins at r), (4) decrementing the current order of the decoder, going back to (2) based on the current (decremented) order of the decoder, and (5) returning, when the value of the current order is decremented below zero, the determined corresponding bit values as a particular decoded codeword.

In some aspects, when a current order of the decoder is greater than the second order, the thresholding operation based on the threshold value performed on the set of binary values associated with the set of linear combinations of bits in the current codeword as described above may include: (1) comparing a (second) number of non-zero binary values in the set of binary values to the threshold value, (2) setting the bit to zero when the second number is less than the threshold value, and (3) setting the bit to one when the second number is at least the threshold value. In some aspects, the threshold may be applied such that if the distance is less than, or equal to, the threshold number, the bit is set to zero, and if the second number is greater than the threshold number, the bit is set to one (e.g., the inequality for the test may be one of dist({C_{S,b}}_{b}, 0²^{^{m-t}})<θ or dist({C_{S,b}})_{b}, 0²^{^{m-t}})≤θ). In some aspects, the threshold number (θ) is a threshold fraction of the first number (e.g., γ2^{m-t}), wherein the threshold fraction is greater than 50 percent (e.g., 0.5<γ<1).

As described above, when a current order of the decoder is not greater than the second order, the thresholding operation may be based on the majority performed on the set of binary values associated with the set of linear combinations of bits in the current codeword, and may include: (1) comparing a second number of non-zero values in the set of binary values to a third number of zero values in the set of binary values, (2) setting the bit to zero when the second number is less than the third number, (3) setting the bit to one when the second number is greater than the third number, and, when the second number is equal to the third number, one of (4) indicating a failure to decode, (5) setting the bit to zero, or (6) setting the bit to one, where setting the bit to a value of 0 or 1 may be based on a random (or pseudo-random), or other determination and/or selection.

The first RM code, in some aspects, may be of a first length and of a first order, and the second RM code may be of the first length and of a second order that is greater than the first order. In some aspects, the second (higher) order may be associated with less error tolerance than the first order. The decoding method, in some aspects, may be the modified RPA decoding algorithm and/or method (e.g., as illustrated in FIG. 12) that accepts (as input) a length value (m, where m, in some aspects, may be interpreted as the length of an input codeword which is equal to 2^{m}), a first order value (r+s), a second order value(s), a threshold value (θ), and a codeword (y) as input (e.g., RPA-UMP(m,r+s, s, θ, y)) and performs a projection operation on the input codeword that produces a plurality of intermediate codewords (y_{b}_{ᵢ} for i=1, 2, . . . , 2^{m}−1) that are used as the input for a next iteration of the modified RPA decoding algorithm and/or method with a decremented length value and a decremented order value (e.g., RPA-UMP(m−1,r+s−1, s, θ, y_{b}_{ᵢ}) for i=1, 2, . . . , 2^{m}−1). In some aspects, the decoding for a particular codeword of the plurality of codewords may include applying the projection operation for a number of iterations that is equal to one less than the first order of the first RM code (e.g., r−1) and attempting to decode a current intermediate codeword using a FHT. If the decoding using the FHT is successful, the RPA decoding method, in some aspects, uses the decoded codeword at the current recursion to decode codewords associated with previous recursive steps and continues with an aggregation operation to produce a decoded message in the first subset of the plurality of messages (or a decoded codeword in the first subset of codewords). However, if the decoding using the FHT is not successful, the RPA decoding method, in some aspects, may perform an additional set of iterations of the projection operation until the decremented order value is equal to one and then perform the FHT and the aggregation operation to produce a decoded message in the second subset of the plurality of messages (or a decoded codeword in the second subset of codewords). In some aspects, the decoding using the FHT may be determined to be successful if a Hamming distance between the decoded codeword and the input codeword is less than a threshold distance based on the threshold value.

In some aspects, the first RM code may be of a first length and of a first order, and the second RM code may be of the first length and of a second order that is greater than the first order. In some aspects, the second (higher) order may be associated with less error tolerance than the first order. The decoding method, in some aspects, may be the modified RPA decoding algorithm and/or method (e.g., as illustrated in FIG. 11) that accepts (as input) a length value (m, where m, in some aspects, may be interpreted as, or used to calculate or determine, the length of an input codeword which is equal to 2^{m}), a first order value (r+s), a second order value(s), a threshold value (θ), and a codeword (y) as input (e.g., RPA-UMP(m,r+s, s, θ, y)) and performs a projection operation on the input codeword that produces a plurality of intermediate codewords (y_{b}_{ᵢ} for i=1, 2, . . . , 2^{m}−1) that are used as the input for a next iteration of the modified RPA decoding algorithm and/or method with a decremented length value and a decremented order value (e.g., RPA-UMP(m−1, r+s−1, s, θ, y_{b}_{ᵢ}) for i=1, 2, . . . , 2^{m}−1). In some aspects, the decoding for a particular codeword of the plurality of codewords may include applying the projection operation for a first number of iterations that is equal to one more than the first order of the first RM code (e.g., r+1), and comparing, for a current intermediate codeword, a Hamming distance between the current intermediate codeword and a zero codeword to a threshold distance. If the Hamming distance is less than the threshold distance, the RPA decoding method, in some aspects, may provide a zero vector (e.g., 0^{m} at 1101, where m is the input length value to a current recursion (or invocation) of the modified RPA decoding algorithm such that the length of the zero vector, in some aspects, is 2^{m}) of a length that is based on one or more of the length value or a current first order value (e.g., based on the current first order value that is equal to m−r−1 or s−1), uses the decoded codeword at the current recursion (e.g., the zero vector) to decode codewords associated with previous recursive steps and continue with an aggregation operation to produce a decoded message in the first subset of the plurality of messages (or a decoded codeword in the first subset of codewords). However, if the Hamming distance is at least the threshold distance, the RPA decoding method, in some aspects, may perform an additional set of iterations of the projection operation until the decremented order value is equal to one and then perform a FHT and the aggregation operation to produce a decoded message in the second subset of the plurality of messages (or a decoded codeword in the second subset of codewords).

In some aspects, the decoding method may be a modified RPA decoding algorithm for decoding an input codeword, where the modified RPA decoding algorithm is based on a first input value associated with the length of the input codeword, a second input value based on the second order, a third input value associated with a first number of recursions of (e.g., invocations of, or calls to) the modified RPA decoding algorithm to perform before attempting to decode the input codeword as a codeword in the first subset of codewords, and a fourth input value associated with the threshold value, where the third input value is based on the difference between the first order and the second order, where the modified RPA decoding algorithm for a second input value equal to 1 includes (or performs) an FHT, where each iteration of the modified RPA decoding algorithm may be performed one of up to a maximum number of times or until a decoded codeword converges. In some aspects the decoding for a particular codeword of the plurality of codewords may include invoking the modified RPA decoding algorithm with a current input codeword that is the particular codeword, a current first input value that is a first value associated with the length of the particular codeword, a current second input value that is the second order, and a third input value that is a third value based on the difference between the first order and the second order, and a fourth input value associated with the threshold value, where upon being invoked, the modified RPA decoding algorithm is associated with: (1) determining whether the first number of invocations of the modified RPA decoding algorithm have been performed based on a current second input value and the third input value, (2) performing, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value, (3) determining, when the first number of invocations of the modified RPA decoding algorithm have been performed, if a current input codeword of a most recent invocation of the modified RPA decoding algorithm is associated with the first subset of codewords based on the fourth input value associated with the threshold value (e.g., for a first order equal to r, After r−1 steps of recursion, the current input codeword (at this invocation of the recursive method) is compared with the codewords in a RM(m−r+1,1) code based on the threshold value), (4) outputting, when the first number of invocations of the modified RPA decoding algorithm have been performed and based on determining that the current input codeword of the most recent invocation of the modified RPA decoding algorithm is associated with the first subset of codewords, a decoded codeword based on the particular codeword, (5) performing, when the first number of invocations of the modified RPA decoding algorithm have been performed and based on determining that the current input codeword of the most recent invocation of the modified RPA decoding algorithm is not associated with the first subset of codewords, a set of additional projections and invocations of the modified RPA decoding algorithm with an additional decremented first input value and an additional decremented second value until the current second input value is equal to 1 and decoding the current input codeword for each of a plurality of projected codewords associated with the current invocation of the modified RPA decoding algorithm using the FHT, and (6) decoding, based on the decoded current input codeword for each of the plurality of projected codewords, a plurality of input codewords associated with previous invocations of the modified RPA decoding algorithm.

The decoding method, in some aspects, may be a machine-trained (MT) (e.g., AI/ML or transformer-based architecture in deep learning) RPA decoding method. In some aspects, the MT RPA may be trained to determine whether particular codewords in the plurality of codewords were encoded with the first RM code or the second RM code. The training, in some aspects, may be based on a training set including multiple data sets, where each data set includes (1) multiple projections generated by an RPA decoding method applied to a test codeword encoded with one of the first RM code or the second RM code and (2) an indication of whether the first RM code or the second RM code was used to encode the test codeword. In some aspects, the MT RPA may further be trained to decode an input codeword encoded with the first RM code with a first accuracy based on the first error tolerance and to decode the input codeword encoded with the second RM code with a second accuracy based on the second error tolerance. In some aspects, the MT RPA (or AI/ML decoding method more generally) may be received by the decoder 1304 after a training on another device (e.g., the decoder 1304 may receive an indication of a structure of the AI/ML decoder and a set of related weights for elements of the AI/ML or a program utilizing and/or implementing a set of learned relationships between projections and a subset of messages).

After decoding the plurality of codewords into a plurality of decoded messages, the decoder 1304 may, at 1314, output the decoded plurality of messages 1315. The decoded plurality of messages 1315, in some aspects, may be provided to a different component of the decoder 1304, or to a different component of a device including the decoder 1304.

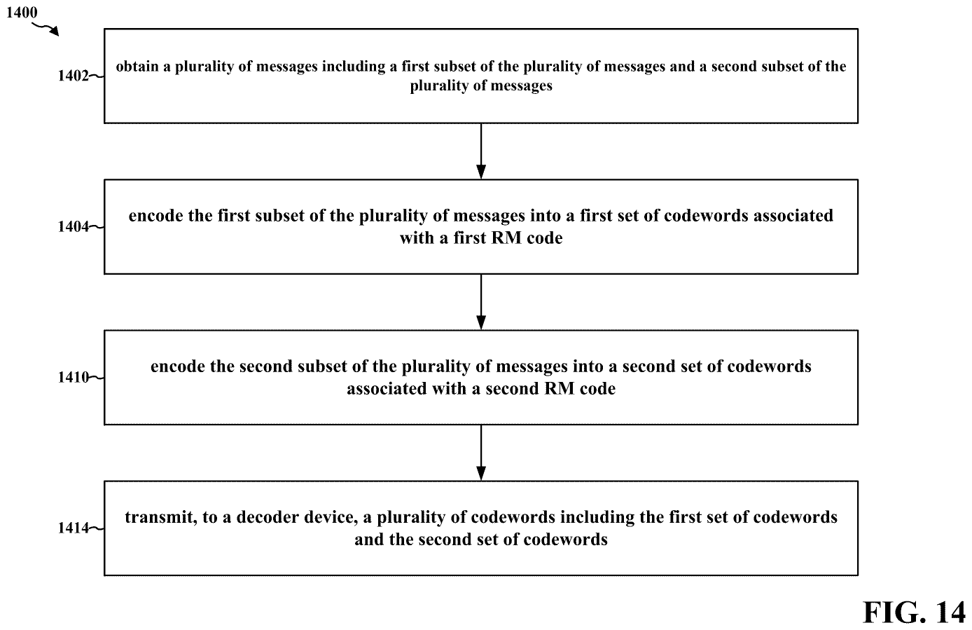

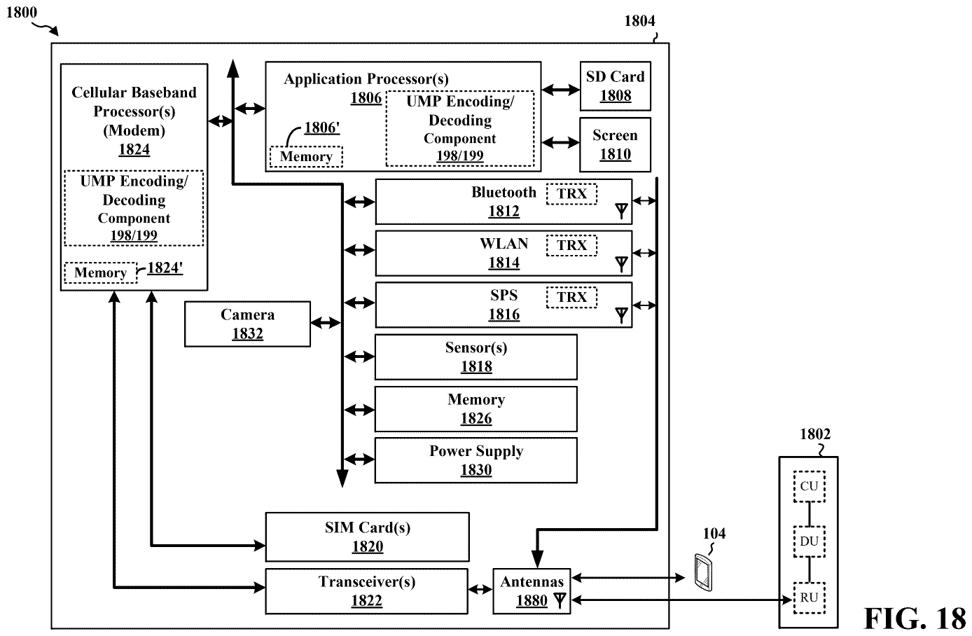

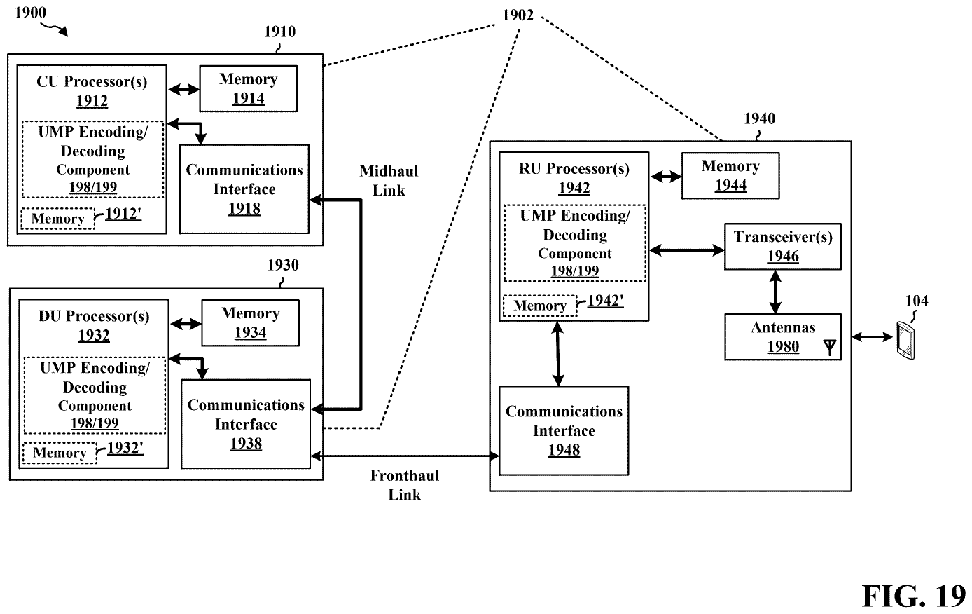

FIG. 14 is a flowchart 1400 of a method of wireless communication. The method may be performed by an encoder (e.g., the encoder 1302) that may be associated with a UE (e.g., the UE 104; the apparatus 1804), a base station (e.g., the base station 102; the network entity 1802, 1902) or a device including the encoder. At 1402, the encoder may obtain a plurality of messages including a first subset of the plurality of messages and a second subset of the plurality of messages. In some aspects, the plurality of messages may further include a third subset (or at least one additional subset) of the plurality of messages. For example, 1402 may be performed by application processor(s) 1806, cellular baseband processor(s) 1824, transceiver(s) 1822, antenna(s) 1880, and/or UMP encoding/decoding component 198/199 of FIG. 18. For example, 1402 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the encoder 1302 may, at 1306, obtain the plurality of messages 1305.

In some aspects, the encoder may encode, at 1404 and 1410, a plurality of subsets of the plurality of messages using a corresponding plurality of RM codes where 1404 and 1410 may be performed in any order and/or may be performed multiple times in different orders as messages in different subsets of the plurality of messages are obtained by the encoder. The encoder may, at 1404, encode the first subset of the plurality of messages into a first set of codewords associated with a first RM code. The encoder may, at 1410, encode the second subset of the plurality of messages into a second set of codewords associated with a second RM code, where the first RM code is a subcode of the second RM code. As described above, the first RM code and the second RM code, in some aspects, are of a first length (or blocklength). In some aspects, the first RM code of the first length is of a first order (e.g., r) and the second RM code of the first length is of a second order that is greater than the first order (e.g., r+s, where s≥1). In some aspects, the first order is associated with a first error tolerance that is greater than a second tolerance associated with the second RM code (e.g., dᵣ=2^{m-r-1}>dᵣ₊ₛ=2^{m-r-s-1}, based on the condition that s≥1).

In some aspects, to encode the first subset of the plurality of messages at 1404, the encoder may identify that the particular message belongs to the first subset of messages and map the particular message to one of the particular codeword or a string of bits to be encoded into the particular codeword using a generator matrix associated with the first RM code. While described for the encoding of the first subset of the plurality of messages, similar steps may be performed when encoding the second subset of the plurality of messages. For example, 1404 and 1410 may be performed by application processor(s) 1806, cellular baseband processor(s) 1824, transceiver(s) 1822, antenna(s) 1880, and/or UMP encoding/decoding component 198/199 of FIG. 18. For example, 1404 and 1410 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the encoder 1302 may, at 1308, encode a plurality of subsets of the plurality of messages 1305 using a corresponding plurality of RM codes (e.g., a first RM code of a common blocklength and a highest order for encoding a first subset of the plurality of messages through an nth RM code of the common blocklength with a lowest order in the plurality of RM codes).

At 1412, the encoder may refrain from transmitting, for each codeword in the plurality of codewords, an explicit indication of whether the codeword belongs to the first subset of codewords or the second set of codewords. At 1416, the encoder may transmit, to a decoder device, the plurality of codewords including the first subset of codewords and the second set of codewords. For example, 1414 and 1416 may be performed by application processor(s) 1806, cellular baseband processor(s) 1824, transceiver(s) 1822, antenna(s) 1880, and/or UMP encoding/decoding component 198/199 of FIG. 18. For example, 1414 and 1416 may be performed by CU processor(s) 1912, DU processor(s) 1932, RU processor(s) 1942, transceiver(s) 1946, antenna(s) 1980, and/or UMP encoding/decoding component 198/199 of FIG. 19. In some aspects, the plurality of codewords may further include the third set of codewords. For example, referring to FIG. 13, the encoder 1302 may transmit the encoded (plurality of) messages as (a plurality of) codewords 1310. In some aspects, the encoder 1302 may refrain, at 1309, from transmitting an explicit indication of a subset of messages associated with each of the (plurality of) codewords 1310.

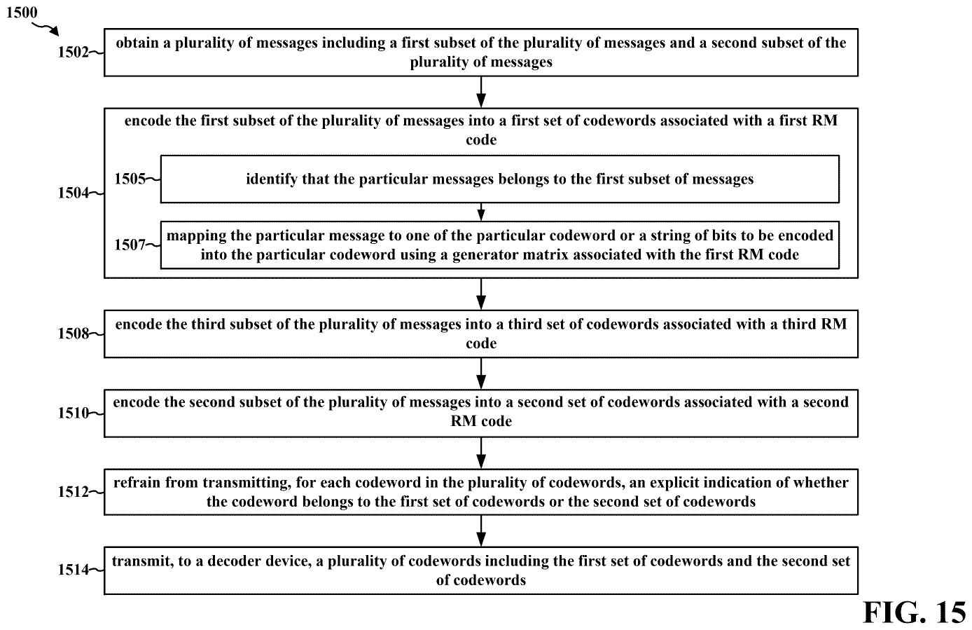

FIG. 15 is a flowchart 1500 of a method of wireless communication. The method may be performed by an encoder (e.g., the encoder 1302) that may be associated with a UE (e.g., the UE 104; the apparatus 1804), a base station (e.g., the base station 102; the network entity 1802, 1902) or a device including the encoder. At 1502, the encoder may obtain a plurality of messages including a first subset of the plurality of messages and a second subset of the plurality of messages. In some aspects, the plurality of messages may further include a third subset (or at least one additional subset) of the plurality of messages. For example, 1502 may be performed by application processor(s) 1806, cellular baseband processor(s) 1824, transceiver(s) 1822, antenna(s) 1880, and/or UMP encoding/decoding component 198/199 of FIG. 18. For example, 1502 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the encoder 1302 may, at 1306, obtain the plurality of messages 1305.

In some aspects, the encoder may encode, at 1504-1510, a plurality of subsets of the plurality of messages using a corresponding plurality of RM codes where 1504, 1508, and 1510 may be performed in any order and/or may be performed multiple times in different orders as messages in different subsets of the plurality of messages are obtained by the encoder. The encoder may, at 1504, encode the first subset of the plurality of messages into a first set of codewords associated with a first RM code. At 1508, the encoder may encode the third subset of the plurality of messages into a third set of codewords associated with a third RM code. The encoder may, at 1510, encode the second subset of the plurality of messages into a second set of codewords associated with a second RM code, where the first RM code is a first subcode of the second RM code and the third RM code is a second subcode of the second RM code that is different from the first subcode (e.g., the first RM code). As described above, the first RM code and the second RM code (and the third RM code), in some aspects, are of a first length (or blocklength). In some aspects, the first RM code of the first length is of a first order (e.g., r), the third RM code is of a third order that is greater than the first order but less than the second order (e.g., r<r′<r+s), and the second RM code of the first length is of a second order that is greater than the first order (e.g., r+s, where s≥1). In some aspects, the first order is associated with a first error tolerance that is greater than a third error tolerance associated with the third RM code which is greater than a second tolerance associated with the second RM code (e.g., dᵣ=2^{m-r-1}>d_{r′}=2^{m-r′-1}>dᵣ₊ₛ=2^{m-r-s-1}, based on the condition that s≥1 and r<r′<r+s).

In some aspects, to encode the first subset of the plurality of messages at 1504, the encoder may, at 1505, identify that the particular message belongs to the first subset of messages and, at 1507, map the particular message to one of the particular codeword or a string of bits to be encoded into the particular codeword using a generator matrix associated with the first RM code. While described for the encoding of the first subset of the plurality of messages, similar steps to 1505 and 1507 may be performed when encoding the second subset and/or third subset of the plurality of messages. For example, 1504-1510 may be performed by application processor(s) 1806, cellular baseband processor(s) 1824, transceiver(s) 1822, antenna(s) 1880, and/or UMP encoding/decoding component 198/199 of FIG. 18. For example, 1504-1510 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the encoder 1302 may, at 1308, encode a plurality of subsets of the plurality of messages 1305 using a corresponding plurality of RM codes (e.g., a first RM code of a common blocklength and a highest order for encoding a first subset of the plurality of messages through an nth RM code of the common blocklength with a lowest order in the plurality of RM codes).

At 1512, the encoder may refrain from transmitting, for each codeword in the plurality of codewords, an explicit indication of whether the codeword belongs to the first subset of codewords or the second set of codewords. At 1516, the encoder may transmit, to a decoder device, the plurality of codewords including the first subset of codewords and the second set of codewords. For example, 1514 and 1516 may be performed by application processor(s) 1806, cellular baseband processor(s) 1824, transceiver(s) 1822, antenna(s) 1880, and/or UMP encoding/decoding component 198/199 of FIG. 18. For example, 1514 and 1516 may be performed by CU processor(s) 1912, DU processor(s) 1932, RU processor(s) 1942, transceiver(s) 1946, antenna(s) 1980, and/or UMP encoding/decoding component 198/199 of FIG. 19. In some aspects, the plurality of codewords may further include the third set of codewords. For example, referring to FIG. 13, the encoder 1302 may transmit the encoded (plurality of) messages as (a plurality of) codewords 1310. In some aspects, the encoder 1302 may refrain, at 1309, from transmitting an explicit indication of a subset of messages associated with each of the (plurality of) codewords 1310.

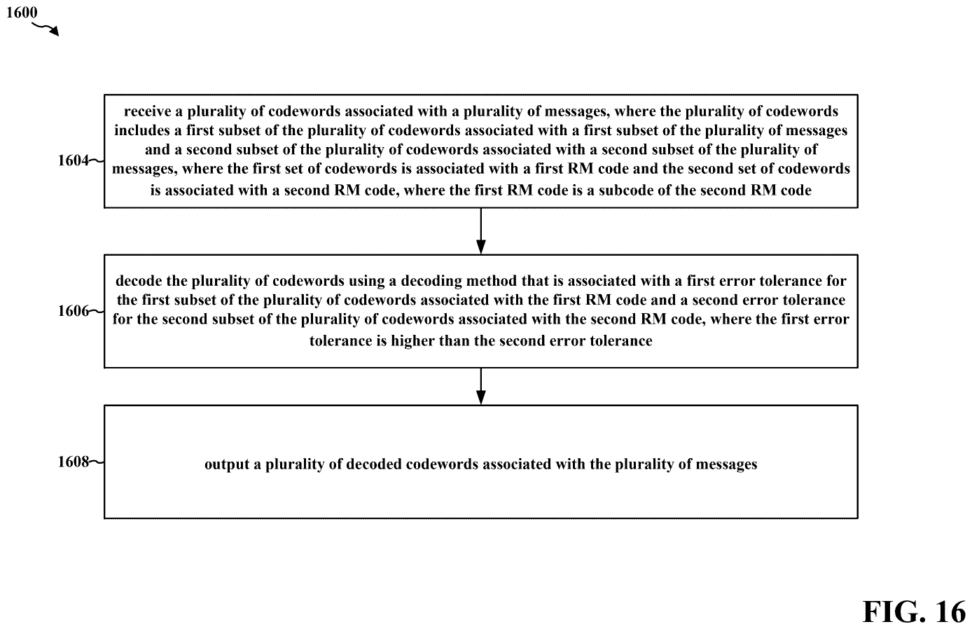

FIG. 16 is a flowchart 1600 of a method of wireless communication. The method may be performed by a decoder (e.g., the decoder 1304) that may be associated with a UE (e.g., the UE 104; the apparatus 1804), a base station (e.g., the base station 102; the network entity 1802, 1902) or a device including the decoder. In some aspects, the decoder may obtain an indication of a codeword length associated with each codeword in the plurality of codewords, a first order associated with a first RM code, a second order associated with a second RM code that is greater than the first order, and a threshold value associated with at least a first error tolerance for a first subset of a plurality of codewords. For example, referring to FIG. 13, the decoder 1304 may obtain a set of parameters for the UMP encoding/decoding. For example, the set of parameters, in some aspects, may include a codeword length associated with each codeword in the plurality of codewords (e.g., m), a first order associated with the first RM code (e.g., r), a second order associated with the second RM code that is greater than the first order (e.g., r+s or s), and a threshold value associated with at least the first error tolerance for the first subset of the plurality of codewords (e.g., 0). In some aspects, other algorithm-dependent parameters may additionally be determined or obtained, such as, for a modified RPA decoding algorithm and/or method, a maximum number (Nₘ) of rounds of projections and aggregations to perform before exiting a (current) recursion.

At 1604, the decoder may receive a plurality of codewords associated with a plurality of messages. In some aspects, the plurality of codewords may include a first subset of the plurality of codewords associated with a first subset of the plurality of messages and a second subset of the plurality of codewords associated with a second subset of the plurality of messages. The first subset of codewords, in some aspects, may be associated with the first RM code and the second subset of codewords may be associated with the second RM code, where the first RM code is a subcode of the second RM code. For example, 1604 may be performed by application processor(s) 1806, cellular baseband processor(s) 1824, transceiver(s) 1822, antenna(s) 1880, and/or UMP encoding/decoding component 198/199 of FIG. 18. For example, 1604 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may receive the encoded (plurality of) messages as (a plurality of) codewords 1310.

At 1606, the decoder may decode the plurality of codewords using a decoding method that is associated with a first error tolerance for first codewords (or a first set of codewords) associated with the first RM code (e.g., the RM(m, r) code) and a second error tolerance for second codewords (or a second set of codewords) associated with the second RM code (e.g., the RM(m, r+s) code), where the second error tolerance is lower than the first error tolerance (e.g., dᵣ₊ₛ=2^{m-r-s-1}<dᵣ=2^{m-r-1}, based on the condition that s≥1). For example, 1606 may be performed by application processor(s) 1806, cellular baseband processor(s) 1824, transceiver(s) 1822, antenna(s) 1880, and/or UMP encoding/decoding component 198/199 of FIG. 18. For example, 1606 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may, at 1312, decode the decode the codewords 1310 using a decoding method such as one of the decoding methods illustrated in FIGS. 10-12, that is associated with a plurality of error tolerances corresponding to the plurality of subsets of the messages. In some aspects, a one-to-one mapping exists from decoded codewords in the plurality of decoded codewords to corresponding messages in the plurality of messages (e.g., a first one-to-one mapping may exist between codewords and sets of bits used to generate the codewords using a generator matrix while a second one-to-one mapping may exist between the sets of bits used to generate the codewords and messages in the plurality of messages, such that each valid codeword can uniquely identify a valid message in the plurality of messages).

In some aspects, each codeword includes a first number of bits (e.g., is of a first length or has a first blocklength). The first number of bits, in some aspects, may include at least a first set of bits associated with a corresponding set of rows of an encoder (e.g., rows of a generator matrix corresponding to Gᵢ for i>r) associated with the first RM code that are not associated with an encoder associated with the subcode of the first RM code. In some aspects, the decoding method is an adapted reed decoder, and the decoding for a particular codeword of the plurality of codewords includes calculating, for each bit in the first set of bits, a first set of binary values (e.g., {C_{S}}_{b}) including a first number (2^{m-t} for t>r) of binary values and comparing, for each bit in the first set of bits, a second number (n_{S}) of the binary values in the first set of binary values that have a first binary value (e.g., a value of “1”) to a threshold number (e.g., θ), where, if the second number is (strictly) less than the threshold number, the bit is set to the second binary value (e.g., a value of “0”), and if the second number is at least the threshold number, the bit is set to the first binary value. In some aspects, the threshold may be applied such that if the second number is less than, or equal to, the threshold number, the bit is set to the second binary value (e.g., a value of “0”), and if the second number is greater than the threshold number, the bit is set to the first binary value (e.g., the inequality for the test may be one of n_{S}<θ or n_{S}≤θ). In some aspects, the threshold number (θ) is a threshold fraction of the first number (e.g., γ2^{m-t}), wherein the threshold fraction is greater than 50 percent (e.g., 0.5<γ<1).

In some aspects, the second RM code is associated with a generator matrix having a first number of rows corresponding to a first number of bits in each decoded codeword, wherein each row uniquely corresponds to an order of the RM code (e.g., is a row of a Gᵢ for one i∈[0, r+s]), where a particular order of the RM code may correspond to one of a single row or multiple rows of the generator matrix (e.g., each Gᵢ may include one or multiple rows). In some aspects, the decoding method may be an adapted (or modified) Reed decoder (As illustrated in FIG. 10), and the decoding for a particular codeword (ƒ) of the plurality of codewords corresponding to a particular message of the plurality of messages, in some aspects may include: (1) setting a current order of the decoder to be the second order (e.g., t=r+s) and a current codeword (ƒₜ) to be the particular codeword (ƒ), and, until the current order is decremented below zero, (2) determining, for each row of the generator matrix corresponding to the current order of the decoder, a corresponding bit value (C_{S}) based on a thresholding operation (e.g., dist({C_{S,b}}_{b}, 0²^{^{m-t}})<θ or C_{S}←majority_{b} {C_{S,b}}) performed on a set of binary values (C_{S,b}) associated with a set of linear combinations of bits in the current codeword, where the thresholding operation is based on the threshold value when a current order (t) of the decoder is greater than the first order (r) and is based on a majority when a current order of the decoder is not greater than the first order (e.g., if t>r and dist({C_{S,b}}_{b}, 0²^{^{m-t}})<θ, then C_{S}←0, else C_{S}←majority_{b}{C_{S,b}}), (3) calculating, based on the determined corresponding bit values, an updated codeword (e.g., Pₜ←Pₜ₊₁+Σ_{S⊆[m]:|S|=t}C_{S} X_{S} and ƒₜ←ƒ−Pₜ₊₁, where Pᵣ₊₁ is initialized to 0 and a current order value, t, begins at r), (4) decrementing the current order of the decoder, going back to (2) based on the current (decremented) order of the decoder, and (5) returning, when the value of the current order is decremented below zero, the determined corresponding bit values as a particular decoded codeword.

In some aspects, when a current order of the decoder is greater than the second order, the thresholding operation based on the threshold value performed on the set of binary values associated with the set of linear combinations of bits in the current codeword as described above may include: (1) comparing a (second) number of non-zero binary values in the set of binary values to the threshold value, (2) setting the bit to zero when the second number is less than the threshold value, and (3) setting the bit to one when the second number is at least the threshold value. In some aspects, the threshold may be applied such that if the distance is less than, or equal to, the threshold number, the bit is set to zero, and if the second number is greater than the threshold number, the bit is set to one (e.g., the inequality for the test may be one of dist ({C_{S,b}}_{b}; 0²^{^{m-t}})<θ or dist({C_{S,b}}_{b}, 0²^{^{m-t}})≤θ). In some aspects, the threshold number (θ) is a threshold fraction of the first number (e.g., γ2^{m-t}), wherein the threshold fraction is greater than 50 percent (e.g., 0.5<γ<1).

As described above, when a current order of the decoder is not greater than the second order, the thresholding operation may be based on the majority performed on the set of binary values associated with the set of linear combinations of bits in the current codeword, and may include: (1) comparing a second number of non-zero values in the set of binary values to a third number of zero values in the set of binary values, (2) setting the bit to zero when the second number is less than the third number, (3) setting the bit to one when the second number is greater than the third number, and, when the second number is equal to the third number, one of (4) indicating a failure to decode, (5) setting the bit to zero, or (6) setting the bit to one, where setting the bit to a value of 0 or 1 may be based on a random (or pseudo-random), or other determination and/or selection.

The first RM code, in some aspects, may be of a first length and of a first order, and the second RM code may be of the first length and of a second order that is greater than the first order. In some aspects, the second (higher) order may be associated with less error tolerance than the first order. The decoding method, in some aspects, may be the modified RPA decoding algorithm and/or method (e.g., as illustrated in FIG. 12) that accepts a length value (m), a first order value (r+s), a second order value (s), a threshold value (θ), and a codeword (y) as input (e.g., RPA-UMP(m,r+s, s, θ, y)) and performs a projection operation on the input codeword that produces a plurality of intermediate codewords (y_{b}_{ᵢ} for i=1, 2, . . . , 2^{m}−1) that are used as the input for a next iteration of the modified RPA decoding algorithm and/or method with a decremented length value and a decremented order value (e.g., RPA-UMP(m−1,r+s−1, s, θ, y_{b}_{ᵢ}) for i=1, 2, . . . , 2^{m}−1). In some aspects, the decoding for a particular codeword of the plurality of codewords may include applying the projection operation for a number of iterations that is equal to one less than the first order of the first RM code (e.g., r−1) and attempting to decode a current intermediate codeword using a FHT. If the decoding using the FHT is successful, the RPA decoding method, in some aspects, uses the decoded codeword at the current recursion to decode codewords associated with previous recursive steps and continues with an aggregation operation to produce a decoded message in the first subset of the plurality of messages (or a decoded codeword in the first subset of codewords). However, if the decoding using the FHT is not successful, the RPA decoding method, in some aspects, may perform an additional set of iterations of the projection operation until the decremented order value is equal to one and then perform the FHT and the aggregation operation to produce a decoded message in the second subset of the plurality of messages (or a decoded codeword in the second subset of codewords). In some aspects, the decoding using the FHT may be determined to be successful if a Hamming distance between the decoded codeword and the input codeword is less than a threshold distance based on the threshold value.

In some aspects, the first RM code may be of a first length and of a first order, and the second RM code may be of the first length and of a second order that is greater than the first order. In some aspects, the second (higher) order may be associated with less error tolerance than the first order. The decoding method, in some aspects, may be the modified RPA decoding algorithm and/or method (e.g., as illustrated in FIG. 11) that accepts a length value (m), a first order value (r+s), a second order value (s), a threshold value (θ), and a codeword (y) as input (e.g., RPA-UMP(m,r+s, s, θ, y)) and performs a projection operation on the input codeword that produces a plurality of intermediate codewords (y_{b}_{ᵢ} for i=1, 2, . . . , 2^{m}−1) that are used as the input for a next iteration of the modified RPA decoding algorithm and/or method with a decremented length value and a decremented order value (e.g., RPA-UMP(m−1,r+s−1, s, θ, y_{b}_{ᵢ}) for i=1, 2, . . . , 2^{m}−1). In some aspects, the decoding for a particular codeword of the plurality of codewords may include applying the projection operation for a first number of iterations that is equal to one more than the first order of the first RM code (e.g., r+1), and comparing, for a current intermediate codeword, a Hamming distance between the current intermediate codeword and a zero codeword to a threshold distance. If the Hamming distance is less than the threshold distance, the RPA decoding method, in some aspects, may provide a zero vector (e.g., 0^{m} at 1101, where m is the input length value to a current recursion (or invocation) of the modified RPA decoding algorithm) of a length that is based on the length value and a current first order value (e.g., based on m−r−1, or 2^{m-r-1}), uses the decoded codeword at the current recursion (e.g., the zero vector) to decode codewords associated with previous recursive steps and continue with an aggregation operation to produce a decoded message in the first subset of the plurality of messages (or a decoded codeword in the first subset of codewords). However, if the Hamming distance is at least the threshold distance, the RPA decoding method, in some aspects, may perform an additional set of iterations of the projection operation until the decremented order value is equal to one and then perform a FHT and the aggregation operation to produce a decoded message in the second subset of the plurality of messages (or a decoded codeword in the second subset of codewords).

In some aspects, the decoding method may be a modified RPA decoding algorithm for decoding an input codeword, where the modified RPA decoding algorithm is based on a first input value associated with the length of the input codeword, a second input value based on the second order, a third input value associated with a first number of recursions (or invocations) of the modified RPA decoding algorithm to perform before attempting to decode the input codeword as a codeword in the first subset of codewords, and a fourth input value associated with the threshold value, where the third input value is based on the difference between the first order and the second order, where the modified RPA decoding algorithm for a second input value equal to 1 includes (or performs) an FHT, where each iteration of the modified RPA decoding algorithm may be performed one of up to a maximum number of times or until a decoded codeword converges. In some aspects the decoding for a particular codeword of the plurality of codewords may include invoking the modified RPA decoding algorithm with a current input codeword that is the particular codeword, a current first input value that is a first value associated with the length of the particular codeword, a current second input value that is the second order, and a third input value that is a third value based on the difference between the first order and the second order, and a fourth input value associated with the threshold value, where upon being invoked, the modified RPA decoding algorithm is associated with: (1) determining whether the first number of invocations of the modified RPA decoding algorithm have been performed based on a current second input value and the third input value, (2) performing, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value, (3) determining, when the first number of invocations of the modified RPA decoding algorithm have been performed, if a current input codeword of a most recent invocation of the modified RPA decoding algorithm is associated with the first subset of codewords based on the fourth input value associated with the threshold value, (4) outputting, when the first number of invocations of the modified RPA decoding algorithm have been performed and based on determining that the current input codeword of the most recent invocation of the modified RPA decoding algorithm is associated with the first subset of codewords, a decoded codeword based on the particular codeword, (5) performing, when the first number of invocations of the modified RPA decoding algorithm have been performed and based on determining that the current input codeword of the most recent invocation of the modified RPA decoding algorithm is not associated with the first subset of codewords, a set of additional projections and invocations of the modified RPA decoding algorithm with an additional decremented first input value and an additional decremented second value until the current second input value is equal to 1 and decoding the current input codeword for each of a plurality of projected codewords associated with the current invocation of the modified RPA decoding algorithm using the FHT, and (6) decoding, based on the decoded current input codeword for each of the plurality of projected codewords, a plurality of input codewords associated with previous invocations of the modified RPA decoding algorithm.

In some aspects, the decoding method is a modified RPA decoding algorithm for decoding an input codeword, where the modified RPA decoding algorithm is based on a first input value associated with the length of the input codeword, a second input value based on the second order associated with the input codeword, a third input value associated with a first number of recursions (or invocations) of the modified RPA decoding algorithm to perform before attempting to decode the input codeword as a codeword in the first subset of codewords, and a fourth input value associated with the threshold value, where the third input value is based on the difference between the first order and the second order. In some aspects, the modified RPA decoding algorithm for a second input value equal to one includes (or performs) a FHT (e.g., a call to the modified RPA decoding algorithm with second input value equal to one is the end of the recursion). In some aspects, each invocation of the modified RPA decoding algorithm for which a particular condition is not met (e.g., for which the recursion is not interrupted) includes performing a projection operation of the input codeword that produces a plurality of intermediate codewords that are each used as the input for a next invocation of the modified RPA decoding algorithm with a decremented first input value associated with the length of the input intermediate codeword and a decremented second input value based on an order associated with the input intermediate codeword, and wherein the decoding for a particular codeword of the plurality of codewords includes: (1) invoking a first recursion of the modified RPA decoding algorithm that invokes additional recursions of the modified RPA decoding algorithm with decremented first input values and decremented second input values until the modified RPA decoding algorithm is invoked with an order value that is equal to one more than the difference between the first order and the second order, (2) attempting to decode a current intermediate codeword using a FHT, (3) outputting, when the decoding using the FHT is successful, a decoded codeword from the first subset of codewords by resolving previous invocations of the modified RPA decoding algorithm based on the decoded current intermediate codeword and an aggregation operation to account for the plurality of invocations of the modified RPA decoding algorithm at each level of recursion, where a first invocation of the modified RPA decoding algorithm may perform an additional round beginning from the projection operation if one of a set of stopping conditions has not been met, and (4) invoking, when the decoding using the FHT is not successful, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition. In some aspects, the decoding using the FHT may be successful if a Hamming distance between the decoded codeword and the input intermediate codeword is less than a threshold distance.

The decoding method, in some aspects, may be a modified RPA decoding algorithm for decoding an input codeword, wherein the modified RPA decoding algorithm is based on a first input value associated with the length of the input codeword, a second input value based on the second order associated with the input codeword, a third input value associated with a first number of invocations of the modified RPA decoding algorithm to perform before attempting to decode the input codeword as a codeword in the first subset of codewords, and a fourth input value associated with the threshold value, wherein the third input value is based on the difference between the first order and the second order, wherein the modified RPA decoding algorithm for a second input value equal to one includes (or performs) a FHT (e.g., a call to the modified RPA decoding algorithm with second input value equal to one is the end of the recursion). Each invocation of the modified RPA decoding algorithm for which a particular condition is not met, in some aspects, may include performing a projection operation on the input codeword that produces a plurality of intermediate codewords that are each used as the input for a next invocation of the modified RPA decoding algorithm with a decremented first input value associated with the length of the input intermediate codeword and a decremented second input value based on an order associated with the input intermediate codeword. In some aspects, the decoding for a particular codeword of the plurality of codewords includes: (1) invoking a first recursion of the modified RPA decoding algorithm that invokes additional recursions of the modified RPA decoding algorithm with decremented first input values and decremented second input values until the modified RPA decoding algorithm is invoked with an order value that is equal to one less than the difference between the first order and the second order, and (2) comparing, for a current intermediate codeword, the fourth input value associated with the threshold value to a Hamming distance between the current intermediate codeword and a zero codeword of a same length as the current intermediate codeword, (3) outputting, when the Hamming distance is less than the fourth input value, a decoded codeword from the first subset of codewords by resolving previous invocations of the modified RPA decoding algorithm based on the zero codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met, and (5) invoking, when the Hamming distance is at least the fourth input value, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion, the aggregation operation to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition.

The decoding method, in some aspects, may be a machine-trained (MT) (e.g., AI/ML or transformer-based architecture in deep learning) RPA decoding method. In some aspects, the MT RPA may be trained to determine whether particular codewords in the plurality of codewords were encoded with the first RM code or the second RM code. The training, in some aspects, may be based on a training set including multiple data sets, where each data set includes (1) multiple projections generated by an RPA decoding method applied to a test codeword encoded with one of the first RM code or the second RM code and (2) an indication of whether the first RM code or the second RM code was used to encode the test codeword. In some aspects, the MT RPA may further be trained to decode an input codeword encoded with the first RM code with a first accuracy based on the first error tolerance and to decode the input codeword encoded with the second RM code with a second accuracy based on the second error tolerance. In some aspects, the MT RPA (or AI/ML decoding method more generally) may be received by the decoder after a training on another device (e.g., the decoder may receive an indication of a structure of the AI/ML decoder and a set of related weights for elements of the AI/ML or a program utilizing and/or implementing a set of learned relationships between projections and a subset of messages).

In some aspects, the decoding method may be a ML aided RPA decoding method, wherein the ML aided RPA is trained to decode first input codewords in the first subset of the plurality of codewords with a first accuracy based on the first error tolerance and to decode second input codewords in the second subset of the plurality of codewords with a second accuracy based on the second error tolerance, and wherein the training is based on a training set comprising, multiple data sets comprising (1) multiple projections generated by an RPA decoding method applied to a test codeword encoded with one of the first RM code or the second RM code and (2) an indication of whether the first RM code or the second RM code was used to encode the test codeword

After decoding the plurality of codewords into a plurality of decoded messages, at 1606, the decoder may output, at 1608, the decoded plurality of messages. The decoded plurality of messages, in some aspects, may be provided to a different component of the decoder, or to a different component of a device including the decoder. For example, 1606 may be performed by application processor(s) 1806, cellular baseband processor(s) 1824, transceiver(s) 1822, antenna(s) 1880, and/or UMP encoding/decoding component 198/199 of FIG. 18. For example, 1606 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may, at 1314, output the decoded plurality of messages 1315. The decoded plurality of messages 1315, in some aspects, may be provided to a different component of the decoder 1304, or to a different component of a device including the decoder 1304.

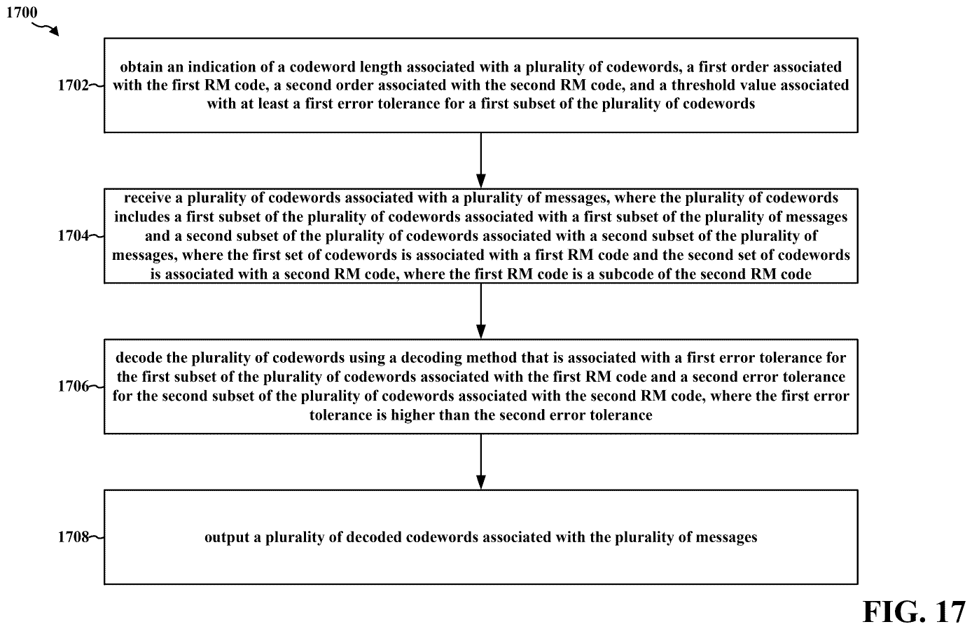

FIG. 17 is a flowchart 1700 of a method of wireless communication. The method may be performed by a decoder (e.g., the decoder 1304) that may be associated with a UE (e.g., the UE 104; the apparatus 1804), a base station (e.g., the base station 102; the network entity 1802, 1902) or a device including the decoder. At 1702, the decoder may obtain an indication of a codeword length associated with each codeword in the plurality of codewords, a first order associated with a first RM code, a second order associated with a second RM code that is greater than the first order, and a threshold value associated with at least a first error tolerance for a first subset of a plurality of codewords. For example, 1702 may be performed by application processor(s) 1806, cellular baseband processor(s) 1824, transceiver(s) 1822, antenna(s) 1880, and/or UMP encoding/decoding component 198/199 of FIG. 18. For example, 1702 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may obtain a set of parameters for the UMP encoding/decoding. For example, the set of parameters, in some aspects, may include a codeword length associated with each codeword in the plurality of codewords (e.g., m), a first order associated with the first RM code (e.g., r), a second order associated with the second RM code that is greater than the first order (e.g., r+s or s), and a threshold value associated with at least the first error tolerance for the first subset of the plurality of codewords (e.g., θ). In some aspects, other algorithm-dependent parameters may additionally be determined or obtained, such as, for a modified RPA decoding algorithm and/or method, a maximum number (Nₘ) of rounds of projections and aggregations to perform before exiting a (current) recursion.

At 1704, the decoder may receive a plurality of codewords associated with a plurality of messages. In some aspects, the plurality of codewords may include a first subset of the plurality of codewords associated with a first subset of the plurality of messages and a second subset of the plurality of codewords associated with a second subset of the plurality of messages. The first subset of codewords, in some aspects, may be associated with the first RM code and the second subset of codewords may be associated with the second RM code, where the first RM code is a subcode of the second RM code. For example, 1704 may be performed by application processor(s) 1806, cellular baseband processor(s) 1824, transceiver(s) 1822, antenna(s) 1880, and/or UMP encoding/decoding component 198/199 of FIG. 18. For example, 1704 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may receive the encoded (plurality of) messages as (a plurality of) codewords 1310. At 1706, the decoder may decode the plurality of codewords using a decoding method that is associated with a first error tolerance for first codewords (or a first set of codewords) associated with the first RM code (e.g., the RM(m, r) code) and a second error tolerance for second codewords (or a second set of codewords) associated with the second RM code (e.g., the RM(m, r+s) code), where the second error tolerance is lower than the first error tolerance (e.g., dᵣ₊ₛ=2^{m-r-s-1}<dᵣ=2^{m-r-1}, based on the condition that s≥1). For example, 1706 may be performed by application processor(s) 1806, cellular baseband processor(s) 1824, transceiver(s) 1822, antenna(s) 1880, and/or UMP encoding/decoding component 198/199 of FIG. 18. For example, 1706 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may, at 1312, decode the decode the codewords 1310 using a decoding method such as one of the decoding methods illustrated in FIGS. 10-12, that is associated with a plurality of error tolerances corresponding to the plurality of subsets of the messages. In some aspects, a one-to-one mapping exists from decoded codewords in the plurality of decoded codewords to corresponding messages in the plurality of messages (e.g., a first one-to-one mapping may exist between codewords and sets of bits used to generate the codewords using a generator matrix while a second one-to-one mapping may exist between the sets of bits used to generate the codewords and messages in the plurality of messages, such that each valid codeword can uniquely identify a valid message in the plurality of messages).

In some aspects, each codeword includes a first number of bits (e.g., is of a first length or has a first blocklength). The first number of bits, in some aspects, may include at least a first set of bits associated with a corresponding set of rows of an encoder (e.g., rows of a generator matrix corresponding to Gᵢ for i>r) associated with the first RM code that are not associated with an encoder associated with the subcode of the first RM code. In some aspects, the decoding method is an adapted reed decoder, and the decoding for a particular codeword of the plurality of codewords includes calculating, for each bit in the first set of bits, a first set of binary values (e.g., {Cₛ}_{b}) including a first number (2^{m-t} for t>r) of binary values and comparing, for each bit in the first set of bits, a second number (n_{S}) of the binary values in the first set of binary values that have a first binary value (e.g., a value of “1”) to a threshold number (e.g., θ), where, if the second number is (strictly) less than the threshold number, the bit is set to the second binary value (e.g., a value of “0”), and if the second number is at least the threshold number, the bit is set to the first binary value. In some aspects, the threshold may be applied such that if the second number is less than, or equal to, the threshold number, the bit is set to the second binary value (e.g., a value of “0”), and if the second number is greater than the threshold number, the bit is set to the first binary value (e.g., the inequality for the test may be one of n_{S}<θ or n_{S}≤θ). In some aspects, the threshold number (θ) is a threshold fraction of the first number (e.g., γ2^{m-t}), wherein the threshold fraction is greater than 50 percent (e.g., 0.5<γ<1).

In some aspects, the second RM code is associated with a generator matrix having a first number of rows corresponding to a first number of bits in each decoded codeword, wherein each row uniquely corresponds to an order of the RM code (e.g., is a row of a Gᵢ for one i∈[0, r+s]), where a particular order of the RM code may correspond to one of a single row or multiple rows of the generator matrix (e.g., each Gᵢ may include one or multiple rows). In some aspects, the decoding method may be an adapted (or modified) Reed decoder (As illustrated in FIG. 10), and the decoding for a particular codeword (ƒ) of the plurality of codewords corresponding to a particular message of the plurality of messages, in some aspects may include: (1) setting a current order of the decoder to be the second order (e.g., t=r+s) and a current codeword (ƒₜ) to be the particular codeword (ƒ), and, until the current order is decremented below zero, (2) determining, for each row of the generator matrix corresponding to the current order of the decoder, a corresponding bit value (C_{S}) based on a thresholding operation (e.g., dist ({C_{S,b}}_{b}, 0²^{^{m-t}})<θ or C_{S}←majority, {C_{S,b}}) performed on a set of binary values (C_{S,b}) associated with a set of linear combinations of bits in the current codeword, where the thresholding operation is based on the threshold value when a current order (t) of the decoder is greater than the first order (r) and is based on a majority when a current order of the decoder is not greater than the first order (e.g., if t>r and dist ({C_{S,b}}_{b}, 0²^{^{m-t}})<θ, then C_{S}←0, else C_{S}←majority_{b}{C_{S,b}}), (3) calculating, based on the determined corresponding bit values, an updated codeword (e.g., Pₜ←Pₜ₊₁+Σ_{S⊆[m]:|S|=t}C_{S}X_{S} and ƒₜ←ƒ−Pₜ₊₁, where Pᵣ₊₁ is initialized to 0 and a current order value, t, begins at r), (4) decrementing the current order of the decoder, going back to (2) based on the current (decremented) order of the decoder, and (5) returning, when the value of the current order is decremented below zero, the determined corresponding bit values as a particular decoded codeword.

In some aspects, when a current order of the decoder is greater than the second order, the thresholding operation based on the threshold value performed on the set of binary values associated with the set of linear combinations of bits in the current codeword as described above may include: (1) comparing a (second) number of non-zero binary values in the set of binary values to the threshold value, (2) setting the bit to zero when the second number is less than the threshold value, and (3) setting the bit to one when the second number is at least the threshold value. In some aspects, the threshold may be applied such that if the distance is less than, or equal to, the threshold number, the bit is set to zero, and if the second number is greater than the threshold number, the bit is set to one (e.g., the inequality for the test may be one of dist{C_{S,b}}_{b}, 0²^{^{m-t}})<θ or dist ({C_{S,b}}_{b}, 0²^{^{m-t}})≤θ). In some aspects, the threshold number (θ) is a threshold fraction of the first number (e.g., γ2^{m-t}), wherein the threshold fraction is greater than 50 percent (e.g., 0.5<γ<1).

As described above, when a current order of the decoder is not greater than the second order, the thresholding operation may be based on the majority performed on the set of binary values associated with the set of linear combinations of bits in the current codeword, and may include: (1) comparing a second number of non-zero values in the set of binary values to a third number of zero values in the set of binary values, (2) setting the bit to zero when the second number is less than the third number, (3) setting the bit to one when the second number is greater than the third number, and, when the second number is equal to the third number, one of (4) indicating a failure to decode, (5) setting the bit to zero, or (6) setting the bit to one, where setting the bit to a value of 0 or 1 may be based on a random (or pseudo-random), or other determination and/or selection.

The first RM code, in some aspects, may be of a first length and of a first order, and the second RM code may be of the first length and of a second order that is greater than the first order. In some aspects, the second (higher) order may be associated with less error tolerance than the first order. The decoding method, in some aspects, may be the modified RPA decoding algorithm and/or method (e.g., as illustrated in FIG. 12) that accepts a length value (m), a first order value (r+s), a second order value (s), a threshold value (θ), and a codeword (y) as input (e.g., RPA-UMP(m,r+s, s, θ, y)) and performs a projection operation on the input codeword that produces a plurality of intermediate codewords (y_{b}_{ᵢ} for i=1, 2, . . . , 2^{m}−1) that are used as the input for a next iteration of the modified RPA decoding algorithm and/or method with a decremented length value and a decremented order value (e.g., RPA-UMP(m−1,r+s−1, s, θ, y_{b}_{ᵢ}) for i=1, 2, . . . , 2^{m}−1). In some aspects, the decoding for a particular codeword of the plurality of codewords may include applying the projection operation for a number of iterations that is equal to one less than the first order of the first RM code (e.g., r−1) and attempting to decode a current intermediate codeword using a FHT. If the decoding using the FHT is successful, the RPA decoding method, in some aspects, uses the decoded codeword at the current recursion to decode codewords associated with previous recursive steps and continues with an aggregation operation to produce a decoded message in the first subset of the plurality of messages (or a decoded codeword in the first subset of codewords). However, if the decoding using the FHT is not successful, the RPA decoding method, in some aspects, may perform an additional set of iterations of the projection operation until the decremented order value is equal to one and then perform the FHT and the aggregation operation to produce a decoded message in the second subset of the plurality of messages (or a decoded codeword in the second subset of codewords). In some aspects, the decoding using the FHT may be determined to be successful if a Hamming distance between the decoded codeword and the input codeword is less than a threshold distance based on the threshold value.

In some aspects, the first RM code may be of a first length and of a first order, and the second RM code may be of the first length and of a second order that is greater than the first order. In some aspects, the second (higher) order may be associated with less error tolerance than the first order. The decoding method, in some aspects, may be the modified RPA decoding algorithm and/or method (e.g., as illustrated in FIG. 11) that accepts a length value (m), a first order value (r+s), a second order value (s), a threshold value (θ), and a codeword (y) as input (e.g., RPA-UMP(m,r+s, s, θ, y)) and performs a projection operation on the input codeword that produces a plurality of intermediate codewords (y_{b}_{ᵢ} for i=1, 2, . . . , 2^{m}−1) that are used as the input for a next iteration of the modified RPA decoding algorithm and/or method with a decremented length value and a decremented order value (e.g., RPA-UMP(m−1,r+s−1, s, θ, y_{b}_{ᵢ}) for i=1, 2, . . . , 2^{m}−1). In some aspects, the decoding for a particular codeword of the plurality of codewords may include applying the projection operation for a first number of iterations that is equal to one more than the first order of the first RM code (e.g., r+1), and comparing, for a current intermediate codeword, a Hamming distance between the current intermediate codeword and a zero codeword to a threshold distance. If the Hamming distance is less than the threshold distance, the RPA decoding method, in some aspects, may provide a zero vector of a length that is based on the length value and a current first order value (e.g., based on m−r−1, or 2^{m-r-1}), uses the decoded codeword at the current recursion (e.g., the zero vector) to decode codewords associated with previous recursive steps and continue with an aggregation operation to produce a decoded message in the first subset of the plurality of messages (or a decoded codeword in the first subset of codewords). However, if the Hamming distance is at least the threshold distance, the RPA decoding method, in some aspects, may perform an additional set of iterations of the projection operation until the decremented order value is equal to one and then perform a FHT and the aggregation operation to produce a decoded message in the second subset of the plurality of messages (or a decoded codeword in the second subset of codewords).

In some aspects, the decoding method may be a modified RPA decoding algorithm for decoding an input codeword, where the modified RPA decoding algorithm is based on a first input value associated with the length of the input codeword, a second input value based on the second order, a third input value associated with a first number of recursions (or invocations) of the modified RPA decoding algorithm to perform before attempting to decode the input codeword as a codeword in the first subset of codewords, and a fourth input value associated with the threshold value, where the third input value is based on the difference between the first order and the second order, where the modified RPA decoding algorithm for a second input value equal to 1 includes (or performs) an FHT, where each iteration of the modified RPA decoding algorithm may be performed one of up to a maximum number of times or until a decoded codeword converges. In some aspects the decoding for a particular codeword of the plurality of codewords may include invoking the modified RPA decoding algorithm with a current input codeword that is the particular codeword, a current first input value that is a first value associated with the length of the particular codeword, a current second input value that is the second order, and a third input value that is a third value based on the difference between the first order and the second order, and a fourth input value associated with the threshold value, where upon being invoked, the modified RPA decoding algorithm is associated with: (1) determining whether the first number of invocations of the modified RPA decoding algorithm have been performed based on a current second input value and the third input value, (2) performing, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value, (3) determining, when the first number of invocations of the modified RPA decoding algorithm have been performed, if a current input codeword of a most recent invocation of the modified RPA decoding algorithm is associated with the first subset of codewords based on the fourth input value associated with the threshold value (e.g., for a first order equal to r, After r−1 steps of recursion, the current input codeword (at this invocation of the recursive method) is compared with the codewords in a RM(m−r+1,1) code based on the threshold value), (4) outputting, when the first number of invocations of the modified RPA decoding algorithm have been performed and based on determining that the current input codeword of the most recent invocation of the modified RPA decoding algorithm is associated with the first subset of codewords, a decoded codeword based on the particular codeword, (5) performing, when the first number of invocations of the modified RPA decoding algorithm have been performed and based on determining that the current input codeword of the most recent invocation of the modified RPA decoding algorithm is not associated with the first subset of codewords, a set of additional projections and invocations of the modified RPA decoding algorithm with an additional decremented first input value and an additional decremented second value until the current second input value is equal to 1 and decoding the current input codeword for each of a plurality of projected codewords associated with the current invocation of the modified RPA decoding algorithm using the FHT, and (6) decoding, based on the decoded current input codeword for each of the plurality of projected codewords, a plurality of input codewords associated with previous invocations of the modified RPA decoding algorithm.

In some aspects, the decoding method is a modified RPA decoding algorithm for decoding an input codeword, where the modified RPA decoding algorithm is based on a first input value associated with the length of the input codeword, a second input value based on the second order associated with the input codeword, a third input value associated with a first number of recursions (or invocations) of the modified RPA decoding algorithm to perform before attempting to decode the input codeword as a codeword in the first subset of codewords, and a fourth input value associated with the threshold value, where the third input value is based on the difference between the first order and the second order. In some aspects, the modified RPA decoding algorithm for a second input value equal to one includes (or performs) a FHT (e.g., a call to the modified RPA decoding algorithm with second input value equal to one is the end of the recursion). In some aspects, each invocation of the modified RPA decoding algorithm for which a particular condition is not met (e.g., for which the recursion is not interrupted) includes performing a projection operation of the input codeword that produces a plurality of intermediate codewords that are each used as the input for a next invocation of the modified RPA decoding algorithm with a decremented first input value associated with the length of the input intermediate codeword and a decremented second input value based on an order associated with the input intermediate codeword, and wherein the decoding for a particular codeword of the plurality of codewords includes: (1) invoking a first recursion of the modified RPA decoding algorithm that invokes additional recursions of the modified RPA decoding algorithm with decremented first input values and decremented second input values until the modified RPA decoding algorithm is invoked with an order value that is equal to one more than the difference between the first order and the second order, (2) attempting to decode a current intermediate codeword using a FHT, (3) outputting, when the decoding using the FHT is successful, a decoded codeword from the first subset of codewords by resolving previous invocations of the modified RPA decoding algorithm based on the decoded current intermediate codeword and an aggregation operation to account for the plurality of invocations of the modified RPA decoding algorithm at each level of recursion, where a first invocation of the modified RPA decoding algorithm may perform an additional round beginning from the projection operation if one of a set of stopping conditions has not been met, and (4) invoking, when the decoding using the FHT is not successful, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition. In some aspects, the decoding using the FHT may be successful if a Hamming distance between the decoded codeword and the input intermediate codeword is less than a threshold distance.

The decoding method, in some aspects, may be a modified RPA decoding algorithm for decoding an input codeword, wherein the modified RPA decoding algorithm is based on a first input value associated with the length of the input codeword, a second input value based on the second order associated with the input codeword, a third input value associated with a first number of invocations of the modified RPA decoding algorithm to perform before attempting to decode the input codeword as a codeword in the first subset of codewords, and a fourth input value associated with the threshold value, wherein the third input value is based on the difference between the first order and the second order, wherein the modified RPA decoding algorithm for a second input value equal to one includes (or performs) a FHT (e.g., a call to the modified RPA decoding algorithm with second input value equal to one is the end of the recursion). Each invocation of the modified RPA decoding algorithm for which a particular condition is not met, in some aspects, may include performing a projection operation on the input codeword that produces a plurality of intermediate codewords that are each used as the input for a next invocation of the modified RPA decoding algorithm with a decremented first input value associated with the length of the input intermediate codeword and a decremented second input value based on an order associated with the input intermediate codeword. In some aspects, the decoding for a particular codeword of the plurality of codewords includes: (1) invoking a first recursion of the modified RPA decoding algorithm that invokes additional recursions of the modified RPA decoding algorithm with decremented first input values and decremented second input values until the modified RPA decoding algorithm is invoked with an order value that is equal to one less than the difference between the first order and the second order, and (2) comparing, for a current intermediate codeword, the fourth input value associated with the threshold value to a Hamming distance between the current intermediate codeword and a zero codeword of a same length as the current intermediate codeword, (3) outputting, when the Hamming distance is less than the fourth input value, a decoded codeword from the first subset of codewords by resolving previous invocations of the modified RPA decoding algorithm based on the zero codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met, and (5) invoking, when the Hamming distance is at least the fourth input value, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion, the aggregation operation to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition.

The decoding method, in some aspects, may be a machine-trained (MT) (e.g., AI/ML or transformer-based architecture in deep learning) RPA decoding method. In some aspects, the MT RPA may be trained to determine whether particular codewords in the plurality of codewords were encoded with the first RM code or the second RM code. The training, in some aspects, may be based on a training set including multiple data sets, where each data set includes (1) multiple projections generated by an RPA decoding method applied to a test codeword encoded with one of the first RM code or the second RM code and (2) an indication of whether the first RM code or the second RM code was used to encode the test codeword. In some aspects, the MT RPA may further be trained to decode an input codeword encoded with the first RM code with a first accuracy based on the first error tolerance and to decode the input codeword encoded with the second RM code with a second accuracy based on the second error tolerance. In some aspects, the MT RPA (or AI/ML decoding method more generally) may be received by the decoder after a training on another device (e.g., the decoder may receive an indication of a structure of the AI/ML decoder and a set of related weights for elements of the AI/ML or a program utilizing and/or implementing a set of learned relationships between projections and a subset of messages).

In some aspects, the decoding method may be a ML aided RPA decoding method, wherein the ML aided RPA is trained to decode first input codewords in the first subset of the plurality of codewords with a first accuracy based on the first error tolerance and to decode second input codewords in the second subset of the plurality of codewords with a second accuracy based on the second error tolerance, and wherein the training is based on a training set comprising, multiple data sets comprising (1) multiple projections generated by an RPA decoding method applied to a test codeword encoded with one of the first RM code or the second RM code and (2) an indication of whether the first RM code or the second RM code was used to encode the test codeword

After decoding the plurality of codewords into a plurality of decoded messages, at 1706, the decoder may output, at 1708, the decoded plurality of messages. The decoded plurality of messages, in some aspects, may be provided to a different component of the decoder, or to a different component of a device including the decoder. For example, 1706 may be performed by application processor(s) 1806, cellular baseband processor(s) 1824, transceiver(s) 1822, antenna(s) 1880, and/or UMP encoding/decoding component 198/199 of FIG. 18. For example, 1706 may be performed by CU processor(s) 1912, DU processor(s) 1932, RU processor(s) 1942, transceiver(s) 1946, antenna(s) 1980, and/or UMP encoding/decoding component 198/199 of FIG. 19. For example, referring to FIG. 13, the decoder 1304 may, at 1314, output the decoded plurality of messages 1315. The decoded plurality of messages 1315, in some aspects, may be provided to a different component of the decoder 1304, or to a different component of a device including the decoder 1304.

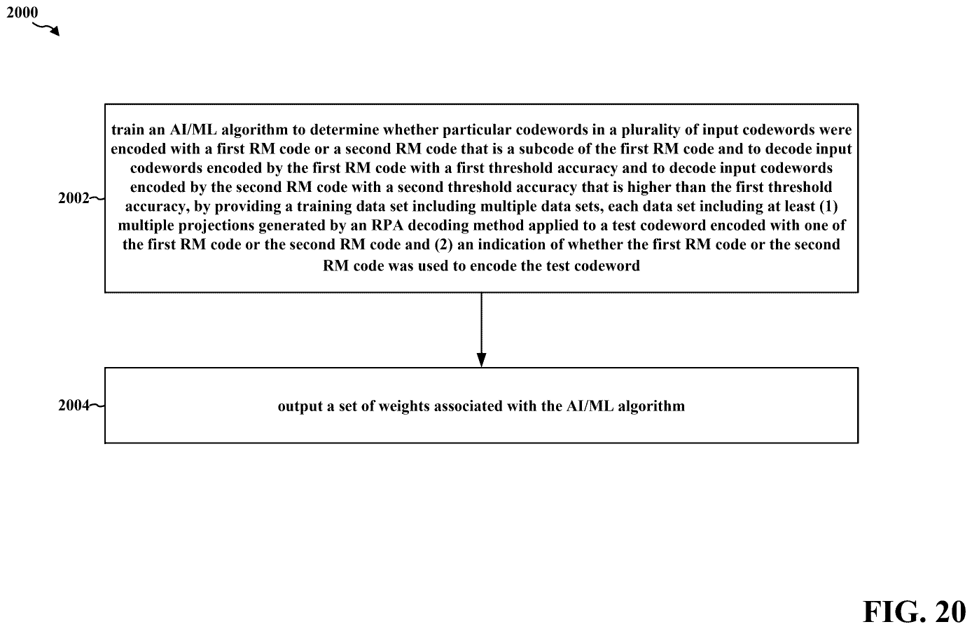

FIG. 20 is a flowchart 2000 of a method of training an AI/ML algorithm. The method may be performed by a model training component (e.g., the model training host 502). At 2002, the model training component may train a MT (or AI/ML) algorithm to determine whether particular codewords in a plurality of input codewords were encoded with a first RM code or a second RM code that is a subcode of the first RM code and to decode input codewords encoded by the first RM code with a first threshold accuracy and to decode input codewords encoded by the second RM code with a second threshold accuracy that is higher than the first threshold accuracy, by providing a training data set including multiple data sets, each data set including at least (1) multiple projections generated by an RPA decoding method applied to a test codeword encoded with one of the first RM code or the second RM code and (2) an indication of whether the first RM code or the second RM code was used to encode the test codeword. For example, 2002 may be performed by the AI/ML architecture 500, the data source 506, or the model training host 502 of FIG. 5.

At 2004, the model training component may output the set of weights associated with the MT algorithm. For example, 2004 may be performed by the AI/ML architecture 500, the data source 506, or the model training host 502 of FIG. 5.

FIG. 18 is a diagram 1800 illustrating an example of a hardware implementation for an apparatus 1804. The apparatus 1804 may be a UE, a component of a UE, or may implement UE functionality. In some aspects, the apparatus 1804 may include at least one cellular baseband processor 1824 (also referred to as a modem) coupled to one or more transceivers 1822 (e.g., cellular RF transceiver). The cellular baseband processor(s) 1824 may include at least one on-chip memory 1824′. In some aspects, the apparatus 1804 may further include one or more subscriber identity modules (SIM) cards 1820 and at least one application processor 1806 coupled to a secure digital (SD) card 1808 and a screen 1810. The application processor(s) 1806 may include on-chip memory 1806′. In some aspects, the apparatus 1804 may further include a Bluetooth module 1812, a WLAN module 1814, an SPS module 1816 (e.g., GNSS module), one or more sensor modules 1818 (e.g., barometric pressure sensor/altimeter; motion sensor such as inertial measurement unit (IMU), gyroscope, and/or accelerometer(s); light detection and ranging (LIDAR), radio assisted detection and ranging (RADAR), sound navigation and ranging (SONAR), magnetometer, audio and/or other technologies used for positioning), additional memory modules 1826, a power supply 1830, and/or a camera 1832. The Bluetooth module 1812, the WLAN module 1814, and the SPS module 1816 may include an on-chip transceiver (TRX) (or in some cases, just a receiver (RX)). The Bluetooth module 1812, the WLAN module 1814, and the SPS module 1816 may include their own dedicated antennas and/or utilize one or more antennas 1880 for communication. The cellular baseband processor(s) 1824 communicates through the transceiver(s) 1822 via the one or more antennas 1880 with the UE 104 and/or with an RU associated with a network entity 1802. The cellular baseband processor(s) 1824 and the application processor(s) 1806 may each include a computer-readable medium/memory 1824′, 1806′, respectively. The additional memory modules 1826 may also be considered a computer-readable medium/memory. Each computer-readable medium/memory 1824′, 1806′, 1826 may be non-transitory. The cellular baseband processor(s) 1824 and the application processor(s) 1806 are each responsible for general processing, including the execution of software stored on the computer-readable medium/memory. The software, when executed by the cellular baseband processor(s) 1824/application processor(s) 1806, causes the cellular baseband processor(s) 1824/application processor(s) 1806 to perform the various functions described supra. The computer-readable medium/memory may also be used for storing data that is manipulated by the cellular baseband processor(s) 1824/application processor(s) 1806 when executing software. The cellular baseband processor(s) 1824/application processor(s) 1806 may be a component of the UE 350 and may include the at least one memory 360 and/or at least one of the TX processor 368, the RX processor 356, and the controller/processor 359. In one configuration, the apparatus 1804 may be at least one processor chip (modem and/or application) and include just the cellular baseband processor(s) 1824 and/or the application processor(s) 1806, and in another configuration, the apparatus 1804 may be the entire UE (e.g., see UE 350 of FIG. 3) and include the additional modules of the apparatus 1804.

As discussed supra, the UMP encoding/decoding component 198/199 may be configured to obtain a plurality of messages comprising a first subset of the plurality of messages and a second subset of the plurality of messages, encode the first subset of the plurality of messages into a first set of codewords associated with a first RM code, encode the second subset of the plurality of messages into a second set of codewords associated with a second RM code, where the first RM code is a subcode of the second RM code, and transmit, to a decoder device, the plurality of codewords. In some aspects, the UMP encoding/decoding component 198/199 may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages. The UMP encoding/decoding component 198/199 may be within the cellular baseband processor(s) 1824, the application processor(s) 1806, or both the cellular baseband processor(s) 1824 and the application processor(s) 1806. The UMP encoding/decoding component 198/199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. As shown, the apparatus 1804 may include a variety of components configured for various functions. In one configuration, the apparatus 1804, and in particular the cellular baseband processor(s) 1824 and/or the application processor(s) 1806, may include means for obtaining a plurality of messages comprising a first subset of the plurality of messages and a second subset of the plurality of messages. The apparatus 1804, and in particular the cellular baseband processor(s) 1824 and/or the application processor(s) 1806, may include means for encoding the first subset of the plurality of messages into a first set of codewords associated with a first Reed-Muller (RM) code. The apparatus 1804, and in particular the cellular baseband processor(s) 1824 and/or the application processor(s) 1806, may include means for encoding the second subset of the plurality of messages into a second set of codewords associated with a second RM code, wherein the first RM code is a subcode of the second RM code. The apparatus 1804, and in particular the cellular baseband processor(s) 1824 and/or the application processor(s) 1806, may include means for transmitting, to a decoder device, a plurality of codewords comprising the first subset of codewords and the second set of codewords. The apparatus 1804, and in particular the cellular baseband processor(s) 1824 and/or the application processor(s) 1806, may include means for refraining from transmitting, for each codeword in the plurality of codewords, an explicit indication of whether the codeword belongs to the first subset of codewords or the second subset of codewords. The apparatus 1804, and in particular the cellular baseband processor(s) 1824 and/or the application processor(s) 1806, may include means for mapping the particular message to one of the particular codeword or a string of bits to be encoded into the particular codeword using a generator matrix associated with the first RM code. The apparatus 1804, and in particular the cellular baseband processor(s) 1824 and/or the application processor(s) 1806, may include means for encoding a third subset of the plurality of messages into a third set of codewords associated with a third RM code.

The apparatus 1804, and in particular the cellular baseband processor(s) 1824 and/or the application processor(s) 1806, may include means for receiving a plurality of codewords associated with a plurality of messages, wherein the plurality of codewords comprises a first subset of the plurality of codewords associated with a first subset of the plurality of messages and a second subset of the plurality of codewords associated with a second subset of the plurality of messages, wherein the first subset of codewords is associated with a first Reed-Muller (RM) code and the second subset of codewords is associated with a second RM code, wherein the first RM code is a subcode of the second RM code. The apparatus 1804, and in particular the cellular baseband processor(s) 1824 and/or the application processor(s) 1806, may include means for decoding the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance. The apparatus 1804, and in particular the cellular baseband processor(s) 1824 and/or the application processor(s) 1806, may include means for outputting a plurality of decoded codewords associated with the plurality of messages. The apparatus 1804, and in particular the cellular baseband processor(s) 1824 and/or the application processor(s) 1806, may include means for obtaining an indication of a codeword length associated with each codeword in the plurality of codewords, a first order associated with a first RM code, a second order associated with a second RM code that is greater than the first order, and a threshold value associated with at least a first error tolerance for a first subset of a plurality of codewords. The apparatus 1804, and in particular the cellular baseband processor(s) 1824 and/or the application processor(s) 1806, may include means for setting a current order of the decoder to be the second order and a current codeword to be the particular codeword. The apparatus 1804, and in particular the cellular baseband processor(s) 1824 and/or the application processor(s) 1806, may include means for determining, for each row of the generator matrix corresponding to the current order of the decoder and until the current order is decremented below zero, a corresponding bit value based on a thresholding operation performed on a set of binary values associated with a set of linear combinations of bits in the current codeword, wherein the thresholding operation is based on the threshold value when a current order of the decoder is greater than the first order and is based on a majority when a current order of the decoder is not greater than the first order. The apparatus 1804, and in particular the cellular baseband processor(s) 1824 and/or the application processor(s) 1806, may include means for calculating, based on the determined corresponding bit values, an updated codeword. The apparatus 1804, and in particular the cellular baseband processor(s) 1824 and/or the application processor(s) 1806, may include means for decrementing the current order of the decoder. The apparatus 1804, and in particular the cellular baseband processor(s) 1824 and/or the application processor(s) 1806, may include means for returning, when the value of the current order is decremented below zero, the determined corresponding bit values as a particular decoded codeword. The apparatus 1804, and in particular the cellular baseband processor(s) 1824 and/or the application processor(s) 1806, may include means for comparing a second number of non-zero binary values in the set of binary values to the threshold value. The apparatus 1804, and in particular the cellular baseband processor(s) 1824 and/or the application processor(s) 1806, may include means for setting the bit to zero when the second number is less than the threshold value. The apparatus 1804, and in particular the cellular baseband processor(s) 1824 and/or the application processor(s) 1806, may include means for setting the bit to one when the second number is at least the threshold value. The apparatus 1804, and in particular the cellular baseband processor(s) 1824 and/or the application processor(s) 1806, may include means for comparing a second number of non-zero values in the set of binary values to a third number of zero values in the set of binary values. The apparatus 1804, and in particular the cellular baseband processor(s) 1824 and/or the application processor(s) 1806, may include means for setting the bit to zero when the second number is less than the third number. The apparatus 1804, and in particular the cellular baseband processor(s) 1824 and/or the application processor(s) 1806, may include means for setting the bit to one when the second number is greater than the third number. The apparatus 1804, and in particular the cellular baseband processor(s) 1824 and/or the application processor(s) 1806, may include means for indicating a failure to decode, setting the bit to zero, or setting the bit to one, when the second number is equal to the third number. The apparatus 1804, and in particular the cellular baseband processor(s) 1824 and/or the application processor(s) 1806, may include means for determining whether the first number of invocations of the modified RPA decoding algorithm have been performed based on a current second input value and the third input value.

The apparatus 1804, and in particular the cellular baseband processor(s) 1824 and/or the application processor(s) 1806, may include means for performing, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value. The apparatus 1804, and in particular the cellular baseband processor(s) 1824 and/or the application processor(s) 1806, may include means for determining, when the first number of invocations of the modified RPA decoding algorithm have been performed, if a current input codeword of a most recent invocation of the modified RPA decoding algorithm is associated with the first subset of codewords based on the fourth input value associated with the threshold value. The apparatus 1804, and in particular the cellular baseband processor(s) 1824 and/or the application processor(s) 1806, may include means for outputting, when the first number of invocations of the modified RPA decoding algorithm have been performed and based on determining that the current input codeword of the most recent invocation of the modified RPA decoding algorithm is associated with the first subset of codewords, a decoded codeword based on the particular codeword. The apparatus 1804, and in particular the cellular baseband processor(s) 1824 and/or the application processor(s) 1806, may include means for performing, when the first number of invocations of the modified RPA decoding algorithm have been performed and based on determining that the current input codeword of the most recent invocation of the modified RPA decoding algorithm is not associated with the first subset of codewords, a set of additional projections and invocations of the modified RPA decoding algorithm with an additional decremented first input value and an additional decremented second value until the current second input value is equal to 1 and decoding the current input codeword for each of a plurality of projected codewords associated with the current invocation of the modified RPA decoding algorithm using the FHT. The apparatus 1804, and in particular the cellular baseband processor(s) 1824 and/or the application processor(s) 1806, may include means for decoding, based on the decoded current input codeword for each of the plurality of projected codewords, a plurality of input codewords associated with previous invocations of the modified RPA decoding algorithm.

The apparatus 1804, and in particular the cellular baseband processor(s) 1824 and/or the application processor(s) 1806, may include means for invoking a first recursion of the modified RPA decoding algorithm that invokes additional recursions of the modified RPA decoding algorithm with decremented first input values and decremented second input values until the modified RPA decoding algorithm is invoked with an order value that is equal to one more than the difference between the first order and the second order. The apparatus 1804, and in particular the cellular baseband processor(s) 1824 and/or the application processor(s) 1806, may include means for attempting to decode a current intermediate codeword using a fast Hadamard transform (FHT). The apparatus 1804, and in particular the cellular baseband processor(s) 1824 and/or the application processor(s) 1806, may include means for outputting, when the decoding using the FHT is successful, a decoded codeword from the first subset of codewords by resolving previous invocations of the modified RPA decoding algorithm based on the decoded current intermediate codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met. The apparatus 1804, and in particular the cellular baseband processor(s) 1824 and/or the application processor(s) 1806, may include means for invoking, when the decoding using the FHT is not successful, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion, the aggregation operation to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition.

The apparatus 1804, and in particular the cellular baseband processor(s) 1824 and/or the application processor(s) 1806, may include means for invoking a first recursion of the modified RPA decoding algorithm that invokes additional recursions of the modified RPA decoding algorithm with decremented first input values and decremented second input values until the modified RPA decoding algorithm is invoked with an order value that is equal to one less than the difference between the first order and the second order. The apparatus 1804, and in particular the cellular baseband processor(s) 1824 and/or the application processor(s) 1806, may include means for comparing, for a current intermediate codeword, the fourth input value associated with the threshold value to a Hamming distance between the current intermediate codeword and a zero codeword of a same length as the current intermediate codeword. The apparatus 1804, and in particular the cellular baseband processor(s) 1824 and/or the application processor(s) 1806, may include means for outputting, when the Hamming distance is less than the fourth input value, a decoded codeword from the first subset of codewords by resolving previous invocations of the modified RPA decoding algorithm based on the zero codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met. The apparatus 1804, and in particular the cellular baseband processor(s) 1824 and/or the application processor(s) 1806, may include means for invoking, when the Hamming distance is at least the fourth input value, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion, the aggregation operation to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition.

The apparatus 1804 may further include means for performing any of the aspects described in connection with the flowcharts in FIGS. 14-17, and/or performed by the encoder and/or decoder in the communication flow of FIG. 13. The means may be the UMP encoding/decoding component 198/199 of the apparatus 1804 configured to perform the functions recited by the means. As described supra, the apparatus 1804 may include the TX processor 368, the RX processor 356, and the controller/processor 359. As such, in one configuration, the means may be the TX processor 368, the RX processor 356, and/or the controller/processor 359 configured to perform the functions recited by the means.

FIG. 19 is a diagram 1900 illustrating an example of a hardware implementation for a network entity 1902. The network entity 1902 may be a BS, a component of a BS, or may implement BS functionality. The network entity 1902 may include at least one of a CU 1910, a DU 1930, or an RU 1940. For example, depending on the layer functionality handled by the UMP encoding/decoding component 198/199, the network entity 1902 may include the CU 1910; both the CU 1910 and the DU 1930; each of the CU 1910, the DU 1930, and the RU 1940; the DU 1930; both the DU 1930 and the RU 1940; or the RU 1940. The CU 1910 may include at least one CU processor 1912. The CU processor(s) 1912 may include on-chip memory 1912′. In some aspects, the CU 1910 may further include additional memory modules 1914 and a communications interface 1918. The CU 1910 communicates with the DU 1930 through a midhaul link, such as an F1 interface. The DU 1930 may include at least one DU processor 1932. The DU processor(s) 1932 may include on-chip memory 1932′. In some aspects, the DU 1930 may further include additional memory modules 1934 and a communications interface 1938. The DU 1930 communicates with the RU 1940 through a fronthaul link. The RU 1940 may include at least one RU processor 1942. The RU processor(s) 1942 may include on-chip memory 1942′. In some aspects, the RU 1940 may further include additional memory modules 1944, one or more transceivers 1946, one or more antennas 1980, and a communications interface 1948. The RU 1940 communicates with the UE 104. The on-chip memory 1912′, 1932′, 1942′ and the additional memory modules 1914, 1934, 1944 may each be considered a computer-readable medium/memory. Each computer-readable medium/memory may be non-transitory. Each of the processors 1912, 1932, 1942 is responsible for general processing, including the execution of software stored on the computer-readable medium/memory. The software, when executed by the corresponding processor(s) causes the processor(s) to perform the various functions described supra. The computer-readable medium/memory may also be used for storing data that is manipulated by the processor(s) when executing software.

As discussed supra, the UMP encoding/decoding component 198/199 may be configured to obtain a plurality of messages comprising a first subset of the plurality of messages and a second subset of the plurality of messages, encode the first subset of the plurality of messages into a first set of codewords associated with a first RM code, encode the second subset of the plurality of messages into a second set of codewords associated with a second RM code, where the first RM code is a subcode of the second RM code, and transmit, to a decoder device, the plurality of codewords. In some aspects, the UMP encoding/decoding component 198/199 may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages. The UMP encoding/decoding component 198/199 may be within one or more processors of one or more of the CU 1910, DU 1930, and the RU 1940. The UMP encoding/decoding component 198/199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. The network entity 1902 may include a variety of components configured for various functions. In one configuration, the network entity 1902 may include means for obtaining a plurality of messages comprising a first subset of the plurality of messages and a second subset of the plurality of messages. The network entity 1902 may include means for encoding the first subset of the plurality of messages into a first set of codewords associated with a first Reed-Muller (RM) code. The network entity 1902 may include means for encoding the second subset of the plurality of messages into a second set of codewords associated with a second RM code, wherein the first RM code is a subcode of the second RM code. The network entity 1902 may include means for transmitting, to a decoder device, a plurality of codewords comprising the first subset of codewords and the second set of codewords. The network entity 1902 may include means for refraining from transmitting, for each codeword in the plurality of codewords, an explicit indication of whether the codeword belongs to the first subset of codewords or the second subset of codewords. The network entity 1902 may include means for mapping the particular message to one of the particular codeword or a string of bits to be encoded into the particular codeword using a generator matrix associated with the first RM code. The network entity 1902 may include means for encoding a third subset of the plurality of messages into a third set of codewords associated with a third RM code.

The network entity 1902 may include means for receiving a plurality of codewords associated with a plurality of messages, wherein the plurality of codewords comprises a first subset of the plurality of codewords associated with a first subset of the plurality of messages and a second subset of the plurality of codewords associated with a second subset of the plurality of messages, wherein the first subset of codewords is associated with a first Reed-Muller (RM) code and the second subset of codewords is associated with a second RM code, wherein the first RM code is a subcode of the second RM code. The network entity 1902 may include means for decoding the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance. The network entity 1902 may include means for outputting a plurality of decoded codewords associated with the plurality of messages. The network entity 1902 may include means for obtaining an indication of a codeword length associated with each codeword in the plurality of codewords, a first order associated with a first RM code, a second order associated with a second RM code that is greater than the first order, and a threshold value associated with at least a first error tolerance for a first subset of a plurality of codewords. The network entity 1902 may include means for setting a current order of the decoder to be the second order and a current codeword to be the particular codeword. The network entity 1902 may include means for determining, for each row of the generator matrix corresponding to the current order of the decoder and until the current order is decremented below zero, a corresponding bit value based on a thresholding operation performed on a set of binary values associated with a set of linear combinations of bits in the current codeword, wherein the thresholding operation is based on the threshold value when a current order of the decoder is greater than the first order and is based on a majority when a current order of the decoder is not greater than the first order. The network entity 1902 may include means for calculating, based on the determined corresponding bit values, an updated codeword. The network entity 1902 may include means for decrementing the current order of the decoder. The network entity 1902 may include means for returning, when the value of the current order is decremented below zero, the determined corresponding bit values as a particular decoded codeword. The network entity 1902 may include means for comparing a second number of non-zero binary values in the set of binary values to the threshold value. The network entity 1902 may include means for setting the bit to zero when the second number is less than the threshold value. The network entity 1902 may include means for setting the bit to one when the second number is at least the threshold value. The network entity 1902 may include means for comparing a second number of non-zero values in the set of binary values to a third number of zero values in the set of binary values. The network entity 1902 may include means for setting the bit to zero when the second number is less than the third number. The network entity 1902 may include means for setting the bit to one when the second number is greater than the third number. The network entity 1902 may include means for indicating a failure to decode, setting the bit to zero, or setting the bit to one, when the second number is equal to the third number. The network entity 1902 may include means for determining whether the first number of invocations of the modified RPA decoding algorithm have been performed based on a current second input value and the third input value.

The network entity 1902 may include means for performing, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value. The network entity 1902 may include means for determining, when the first number of invocations of the modified RPA decoding algorithm have been performed, if a current input codeword of a most recent invocation of the modified RPA decoding algorithm is associated with the first subset of codewords based on the fourth input value associated with the threshold value. The network entity 1902 may include means for outputting, when the first number of invocations of the modified RPA decoding algorithm have been performed and based on determining that the current input codeword of the most recent invocation of the modified RPA decoding algorithm is associated with the first subset of codewords, a decoded codeword based on the particular codeword. The network entity 1902 may include means for performing, when the first number of invocations of the modified RPA decoding algorithm have been performed and based on determining that the current input codeword of the most recent invocation of the modified RPA decoding algorithm is not associated with the first subset of codewords, a set of additional projections and invocations of the modified RPA decoding algorithm with an additional decremented first input value and an additional decremented second value until the current second input value is equal to 1 and decoding the current input codeword for each of a plurality of projected codewords associated with the current invocation of the modified RPA decoding algorithm using the FHT. The network entity 1902 may include means for decoding, based on the decoded current input codeword for each of the plurality of projected codewords, a plurality of input codewords associated with previous invocations of the modified RPA decoding algorithm.

The network entity 1902 may include means for invoking a first recursion of the modified RPA decoding algorithm that invokes additional recursions of the modified RPA decoding algorithm with decremented first input values and decremented second input values until the modified RPA decoding algorithm is invoked with an order value that is equal to one more than the difference between the first order and the second order. The network entity 1902 may include means for attempting to decode a current intermediate codeword using a fast Hadamard transform (FHT). The network entity 1902 may include means for outputting, when the decoding using the FHT is successful, a decoded codeword from the first subset of codewords by resolving previous invocations of the modified RPA decoding algorithm based on the decoded current intermediate codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met. The network entity 1902 may include means for invoking, when the decoding using the FHT is not successful, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion, the aggregation operation to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition.

The network entity 1902 may include means for invoking a first recursion of the modified RPA decoding algorithm that invokes additional recursions of the modified RPA decoding algorithm with decremented first input values and decremented second input values until the modified RPA decoding algorithm is invoked with an order value that is equal to one less than the difference between the first order and the second order. The network entity 1902 may include means for comparing, for a current intermediate codeword, the fourth input value associated with the threshold value to a Hamming distance between the current intermediate codeword and a zero codeword of a same length as the current intermediate codeword. The network entity 1902 may include means for outputting, when the Hamming distance is less than the fourth input value, a decoded codeword from the first subset of codewords by resolving previous invocations of the modified RPA decoding algorithm based on the zero codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met. The network entity 1902 may include means for invoking, when the Hamming distance is at least the fourth input value, the modified RPA decoding algorithm until the modified RPA decoding algorithm is invoked with an order value that is equal to one and decodes a current intermediate codeword using the FHT and outputs a decoded codeword of the second subset of codewords by resolving previous invocations of the modified RPA decoding algorithm based on the decoded current intermediate codeword and an aggregation operation to account for the plurality of invocations of the modified RPA decoding algorithm at each level of recursion, the aggregation operation to produce a decoded message in the second subset of the plurality of messages, wherein the first invocation of the modified RPA decoding algorithm may perform an additional round beginning from the projection operation if one of a set of stopping conditions has not been met, wherein the set of stopping conditions comprises at least one of a maximum number of additional rounds or a convergence condition.

The network entity 1902 may further include means for performing any of the aspects described in connection with the flowcharts in FIGS. 14-17, and/or performed by the encoder and/or decoder in the communication flow of FIG. 13. The means may be the UMP encoding/decoding component 198/199 of the network entity 1902 configured to perform the functions recited by the means. As described supra, the network entity 1902 may include the TX processor 316, the RX processor 370, and the controller/processor 375. As such, in one configuration, the means may be the TX processor 316, the RX processor 370, and/or the controller/processor 375 configured to perform the functions recited by the means.

Some aspects and techniques as described herein may be implemented, at least in part, using an artificial intelligence (AI) program, such as a program that includes a machine learning (ML) or artificial neural network (ANN) model. An example ML model may include mathematical representations or define computing capabilities for making inferences from input data based on patterns or relationships identified in the input data. As used herein, the term “inferences” can include one or more decisions, predictions, determinations, or values, which may represent outputs of the ML model. The computing capabilities may be defined in terms of certain parameters of the ML model, such as weights and biases. Weights may indicate relationships between certain input data and certain outputs of the ML model, and biases are offsets that may indicate a starting point for the outputs of the ML model. An example ML model operating on input data may start at an initial output based on the biases and then update its output based on a combination of the input data and the weights.

In some aspects, an ML model may be configured to provide computing capabilities for wireless communications. Such an ML model may be configured with weights and biases to assist in decoding received transmissions, e.g., as described herein.

ML models may be deployed in one or more devices (for example, network entities and/or user equipment (UE)) and may be configured to enhance various aspects of a wireless communication system. For example, an ML model may be trained to identify patterns or relationships in data corresponding to a network, a device, an air interface, or the like. An ML model may support operational decisions relating to one or more aspects associated with wireless communications devices, networks, or services. For example, an ML model may be utilized for supporting or improving aspects such as signal coding/decoding, network routing, energy conservation, transceiver circuitry controls, frequency synchronization, timing synchronization, channel state estimation, channel equalization, channel state feedback, modulation, demodulation, device positioning, beamforming, load balancing, operations and management functions, security, etc.

ML models may be characterized in terms of types of learning that generate specific types of learned models that perform specific types of tasks. For example, different types of machine learning include supervised learning, unsupervised learning, semi-supervised learning, reinforcement learning, deep learning, etc. ML models may be used to perform different tasks, such as classification or regression, where classification refers to determining one or more discrete output values from a set of predefined output values, and regression refers to determining continuous values that are not bounded by predefined output values. Some example ML models configured for performing such tasks include ANNs such as convolutional neural networks (CNNs) and recurrent neural networks (RNNs), transformers, diffusion models, regression analysis models (such as statistical models), large language models (LLMs), decision tree learning (such as predictive models), support vector networks (SVMs), and probabilistic graphical models (such as a Bayesian network), etc.

The description herein illustrates, by way of some examples, how one or more tasks or problems in wireless communications may benefit from the application of one or more ML models for decoding. To facilitate the discussion, an ML model configured using an ANN is used, but other types of ML models may be used instead of an ANN. Hence, unless expressly recited, subject matter regarding an ML model is not intended to be limited to an ANN solution. Unless otherwise specifically stated, terms such “AI/ML model,” “ML model,” “trained ML mode,” “ANN,” “model,” “algorithm,” or the like are intended to be interchangeable.

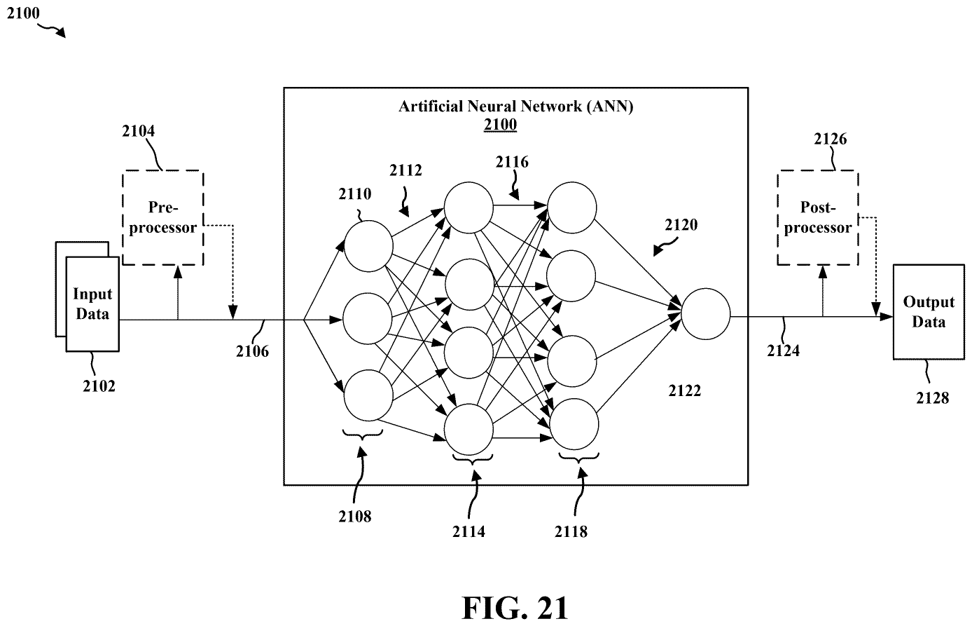

FIG. 21 is an illustrative block diagram of an example machine learning (ML) model represented by an artificial neural network (ANN) 2100. ANN 2100 may receive input data 2106, which may include one or more bits of data 2102, pre-processed data output from pre-processor 2104 (optional), or some combination thereof. Here, data 2102 may include training data, verification data, application-related data, or the like, based, for example, on the stage of deployment of ANN 2100. Pre-processor may be included within ANN 2100 in some other implementations. Pre-processor 2104 may, for example, process all or a portion of data 2102, which may result in some of data 2102 being changed, replaced, deleted, etc. In some implementations, pre-processor 2104 may add additional data to data 2102. In some implementations, the pre-processor 2104 may be an ML model, such as an ANN. As an example, the input may include measurements performed on Set-B beams.

The ANN 2100 includes at least one first layer 2108 of artificial neurons 2110 to process input data 2106 and provide resulting first layer data via connections or “edges” such as edges 2112 to at least a portion of at least one second layer 2114. Second layer 2114 processes data received via edges 2112 and provides second layer output data via edges 2116 to at least a portion of at least one third layer 2118. Third layer 2118 processes data received via edges 2116 and provides third layer output data via edges 2120 to at least a portion of a final layer 2122, including one or more neurons to provide output data 2124. All or part of output data 2124 may be further processed in some manner by (optional) post-processor 2126. Thus, in certain examples, ANN 2100 may provide output data 2128 that is based on output data 2124, post-processed data output from post-processor 2126, or some combination thereof. As an example, the output may include a decoded codeword.

Post-processor 2126 may be included within ANN 2100 in some other implementations. Post-processor 2126 may, for example, process all or a portion of output data 2124, which may result in output data 2128 being different, at least in part, from output data 2124, as a result of data being changed, replaced, deleted, etc. In some implementations, post-processor 2126 may be configured to add additional data to output data 2124. In this example, second layer 2114 and third layer 2118 represent intermediate or hidden layers that may be arranged in a hierarchical or other like structure. Although not explicitly shown, there may be one or more further intermediate layers between the second layer 2114 and the third layer 2118. In some implementations, the post-processor 2126 may be an ML model, such as an ANN.

The structure and training of artificial neurons 2110 in the various layers may be tailored to the specific requirements of an application. Within a given layer, such as first layer 2108, second layer 2114, or third layer 2118 of ANN 2100, some or all of the neurons may be configured to process information provided to the layer and output corresponding transformed information from the layer. For example, transformed information from a layer may represent a weighted sum of the input information associated with or otherwise based on a non-linear activation function or other activation function used to “activate” the artificial neurons of the next layer. Artificial neurons in such a layer may be activated by or be responsive to parameters such as the previously described weights and biases of ANN 2100. The weights and biases of ANN 2100 may be adjusted during a training process or during operation of ANN 2100. The weights of the various artificial neurons may control the strength of connections between layers or artificial neurons, while the biases may control the direction of connections between the layers or artificial neurons. An activation function may select or determine whether an artificial neuron transmits its output to the next layer or not in response to its received data.

Different activation functions may be used to model different types of non-linear relationships. By introducing non-linearity into an ML model, an activation function allows the configuration for the ML model to change in response to identifying or detecting complex patterns and relationships in the input data 2106. Some non-exhaustive example activation functions include a sigmoid based activation function, a hyperbolic tangent (tanh) based activation function, a convolutional activation function, up-sampling, pooling, and a rectified linear unit (ReLU) based activation function.

Training of an ML model, such as ANN 2100, may be conducted using training data, e.g., as described herein. Training data may include one or more datasets that ANN 2100 may use to identify patterns or relationships. Training data may represent various types of information, including written, visual, audio, environmental context, operational properties, etc. During training, the parameters (such as the weights and biases) of artificial neurons 2110 may be changed, such as to minimize or otherwise reduce a loss function or a cost function. A training process may be repeated multiple times to fine-tune ANN 2100 with each iteration.

Various ANN model structures are available for consideration. For example, in a feedforward ANN structure, each artificial neuron 2110 in layer 2114 receives information from the previous layer (such as one or more artificial neurons 2110 in layer 2108) and produces information for the next layer (such as one or more artificial neurons 2110 in layer 2118). In a convolutional ANN structure, some layers may be organized into filters that extract features from data, such as the training data or the input data. In a recurrent ANN structure, some layers may have connections that allow for the processing of data across time, such as for processing information having a temporal structure, such as time series data forecasting.

In an autoencoder ANN structure, compact representations of data may be processed and the model trained to predict or potentially reconstruct original data from a reduced set of features. An autoencoder ANN structure may be useful for tasks related to dimensionality reduction and data compression.

A generative adversarial ANN structure may include a generator ANN and a discriminator ANN that are trained to compete with each other. Generative-adversarial networks (GANs) are ANN structures that may be useful for tasks relating to generating synthetic data or improving the performance of other models.

A transformer ANN structure makes use of attention mechanisms that may enable the model to process input sequences in a parallel and efficient manner. An attention mechanism allows the model to focus on different parts of the input sequence at different times. Attention mechanisms may be implemented using a series of layers known as attention layers to compute weighted sums of input features based on a similarity between different elements of the input sequence. A transformer ANN structure may include a series of feedforward ANN layers whose configurations may change in response to identifying non-linear relationships between the input and output sequences, which may also be referred to as a process of “learning” by the ANN layers. The output of a transformer ANN structure may be obtained by applying a linear transformation to the output of a final attention layer. A transformer ANN structure may be of particular use for tasks that involve sequence modeling, or other like processing.

Another example type of ANN structure is a model with one or more invertible layers. Models of this type may be inverted or “unwrapped” to reveal the input data that was used to generate the output of a layer. Other example types of ANN model structures include fully connected neural networks (FCNNs) and long short-term memory (LSTM) networks.

ANN 2100 or other ML models may be implemented in various types of processing circuits along with memory and applicable instructions therein. For example, general-purpose hardware circuits, such as one or more central processing units (CPUs), one or more graphics processing units (GPUs), or suitable combinations thereof, may be employed to implement a model. In some implementations, one or more tensor processing units (TPUs), neural processing units (NPUs), or other special-purpose processors, field-programmable gate arrays (FPGAs), application-specific integrated circuits (ASICs), or the like may also be employed. In some implementations, the ML model may be implemented by an NPU or a TPU embedded in a system on chip (SoC) along with other components, such as one or more CPUs, GPUs, etc. A SoC includes several components manufactured on a shared semiconductor substrate. The NPU or TPU may be controlled by the one or more CPUs by configuring the ML model implemented by the NPU or TPU with weights and biases, providing certain training data to the ML model to configure the ML model, or providing input data to the ML model to obtain related inferences. The one or more CPUs may also receive the inferences and be configured to perform certain actions based on the inferences produced by the ML model. The actions performed by the one or more CPUs may include sending commands to other components of the SoC or components external to the SoC to perform certain actions. For example, the CPU may send commands to an RF transceiver based on the outputs or inferences obtained from an ML model to cause the RF transceiver to operate on a wireless network in accordance with the ML model.

In some examples, an ML model may be trained prior to, or at some point following, operation of the ML model, such as ANN 2100, on input data. When training the ML model, information in the form of applicable training data may be gathered or otherwise created for use in training an ANN accordingly. For example, training data may be gathered or otherwise created regarding information associated with received/transmitted signal strengths, interference, and resource usage data, as well as any other relevant data that might be useful for training a model to address one or more problems or issues in a communication system. In certain instances, all or part of the training data may originate in a user equipment (UE) or other device in a wireless communication system, or one or more network entities, or aggregated from multiple sources (such as a UE and a network entity/entities, one or more other UEs, the Internet, or the like). For example, wireless network architectures, such as self-organizing networks (SON) or mobile drive test (MDT) networks, may be adapted to support the collection of data for ML model applications. In another example, training data may be generated or collected online, offline, or both online and offline by a UE, network entity, or other device(s), and all or part of such training data may be transferred or shared (in real or near-real time), such as through store and forward functions or the like.

Offline training may refer to creating and using a static training dataset, such as in a batched manner, whereas online training may refer to the real-time collection and use of training data. For example, an ML model at a network device (such as a UE) may be trained or fine-tuned using online or offline training. For offline training, data collection and training can occur in an offline manner at the network side (such as at a base station or other network entity) or at the UE side. For online training, the training of a UE-side ML model may be performed locally at the UE or by a server device (such as a server hosted by a UE vendor) in a real-time or near-real-time manner based on data provided to the server device from the UE. In certain instances, all or part of the training data may be shared within a wireless communication system or even shared (or obtained from) outside of the wireless communication system.

Once an ANN has been configured by setting parameters, including weights and biases, from training data, the ANN's performance may be evaluated. In some scenarios, evaluation/verification tests may use a validation dataset, which may include data not in the training data, to compare the model's performance to baseline or other benchmark information. The ANN configuration may be further refined, for example, by changing its architecture, retraining it on the data, or using different optimization techniques, etc.

As part of a training process, parameters affecting the functioning of the artificial neurons and layers may be adjusted. For example, backpropagation techniques may be used to train an ANN by iteratively adjusting weights or biases of certain artificial neurons associated with errors between a predicted output of the model and a desired output that may be known or otherwise deemed acceptable. Backpropagation may include a forward pass, a loss function, a backward pass, and a parameter update that may be performed in training iteration. The process may be repeated for a certain number of iterations for each set of training data until the weights of the artificial neurons/layers are adequately tuned.

Backpropagation techniques associated with a loss function may measure how well a model is able to predict a desired output for a given input. An optimization algorithm may be used during a training process to adjust weights and biases to reduce or minimize the loss function, which can improve the performance of the model. There are a variety of optimization algorithms that may be used along with backpropagation techniques or other training techniques. Some initial examples include a gradient descent based optimization algorithm and a stochastic gradient descent based optimization algorithm. A stochastic gradient descent technique may be used to adjust weights/biases in order to minimize or otherwise reduce a loss function. A mini-batch gradient descent technique, which is a variant of gradient descent, may involve updating weights/biases using a small batch of training data rather than the entire dataset. A momentum technique may accelerate an optimization process by adding a momentum term to update or otherwise affect certain weights/biases.

An adaptive learning rate technique may adjust the learning rate of an optimization algorithm associated with one or more characteristics of the training data. A batch normalization technique may be used to normalize inputs to a model in order to stabilize a training process and potentially improve the performance of the model. A “dropout” technique may be used to randomly drop out some of the artificial neurons from a model during a training process, for example, in order to reduce overfitting and potentially improve the generalization of the model. An “early stopping” technique may be used to stop an ongoing training process early, such as when a performance of the model using a validation dataset starts to degrade.

Another example technique includes data augmentation to generate additional training data by applying transformations to all or part of the training information. A transfer learning technique may be used which involves using a pre-trained model as a starting point for training a new model, which may be useful when training data is limited or when there are multiple tasks that are related to each other. A multi-task learning technique may be used which involves training a model to perform multiple tasks simultaneously to potentially improve the performance of the model on one or more of the tasks. Hyperparameters or the like may be input and applied during a training process in certain instances.

Another example technique that may be useful with regard to an ANN is a “pruning” technique. A pruning technique, which may be performed during a training process or after a model has been trained, involves the removal of unnecessary or less necessary, or possibly redundant features from a model. In certain instances, a pruning technique may reduce the complexity of a model or improve the efficiency of a model without undermining the intended performance of the model.

Pruning techniques may be particularly useful in the context of wireless communication, where the available resources (such as power and bandwidth) may be limited. Some example pruning techniques include a weight pruning technique, a neuron pruning technique, a layer pruning technique, a structural pruning technique, and a dynamic pruning technique. Pruning techniques may, for example, reduce the amount of data corresponding to a model that is transmitted or stored. Weight pruning techniques may involve removing some of the weights from a model. Neuron pruning techniques may involve removing some neurons from a model. Layer pruning techniques may involve removing some layers from a model. Structural pruning techniques may involve removing some connections between neurons in a model. Dynamic pruning techniques may involve adapting a pruning strategy of a model associated with one or more characteristics of the data or the environment. For example, in certain wireless communication devices, a dynamic pruning technique may more aggressively prune a model for use in a low-power or low-bandwidth environment and less aggressively prune the model for use in a high-power or high-bandwidth environment. In certain example implementations, pruning techniques may also be applied to training data, for example, to remove outliers. In some implementations, pre-processing techniques directed to all or part of a training dataset may improve model performance or promote faster convergence of a model. For example, training data may be pre-processed to change or remove unnecessary data, extraneous data, incorrect data, or otherwise identifiable data. Such pre-processed training data may, for example, lead to a reduction in potential overfitting or otherwise improve the performance of the trained model.

One or more of the example training techniques presented above may be employed as part of a training process. Some example training processes that may be used to train an ANN include supervised learning, unsupervised learning, semi-supervised learning, and reinforcement learning techniques. With supervised learning, a model is trained on a labeled training dataset, where the input data is accompanied by a correct or otherwise acceptable output. With unsupervised learning, a model is trained on an unlabeled training dataset, such that the model will learn to identify patterns and relationships in the data without the explicit guidance of a labeled training dataset. With semi-supervised learning, a model is trained using some combination of supervised and unsupervised learning processes, for example, when the amount of labeled data is somewhat limited. With reinforcement learning, a model may learn from interactions with its operation/environment, such as in the form of feedback akin to rewards or penalties. Reinforcement learning may be particularly beneficial when used to improve or attempt to optimize the behavior of a model deployed in a dynamically changing environment, such as a wireless communication network.

Distributed, shared, or collaborative learning techniques may be used for the training process. For example, techniques such as federated learning may be used to decentralize the training process and rely on multiple devices, network entities, or organizations for training various versions or copies of an ML model without relying on a centralized training mechanism. Federated learning may be particularly useful in scenarios where data is sensitive or subject to privacy constraints, or where it is impractical, inefficient, or expensive to centralize data. In the context of wireless communication, for example, federated learning may be used to improve performance by allowing an ANN to be trained on data collected from a wide range of devices and environments. For example, an ANN may be trained on data collected from a large number of wireless devices in a network, such as distributed wireless communication nodes, smartphones, or internet-of-things (IoT) devices, to improve the network's performance and efficiency. With federated learning, a user equipment (UE) or other device may receive a copy of all or part of a global or shared model and perform local training on the local model using locally available training data. The UE may provide updated information regarding the locally trained model to one or more other devices (such as a network entity or a server), where the updates from other-like devices (such as other UEs) may be aggregated and used to provide an update to the global or shared model. A federated learning process may be repeated iteratively until all or part of a model obtains a satisfactory level of performance. Federated learning may enable devices to protect the privacy and security of local data, while supporting collaboration regarding training and updating of all or part of a shared model.

In some implementations, one or more devices or services may support processes relating to an ML model's usage, maintenance, activation, reporting, or the like. In certain instances, all or part of a dataset or model may be shared across multiple devices to provide or otherwise augment or improve processing. In some examples, signaling mechanisms may be utilized at various nodes of wireless networks to signal the capabilities for performing specific functions related to ML models, support for specific ML models, capabilities for gathering, creating, and transmitting training data, or other ML related capabilities. ML models in wireless communication systems may, for example, be employed to support decisions or improve performance relating to wireless resource allocation or selection, wireless channel condition estimation, interference mitigation, beam management, positioning accuracy, energy savings, or modulation or coding schemes, etc. In some implementations, model deployment may occur jointly or separately at various network levels, such as a UE, a network entity such as a base station, or a disaggregated network entity such as a central unit (CU), a distributed unit (DU), a radio unit (RU), or the like.

FIG. 5 is an illustrative block diagram of an example ML architecture 500 that may be used for wireless communications in any of the various implementations, processes, environments, networks, or use cases listed above. As illustrated, architecture 500 includes multiple logical entities, such as model training host 502, model inference host 504, data source(s) 506, and agent 508. Model inference host 504 is configured to run an ML model based on inference data 512 provided by data source(s) 506. Model inference host 504 may produce output 514, which may include a prediction or inference, such as a discrete or continuous value based on inference data 512, which may then be provided as input to the agent 508.

Agent 508 may represent an element or an entity of a wireless communication system including, for example, a radio access network (RAN), a wireless local area network, a device-to-device (D2D) communications system, etc. As an example, agent 508 may be a user equipment (such as UE 104, referring to FIG. 1, for example), a base station (such as base station 102, referring to FIG. 1, for example), or a disaggregated network entity (such as a CU 110, DU 130, or RU 140 in FIG. 1), an access point, a wireless station, a RAN intelligent controller (RIC) in a cloud-based RAN, among some examples. Additionally, agent 508 may also be a type of agent that depends on the type of tasks performed by model inference host 504, the type of inference data 512 provided to model inference host 504, or the type of output 514 produced by model inference host 504. As an example, the input may be measurements associated with a set of resources (e.g., Set-B beams/resources), and the output may include a set of predictions for a different set of resources (e.g., Set-A beams/resources). A base station or UE may then select a beam for use in transmission and/or reception based on the beam predictions for the Set-A beams output from the AI/ML model.

Agent 508 may perform one or more actions associated with receiving output 514 from model inference host 504, e.g., selection, use, and/or reporting regarding the predictions made for the different set of resources (e.g., Set-A beams/resources). Agent 508 may indicate the one or more actions performed to at least one subject of action 510. In some cases, agent 508 and the subject of action 510 are the same entity.

Data can be collected from data sources 506, and may be used as training data 516 for training an ML model, or as inference data 512 for feeding an ML model inference operation. Data sources 506 may collect data from various subject of action 510 entities (such as the UE or the network entity) and provide the collected data to a model training host 502 for ML model training. In some examples, if output 514 provided to agent 508 is inaccurate (or the accuracy is below an accuracy threshold), model training host 502 may provide feedback to model inference host 504 to modify or retrain the ML model used by model inference host 504, such as via an ML model deployment update.

Model training host 502 may be deployed at the same or a different entity than that in which model inference host 504 is deployed. For example, in order to offload model training processing, which can impact the performance of model inference host 504, model training host 502 may be deployed at a model server.

Various aspects relate generally to the use of RM codes for UEC and/or UMP for different messages. Some aspects more specifically relate to an encoder that encodes different classes of messages (e.g., two or more classed including a first class of messages and a second class of messages) using different RM codes based on an associated threshold error tolerance and corresponding decoders. In some examples, an encoding device, may be configured to obtain a plurality of messages comprising a first subset of the plurality of messages and a second subset of the plurality of messages, encode the first subset of the plurality of messages into a first set of codewords associated with a first RM code, encode the second subset of the plurality of messages into a second set of codewords associated with a second RM code, where the first RM code is a subcode of the second RM code, and transmit, to a decoder device, the plurality of codewords. In some examples, a decoder, or decoding, device may be configured to receive a plurality of codewords associated with a plurality of messages, where the plurality of codewords comprises a first subset of the plurality of codewords associated with a first subset of the plurality of messages and a second subset of the plurality of codewords associated with a second subset of the plurality of messages, wherein the first subset of codewords is associated with a first RM code and the second subset of codewords is associated with a second RM code, wherein the first RM code is a subcode of the second RM code, decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance, and output a plurality of decoded codewords associated with the plurality of messages.

Particular aspects of the subject matter described in this disclosure can be implemented to realize one or more of the following potential advantages. In some examples, by applying different RM codes for encoding different classes of messages and providing at least one decoder that can decode messages using the different error thresholds and/or fault tolerances without prior knowledge of the RM code associated with a particular received codeword, the described techniques can be used to provide unequal message protection to different classes of messages in an electronic and/or wireless communication environment.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not limited to the aspects described herein, but are to be accorded the full scope consistent with the language claims. Reference to an element in the singular does not mean “one and only one” unless specifically so stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. Sets should be interpreted as a set of elements where the elements number one or more. Accordingly, for a set of X, X would include one or more elements. When at least one processor is configured to perform a set of functions, the at least one processor, individually or in any combination, is configured to perform the set of functions. Accordingly, each processor of the at least one processor may be configured to perform a particular subset of the set of functions, where the subset is the full set, a proper subset of the set, or an empty subset of the set. A processor may be referred to as processor circuitry. A memory/memory module may be referred to as memory circuitry. If a first apparatus receives data from or transmits data to a second apparatus, the data may be received/transmitted directly between the first and second apparatuses, or indirectly between the first and second apparatuses through a set of apparatuses. A device configured to “output” data, such as a transmission, signal, or message, may transmit the data, for example with a transceiver, or may send the data to a device that transmits the data. A device configured to “obtain” data, such as a transmission, signal, or message, may receive, for example with a transceiver, or may obtain the data from a device that receives the data. Information stored in a memory includes instructions and/or data. All structural and functional equivalents to the elements of the various aspects described throughout this disclosure that are known or later come to be known to those of ordinary skill in the art are expressly incorporated herein by reference and are encompassed by the claims. Moreover, nothing disclosed herein is dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

The following aspects are illustrative only and may be combined with other aspects or teachings described herein, without limitation.

Aspect 1 is a method of wireless communication at an encoder device, comprising: obtaining a plurality of messages comprising a first subset of the plurality of messages and a second subset of the plurality of messages; encoding the first subset of the plurality of messages into a first subset of codewords associated with a first Reed-Muller (RM) code; encoding the second subset of the plurality of messages into a second subset of codewords associated with a second RM code, wherein the first RM code is a subcode of the second RM code; and transmitting, to a decoder device, a plurality of codewords comprising the first subset of the plurality of codewords and the second subset of the plurality of codewords.

Aspect 2 is the method of aspect 1, further comprising: refraining from transmitting, for each codeword in the plurality of codewords, an explicit indication of whether the codeword belongs to the first subset of the plurality of codewords or the second subset of the plurality of codewords.

Aspect 3 is the method of any of aspects 1 and 2, wherein the first RM code and the second RM code are of a first length and, wherein the first RM code of the first length is of a first order, wherein the second RM code of the first length is of a second order that is greater than the first order, and wherein the first order is associated with a first error tolerance that is greater than a second error tolerance associated with the second order.

Aspect 4, is the method of any of aspects 1 to 3, wherein the first subset of the plurality of codewords is not included in the second subset of the plurality of codewords despite being associated with the second RM code.

Aspect 5 is the method of any of aspects 3 and 4, wherein the first subset of the plurality of codewords is smaller than the second subset of the plurality of codewords by a factor based on a difference between the first order and the second order.

Aspect 6 is the method of any of aspects 1 to 5, wherein encoding a particular message in the first subset of the plurality of messages into a particular codeword in the first subset of the plurality of codewords comprises: identifying that the particular message belongs to the first subset of the plurality of messages; and mapping the particular message to one of the particular codeword or a string of bits to be encoded into the particular codeword using a generator matrix associated with the first RM code.

Aspect 7 is the method of any of aspects 1 to 6, wherein the plurality of messages further comprises a third subset of the plurality of messages and the first RM code is a first subcode of the second RM code, wherein a third set of codewords associated with the third subset of the plurality of messages is associated with a third RM code that is a second subcode of the second RM code, and wherein a third order of the third RM code is associated with a third error tolerance that is greater than a second error tolerance associated with the second RM code and less than a first error tolerance associated with a first RM code.

Aspect 8 is a method of wireless communication at a decoder device, comprising: receiving a plurality of codewords associated with a plurality of messages, wherein the plurality of codewords comprises a first subset of the plurality of codewords associated with a first subset of the plurality of messages and a second subset of the plurality of codewords associated with a second subset of the plurality of messages, wherein the first subset of the plurality of codewords is associated with a first Reed-Muller (RM) code and the second subset of the plurality of codewords is associated with a second RM code, wherein the first RM code is a subcode of the second RM code; decoding the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance; and outputting a plurality of decoded codewords associated with the plurality of messages.

Aspect 9 is the method of aspect 8, wherein a one-to-one mapping exists from decoded codewords in the plurality of decoded codewords to corresponding messages in the plurality of messages.

Aspect 10 is the method of any of aspects 8 and 9, wherein a set of codewords associated with the second RM code comprises the first subset of the plurality of codewords and the second subset of the plurality of codewords but the first subset of the plurality of codewords is not included in the second subset of the plurality of codewords despite being associated with the second RM code.

Aspect 11 is the method of any of aspects 8 to 10, further comprising: obtaining an indication of: a codeword length associated with each codeword in the plurality of codewords, a first order associated with the first RM code, a second order associated with the second RM code that is greater than the first order, and a threshold value associated with at least the first error tolerance for the first subset of the plurality of codewords.

Aspect 12 is the method of aspect 11, wherein the second RM code is associated with a generator matrix having a first number of rows corresponding to a first number of bits in each decoded codeword, wherein each row uniquely corresponds to an order of the RM code, wherein a particular order of the RM code may correspond to one of a single row or multiple rows of the generator matrix, wherein the decoding for a particular codeword of the plurality of codewords corresponding to a particular message of the plurality of messages comprises: setting a current order of the decoding method to be the second order and a current codeword to be the particular codeword; determining, for each row of the generator matrix corresponding to the current order of the decoding method and until the current order is decremented below zero, a corresponding bit value based on a thresholding operation performed on a set of binary values associated with a set of linear combinations of bits in the current codeword, wherein the thresholding operation is based on the threshold value when the current order of the decoding method is greater than the first order and is based on a majority when the current order of the decoding method is not greater than the first order; calculating, based on the determined corresponding bit values, an updated codeword; decrementing a value of the current order of the decoding method; and returning, when the value of the current order is decremented below zero, the determined corresponding bit values as a particular decoded codeword.

Aspect 13 is the method of aspect 12, wherein, when the current order of the decoding method is greater than the second order, the thresholding operation based on the threshold value performed on the set of binary values associated with the set of linear combinations of bits in the current codeword, comprises: comparing a second number of non-zero binary values in the set of binary values to the threshold value; setting the corresponding bit value to zero when the second number of non-zero binary values is less than the threshold value; and setting the corresponding bit value to one when the second number of non-zero binary values is at least the threshold value.

Aspect 14 is the method of aspect 13, wherein the set of binary values comprises a third number of binary values that depends on the current order and the threshold value is a threshold fraction of the third number of binary values, wherein the threshold fraction is greater than 50 percent.

Aspect 15 is the method of any of aspects 12 to 14, wherein, when the current order of the decoding method is not greater than the second order, the thresholding operation based on the majority performed on the set of binary values associated with the set of linear combinations of bits in the current codeword, comprises: comparing a second number of non-zero values in the set of binary values to a third number of zero values in the set of binary values; setting the corresponding bit value to zero when the second number of non-zero values is less than the third number of zero values; setting the corresponding bit value to one when the second number of non-zero values is greater than the third number of zero values; and one of: indicating a failure to decode when the second number of non-zero values is equal to the third number of zero values, setting the corresponding bit value to zero when the second number of non-zero values is equal to the third number of zero values, or setting the corresponding bit value to one, when the second number of non-zero values is equal to the third number of zero values.

Aspect 16 is the method of aspect 11, wherein the decoding method includes a modified recursive projection-aggregation (RPA) decoding algorithm for decoding an input codeword, wherein the modified RPA decoding algorithm is based on a first input value associated with a length of the input codeword, a second input value based on the second order, a third input value associated with a first number of recursions (or invocations) of the modified RPA decoding algorithm to perform before attempting to decode the input codeword as a codeword in the first subset of the plurality of codewords, and a fourth input value associated with the threshold value, wherein the third input value is based on a difference between the first order and the second order, wherein the modified RPA decoding algorithm for the second input value equal to one comprises a fast Hadamard transform (FHT), wherein each iteration of the modified RPA decoding algorithm may be performed one of up to a maximum number of times or until a decoded codeword converges, and wherein the decoding for a particular codeword of the plurality of codewords comprises invoking the modified RPA decoding algorithm with a current input codeword that is the particular codeword, a current first input value that is a first value associated with the length of the particular codeword, a current second input value that is the second order, a current third input value that is a third value based on the difference between the first order and the second order, and a current fourth input value associated with the threshold value, wherein upon being invoked, the modified RPA decoding algorithm is associated with: determining whether the first number of invocations of the modified RPA decoding algorithm have been performed based on the current second input value and the third input value; performing, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value; determining, when the first number of invocations of the modified RPA decoding algorithm have been performed, if the current input codeword of a most recent invocation of the modified RPA decoding algorithm is associated with the first subset of the plurality of codewords based on the fourth input value associated with the threshold value; outputting, when the first number of invocations of the modified RPA decoding algorithm have been performed and based on determining that the current input codeword of the most recent invocation of the modified RPA decoding algorithm is associated with the first subset of the plurality of codewords, the decoded codeword based on the particular codeword; performing, when the first number of invocations of the modified RPA decoding algorithm have been performed and based on determining that the current input codeword of the most recent invocation of the modified RPA decoding algorithm is not associated with the first subset of the plurality of codewords, a set of additional projections and invocations of the modified RPA decoding algorithm with an additional decremented first input value and an additional decremented second value until the current second input value is equal to 1 and decoding the current input codeword for each of the plurality of projected codewords associated with a current invocation of the modified RPA decoding algorithm using the FHT; and decoding, based on a decoded current input codeword for each of the plurality of projected codewords, a plurality of input codewords associated with previous invocations of the modified RPA decoding algorithm.

Aspect 17 is the method of aspect 11, wherein the decoding method includes a modified recursive projection-aggregation (RPA) decoding algorithm for decoding an input codeword, wherein the modified RPA decoding algorithm is based on a first input value associated with the length of the input codeword, a second input value based on the second order associated with the input codeword, a third input value associated with a first number of recursions (or invocations) of the modified RPA decoding algorithm to perform before attempting to decode the input codeword as a codeword in the first subset of the plurality of codewords, and a fourth input value associated with the threshold value, wherein the third input value is based on a difference between the first order and the second order, wherein the modified RPA decoding algorithm for the second input value equal to one comprises a fast Hadamard transform (FHT), wherein each invocation of the modified RPA decoding algorithm for which a particular condition is not met comprises performing a projection operation on the input codeword that produces a plurality of intermediate codewords that are each used as an input for a next invocation of the modified RPA decoding algorithm with a decremented first input value associated with the length of an input intermediate codeword and a decremented second input value based on an order associated with the input intermediate codeword, and wherein the decoding for a particular codeword of the plurality of codewords comprises: invoking a first recursion of the modified RPA decoding algorithm that invokes additional recursions of the modified RPA decoding algorithm with decremented first input values and decremented second input values until the modified RPA decoding algorithm is invoked with the second input value that is equal to one more than the difference between the first order and the second order; attempting to decode a current intermediate codeword using a the FHT; outputting, when a decoding using the FHT is successful, a decoded codeword from the first subset of the plurality of codewords by resolving previous invocations of the modified RPA decoding algorithm based on a decoded current intermediate codeword and an aggregation operation to account for a plurality of invocations of the modified RPA decoding algorithm at each level of recursion, wherein a first invocation of the modified RPA decoding algorithm may perform an additional round beginning from the projection operation if one of a set of stopping conditions has not been met; and invoking, when the decoding using the FHT is not successful, the modified RPA decoding algorithm until the modified RPA decoding algorithm is invoked with the second input value that is equal to one and decodes the current intermediate codeword using the FHT and outputs the decoded codeword of the second subset of the plurality of codewords by resolving the previous invocations of the modified RPA decoding algorithm based on the decoded current intermediate codeword and the aggregation operation to account for the plurality of invocations of the modified RPA decoding algorithm at each level of the recursion, the aggregation operation to produce a decoded message in the second subset of the plurality of messages, wherein the first invocation of the modified RPA decoding algorithm may perform the additional round beginning from the projection operation if one of the set of stopping conditions has not been met, wherein the set of stopping conditions comprises at least one of a maximum number of additional rounds or a convergence condition.

Aspect 18 is the method of aspect 17, wherein the decoding using the FHT is successful if a Hamming distance between the decoded codeword and the input intermediate codeword is less than a threshold distance.

Aspect 19 is the method aspect of 11, wherein the decoding method includes a modified recursive projection-aggregation (RPA) decoding algorithm for decoding an input codeword, wherein the modified RPA decoding algorithm is based on a first input value associated with a length of the input codeword, a second input value based on the second order associated with the input codeword, a third input value associated with a first number of invocations of the modified RPA decoding algorithm to perform before attempting to decode the input codeword as a codeword in the first subset of the plurality of codewords, and a fourth input value associated with the threshold value, wherein the third input value is based on a difference between the first order and the second order, wherein the modified RPA decoding algorithm for the second input value equal to one comprises a fast Hadamard transform (FHT), wherein each invocation of the modified RPA decoding algorithm for which a particular condition is not met comprises performing a projection operation on the input codeword that produces a plurality of intermediate codewords that are each used as an input for a next invocation of the modified RPA decoding algorithm with a decremented first input value associated with the length of the input intermediate codeword and a decremented second input value based on an order associated with the input intermediate codeword, and wherein the decoding for a particular codeword of the plurality of codewords comprises: invoking a first recursion of the modified RPA decoding algorithm that invokes additional recursions of the modified RPA decoding algorithm with decremented first input values and decremented second input values until the modified RPA decoding algorithm is invoked with an order value that is equal to one less than the difference between the first order and the second order; comparing, for a current intermediate codeword, the fourth input value associated with the threshold value to a Hamming distance between the current intermediate codeword and a zero codeword of a same length as the current intermediate codeword; outputting, when the Hamming distance is less than the fourth input value, a decoded codeword from the first subset of the plurality of codewords by resolving previous invocations of the modified RPA decoding algorithm based on the zero codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met; and invoking, when the Hamming distance is at least the fourth input value, the modified RPA decoding algorithm until the modified RPA decoding algorithm is invoked with the second input value that is equal to one and decodes the current intermediate codeword using the FHT and outputs the decoded codeword of the second subset of the plurality of codewords by resolving the previous invocations of the modified RPA decoding algorithm based on a decoded current intermediate codeword and the aggregation operation to account for a plurality of invocations of the modified RPA decoding algorithm at each level of the recursion, the aggregation operation to produce a decoded message in the second subset of the plurality of messages, wherein the first invocation of the modified RPA decoding algorithm may perform the additional round beginning from the projection operation if one of the set of stopping conditions has not been met, wherein the set of stopping conditions comprises at least one of a maximum number of additional rounds or a convergence condition.

Aspect 20 is the method of aspect 8, wherein the decoding method includes a machine-learning (ML) aided recursive projection-aggregation (RPA) decoding method, wherein the ML aided RPA is trained to decode first input codewords in the first subset of the plurality of codewords with a first accuracy based on the first error tolerance and to decode second input codewords in the second subset of the plurality of codewords with a second accuracy based on the second error tolerance, and wherein the ML aided RPA is trained based on a training set comprising, multiple data sets comprising: multiple projections generated by an RPA decoding method applied to a test codeword encoded with one of the first RM code or the second RM code, and an indication of whether the first RM code or the second RM code was used to encode the test codeword.

Aspect 21 is a method comprising: training a machine-learning (ML) aided algorithm to determine whether particular codewords in a plurality of input codewords were encoded with a first RM code or a second RM code that is a subcode of the first RM code and to decode input codewords encoded by the first RM code with a first threshold accuracy and to decode input codewords encoded by the second RM code with a second threshold accuracy that is higher than the first threshold accuracy, by providing a training data set including multiple data sets, each data set including at least multiple projections generated by an RPA decoding method applied to a test codeword encoded with one of the first RM code or the second RM code, and an indication of whether the first RM code or the second RM code was used to encode the test codeword; and outputting the set of weights associated with the ML aided algorithm.

Aspect 22 is an apparatus for wireless communication at a device including a memory and at least one processor coupled to the memory and, based at least in part on information stored in the memory, the at least one processor is configured to implement any of aspects 1 to 7.

Aspect 23 is the apparatus of aspect 22, further including a transceiver or an antenna coupled to the at least one processor.

Aspect 24 is an apparatus for wireless communication at a device including means for implementing any of aspects 1 to 7.

Aspect 25 is a computer-readable medium (e.g., a non-transitory computer-readable medium) storing computer executable code, where the code when executed by a processor causes the processor to implement any of aspects 1 to 7.

Aspect 26 is an apparatus for wireless communication at a device including a memory and at least one processor coupled to the memory and, based at least in part on information stored in the memory, the at least one processor is configured to implement any of aspects 8 to 20.

Aspect 27 is the apparatus of aspect 26, further including a transceiver or an antenna coupled to the at least one processor.

Aspect 28 is an apparatus for wireless communication at a device including means for implementing any of aspects 8 to 20.

Aspect 29 is a computer-readable medium (e.g., a non-transitory computer-readable medium) storing computer executable code, where the code when executed by a processor causes the processor to implement any of aspects 8 to 20.

Aspect 30 is an apparatus for wireless communication at a device including a memory and at least one processor coupled to the memory and, based at least in part on information stored in the memory, the at least one processor is configured to implement aspect 21.

Aspect 31 is the apparatus of aspect 30, further including a transceiver or an antenna coupled to the at least one processor.

Aspect 32 is an apparatus for wireless communication at a device including means for implementing aspect 21.

Aspect 33 is a computer-readable medium (e.g., a non-transitory computer-readable medium) storing computer executable code, where the code when executed by a processor causes the processor to implement aspect 21.

What is claimed is:

1. An apparatus for wireless communication at an encoder device, comprising:
at least one memory; and
at least one processor coupled to the at least one memory and, based at least in part on stored information that is stored in the at least one memory, the at least one processor, individually or in any combination, is configured to:
obtain a plurality of messages comprising a first subset of the plurality of messages and a second subset of the plurality of messages;
encode the first subset of the plurality of messages into a first subset of codewords associated with a first Reed-Muller (RM) code;
encode the second subset of the plurality of messages into a second subset of codewords associated with a second RM code, wherein the first RM code is a subcode of the second RM code; and
transmit, to a decoder device, a plurality of codewords comprising the first subset of the plurality of codewords and the second subset of the plurality of codewords.

2. The apparatus of claim 1, wherein the at least one processor, individually or in any combination, is further configured to:
refrain from transmitting, for each codeword in the plurality of codewords, an explicit indication of whether the codeword belongs to the first subset of the plurality of codewords or the second subset of the plurality of codewords.

3. The apparatus of claim 1, wherein the first RM code and the second RM code are of a first length and, wherein the first RM code of the first length is of a first order, wherein the second RM code of the first length is of a second order that is greater than the first order, wherein the first order is associated with a first error tolerance that is greater than a second error tolerance associated with the second order, wherein the first subset of the plurality of codewords is not included in the second subset of the plurality of codewords despite being associated with the second RM code, wherein the first subset of the plurality of codewords is smaller than the second subset of the plurality of codewords by a factor based on a difference between the first order and the second order.

4. The apparatus of claim 1, wherein to encode a particular message in the first subset of the plurality of messages into a particular codeword in the first subset of the plurality of codewords, the at least one processor, individually or in any combination, is further configured to:
identify that the particular message belongs to the first subset of the plurality of messages; and
map the particular message to one of the particular codeword or a string of bits to be encoded into the particular codeword using a generator matrix associated with the first RM code.

5. The apparatus of claim 1, wherein the plurality of messages further comprises a third subset of the plurality of messages and the first RM code is a first subcode of the second RM code, wherein a third set of codewords associated with the third subset of the plurality of messages is associated with a third RM code that is a second subcode of the second RM code, and wherein a third order of the third RM code is associated with a third error tolerance that is greater than a second error tolerance associated with the second RM code and less than a first error tolerance associated with a first RM code.

6. An apparatus for wireless communication at a decoder device, comprising:
at least one memory; and
at least one processor coupled to the at least one memory and, based at least in part on stored information that is stored in the at least one memory, the at least one processor, individually or in any combination, is configured to:
receive a plurality of codewords associated with a plurality of messages, wherein the plurality of codewords comprises a first subset of the plurality of codewords associated with a first subset of the plurality of messages and a second subset of the plurality of codewords associated with a second subset of the plurality of messages, wherein the first subset of the plurality of codewords is associated with a first Reed-Muller (RM) code and the second subset of the plurality of codewords is associated with a second RM code, wherein the first RM code is a subcode of the second RM code;
decode the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance; and
output a plurality of decoded codewords associated with the plurality of messages.

7. The apparatus of claim 6, wherein a one-to-one mapping exists from decoded codewords in the plurality of decoded codewords to corresponding messages in the plurality of messages.

8. The apparatus of claim 6, wherein a set of codewords associated with the second RM code comprises the first subset of the plurality of codewords and the second subset of the plurality of codewords but the first subset of the plurality of codewords is not included in the second subset of the plurality of codewords despite being associated with the second RM code.

9. The apparatus of claim 6, wherein the at least one processor, individually or in any combination, is further configured to:
obtain an indication of:
a codeword length associated with each codeword in the plurality of codewords,
a first order associated with the first RM code,
a second order associated with the second RM code that is greater than the first order, and
a threshold value associated with at least the first error tolerance for the first subset of the plurality of codewords.

10. The apparatus of claim 9, wherein the second RM code is associated with a generator matrix having a first number of rows corresponding to a first number of bits in each decoded codeword, wherein each row uniquely corresponds to an order of the RM code, wherein a particular order of the RM code may correspond to one of a single row or multiple rows of the generator matrix, wherein to decode a particular codeword of the plurality of codewords corresponding to a particular message of the plurality of messages, the at least one processor, individually or in any combination, is further configured to:
set a current order of the decoding method to be the second order and a current codeword to be the particular codeword;
determine, for each row of the generator matrix corresponding to the current order of the decoding method and until the current order is decremented below zero, a corresponding bit value based on a thresholding operation performed on a set of binary values associated with a set of linear combinations of bits in the current codeword, wherein the thresholding operation is based on the threshold value when the current order of the decoding method is greater than the first order and is based on a majority when the current order of the decoding method is not greater than the first order;
calculate, based on the determined corresponding bit values, an updated codeword;
decrement a value of the current order of the decoding method; and
return, when the value of the current order is decremented below zero, the determined corresponding bit values as a particular decoded codeword.

11. The apparatus of claim 10, wherein, when the current order of the decoding method is greater than the second order, to perform the thresholding operation based on the threshold value performed on the set of binary values associated with the set of linear combinations of bits in the current codeword, the at least one processor, individually or in any combination, is further configured to:
compare a second number of non-zero binary values in the set of binary values to the threshold value;
set the corresponding bit value to zero when the second number of non-zero binary values is less than the threshold value; and
set the corresponding bit value to one when the second number of non-zero binary values is at least the threshold value.

12. The apparatus of claim 11, wherein the set of binary values comprises a third number of binary values that depends on the current order and the threshold value is a threshold fraction of the third number of binary values, wherein the threshold fraction is greater than 50 percent.

13. The apparatus of claim 10, wherein, when the current order of the decoding method is not greater than the second order, to perform the thresholding operation based on the majority performed on the set of binary values associated with the set of linear combinations of bits in the current codeword, the at least one processor, individually or in any combination, is further configured to:
compare a second number of non-zero values in the set of binary values to a third number of zero values in the set of binary values;
set the corresponding bit value to zero when the second number of non-zero values is less than the third number of zero values;
set the corresponding bit value to one when the second number of non-zero values is greater than the third number of zero values; and
one of:
indicate a failure to decode when the second number of non-zero values is equal to the third number of zero values,
set the corresponding bit value to zero when the second number of non-zero values is equal to the third number of zero values, or
set the corresponding bit value to one when the second number of non-zero values is equal to the third number of zero values.

14. The apparatus of claim 9, wherein the decoding method includes a modified recursive projection-aggregation (RPA) decoding algorithm for decoding an input codeword, wherein the modified RPA decoding algorithm is based on a first input value associated with a length of the input codeword, a second input value based on the second order, a third input value associated with a first number of invocations of the modified RPA decoding algorithm to perform before attempting to decode the input codeword as a codeword in the first subset of the plurality of codewords, and a fourth input value associated with the threshold value, wherein the third input value is based on a difference between the first order and the second order, wherein the modified RPA decoding algorithm for the second input value equal to one comprises a fast Hadamard transform (FHT), wherein each iteration of the modified RPA decoding algorithm may be performed one of up to a maximum number of times or until a decoded codeword converges, and wherein to decode a particular codeword of the plurality of codewords the modified RPA decoding algorithm is invoked with a current input codeword that is the particular codeword, a current first input value that is a first value associated with the length of the particular codeword, a current second input value that is the second order, a current third input value that is a third value based on the difference between the first order and the second order, and a current fourth input value associated with the threshold value, wherein to invoke the modified RPA decoding algorithm, the at least one processor, individually or in any combination, is further configured to:
determine whether the first number of invocations of the modified RPA decoding algorithm have been performed based on the current second input value and the third input value;
perform, when the first number of invocations of the modified RPA decoding algorithm have not been performed and when the current second input value is greater than 2, a set of projections of the current input codeword to generate a plurality of projected codewords and invoking the modified RPA decoding algorithm for each of the plurality of projected codewords with a decremented first input value and a decremented second input value;
determine, when the first number of invocations of the modified RPA decoding algorithm have been performed, if the current input codeword of a most recent invocation of the modified RPA decoding algorithm is associated with the first subset of the plurality of codewords based on the fourth input value associated with the threshold value;
output, when the first number of invocations of the modified RPA decoding algorithm have been performed and based on determining that the current input codeword of the most recent invocation of the modified RPA decoding algorithm is associated with the first subset of the plurality of codewords, the decoded codeword based on the particular codeword;
perform, when the first number of invocations of the modified RPA decoding algorithm have been performed and based on a determination that the current input codeword of the most recent invocation of the modified RPA decoding algorithm is not associated with the first subset of the plurality of codewords, a set of additional projections and invocations of the modified RPA decoding algorithm with an additional decremented first input value and an additional decremented second value until the current second input value is equal to 1 and decode the current input codeword for each of the plurality of projected codewords associated with a current invocation of the modified RPA decoding algorithm using the FHT; and
decode, based on a decoded current input codeword for each of the plurality of projected codewords, a plurality of input codewords associated with previous invocations of the modified RPA decoding algorithm.

15. The apparatus of claim 9, wherein the decoding method includes a modified recursive projection-aggregation (RPA) decoding algorithm for decoding an input codeword, wherein the modified RPA decoding algorithm is based on a first input value associated with a length of the input codeword, a second input value based on the second order associated with the input codeword, a third input value associated with a first number of invocations of the modified RPA decoding algorithm to perform before attempting to decode the input codeword as a codeword in the first subset of the plurality of codewords, and a fourth input value associated with the threshold value, wherein the third input value is based on a difference between the first order and the second order, wherein the modified RPA decoding algorithm for the second input value equal to one comprises a fast Hadamard transform (FHT), wherein each invocation of the modified RPA decoding algorithm for which a particular condition is not met comprises performing a projection operation on the input codeword that produces a plurality of intermediate codewords that are each used as an input for a next invocation of the modified RPA decoding algorithm with a decremented first input value associated with the length of an input intermediate codeword and a decremented second input value based on an order associated with the input intermediate codeword, and wherein to decode a particular codeword of the plurality of codewords, the at least one processor, individually or in any combination, is further configured to:
invoke a first recursion of the modified RPA decoding algorithm that invokes additional recursions of the modified RPA decoding algorithm with decremented first input values and decremented second input values until the modified RPA decoding algorithm is invoked with the second input value that is equal to one more than the difference between the first order and the second order;
attempt to decode a current intermediate codeword using a the FHT;
output, when a decoding using the FHT is successful, a decoded codeword from the first subset of the plurality of codewords by resolving previous invocations of the modified RPA decoding algorithm based on a decoded current intermediate codeword and an aggregation operation to account for a plurality of invocations of the modified RPA decoding algorithm at each level of recursion, wherein a first invocation of the modified RPA decoding algorithm may perform an additional round beginning from the projection operation if one of a set of stopping conditions has not been met; and
invoke, when the decoding using the FHT is not successful, the modified RPA decoding algorithm until the modified RPA decoding algorithm is invoked with the second input value that is equal to one and decodes the current intermediate codeword using the FHT and outputs the decoded codeword of the second subset of the plurality of codewords by resolving the previous invocations of the modified RPA decoding algorithm based on the decoded current intermediate codeword and the aggregation operation to account for the plurality of invocations of the modified RPA decoding algorithm at each level of the recursion, the aggregation operation to produce a decoded message in the second subset of the plurality of messages, wherein the first invocation of the modified RPA decoding algorithm may perform the additional round beginning from the projection operation if one of the set of stopping conditions has not been met, wherein the set of stopping conditions comprises at least one of a maximum number of additional rounds or a convergence condition.

16. The apparatus of claim 15, wherein the decoding using the FHT is successful if a Hamming distance between the decoded codeword and the input intermediate codeword is less than a threshold distance.

17. The apparatus of claim 9, wherein the decoding method includes a modified recursive projection-aggregation (RPA) decoding algorithm for decoding an input codeword, wherein the modified RPA decoding algorithm is based on a first input value associated with a length of the input codeword, a second input value based on the second order associated with the input codeword, a third input value associated with a first number of invocations of the modified RPA decoding algorithm to perform before attempting to decode the input codeword as a codeword in the first subset of the plurality of codewords, and a fourth input value associated with the threshold value, wherein the third input value is based on a difference between the first order and the second order, wherein the modified RPA decoding algorithm for the second input value equal to one comprises a fast Hadamard transform (FHT), wherein each invocation of the modified RPA decoding algorithm for which a particular condition is not met comprises performing a projection operation on the input codeword that produces a plurality of intermediate codewords that are each used as an input for a next invocation of the modified RPA decoding algorithm with a decremented first input value associated with the length of the input intermediate codeword and a decremented second input value based on an order associated with the input intermediate codeword, and wherein to decode a particular codeword of the plurality of codewords, the at least one processor, individually or in any combination, is further configured to:
invoke a first recursion of the modified RPA decoding algorithm that invokes additional recursions of the modified RPA decoding algorithm with decremented first input values and decremented second input values until the modified RPA decoding algorithm is invoked with an order value that is equal to one less than the difference between the first order and the second order;
compare, for a current intermediate codeword, the fourth input value associated with the threshold value to a Hamming distance between the current intermediate codeword and a zero codeword of a same length as the current intermediate codeword;
output, when the Hamming distance is less than the fourth input value, a decoded codeword from the first subset of the plurality of codewords by resolving previous invocations of the modified RPA decoding algorithm based on the zero codeword and an aggregation operation to account for the plurality of invocations of the modified RPA decoding algorithm at each level of recursion, wherein a first invocation of the modified RPA decoding algorithm may perform an additional round beginning from the projection operation if one of a set of stopping conditions has not been met; and
invoke, when the Hamming distance is at least the fourth input value, the modified RPA decoding algorithm until the modified RPA decoding algorithm is invoked with the second input value that is equal to one and decodes the current intermediate codeword using the FHT and outputs the decoded codeword of the second subset of the plurality of codewords by resolving the previous invocations of the modified RPA decoding algorithm based on a decoded current intermediate codeword and the aggregation operation to account for a plurality of invocations of the modified RPA decoding algorithm at each level of the recursion, the aggregation operation to produce a decoded message in the second subset of the plurality of messages, wherein the first invocation of the modified RPA decoding algorithm may perform the additional round beginning from the projection operation if one of the set of stopping conditions has not been met, wherein the set of stopping conditions comprises at least one of a maximum number of additional rounds or a convergence condition.

18. The apparatus of claim 6, wherein the decoding method is a machine-learning (ML) aided recursive projection-aggregation (RPA) decoding method, wherein the ML aided RPA is trained to decode first input codewords in the first subset of the plurality of codewords with a first accuracy based on the first error tolerance and to decode second input codewords in the second subset of the plurality of codewords with a second accuracy based on the second error tolerance, and wherein the ML aided RPA is trained based on a training set comprising, multiple data sets comprising:
multiple projections generated by an RPA decoding apparatus applied to a test codeword encoded with one of the first RM code or the second RM code, and
an indication of whether the first RM code or the second RM code was used to encode the test codeword.

19. A method of wireless communication at a decoder device, comprising:
receiving a plurality of codewords associated with a plurality of messages, wherein the plurality of codewords comprises a first subset of the plurality of codewords associated with a first subset of the plurality of messages and a second subset of the plurality of codewords associated with a second subset of the plurality of messages, wherein the first subset of the plurality of codewords is associated with a first Reed-Muller (RM) code and the second subset of the plurality of codewords is associated with a second RM code, wherein the first RM code is a subcode of the second RM code;
decoding the plurality of codewords using a decoding method that is associated with a first error tolerance for the first subset of the plurality of codewords associated with the first RM code and a second error tolerance for the second subset of the plurality of codewords associated with the second RM code, wherein the first error tolerance is higher than the second error tolerance; and
outputting a plurality of decoded codewords associated with the plurality of messages.

20. The method of claim 19, wherein the decoding method includes a machine-learning (ML) aided recursive projection-aggregation (RPA) decoding method, wherein the ML aided RPA is trained to decode first input codewords in the first subset of the plurality of codewords with a first accuracy based on the first error tolerance and to decode second input codewords in the second subset of the plurality of codewords with a second accuracy based on the second error tolerance, and wherein the ML aided RPA is trained based on a training set comprising, multiple data sets comprising:
multiple projections generated by an RPA decoding method applied to a test codeword encoded with one of the first RM code or the second RM code, and
an indication of whether the first RM code or the second RM code was used to encode the test codeword.
